(19) United States
(12) Patent Application Publication
(10) Pub. No.: US 2026/0361233 A1
(43) Pub. Date: Nov. 12, 2026

(54) INTELLIGENT POWER MODULE AND SEMICONDUCTOR MODULE

(71) Applicant: ROHM CO., LTD., Kyoto-shi (JP)

(72) Inventor: Masashi HAYASHIGUCHI, Kyoto-shi (JP)

(21) Appl. No.: 19/706,387

(22) Filed: Jun. 12, 2026

Related U.S. Application Data
(63) Continuation of application No. PCT/JP2024/041467, filed on Nov. 22, 2024.

(30) Foreign Application Priority Data
Dec. 19, 2023 (JP) 2023-213594

(51) Int. Cl. H02M 7/00; H02M 1/088; H02M 7/5387; H10D 62/83; H10D 62/832; H10D 80/20

(52) U.S. Cl. CPC H02M 7/003; H02M 1/088; H02M 7/53871; H10D 62/83; H10D 62/8325; H10D 80/213; H10D 80/231; H10D 80/251

(57) ABSTRACT

An intelligent power module includes: two semiconductor elements connected to each other in parallel; a drive element that outputs a common drive signal to the two semiconductor elements; a pair of rectifying elements connected in series via a first connection point; a pair of rectifying elements connected in series via a second connection point; a first resistor connected between the first connection point and the drive element; and a second resistor connected between the second connection point and the drive element. Each of the pair of rectifying elements is connected to conduct forward current from the first connection point to a corresponding one of the two electrodes. Each of the pair of rectifying elements is connected to conduct forward current from a corresponding one of the two electrodes to the second connection point.

### TECHNICAL FIELD

The present disclosure relates to an intelligent power module and a semiconductor module.

### BACKGROUND ART

Conventionally, semiconductor modules incorporating semiconductor elements, such as MOSFETs (metal oxide semiconductor field effect transistors) and IGBTs (insulated gate bipolar transistors), are known. For example, JP-A-2023-161017 discloses an example of a conventional semiconductor module. The semiconductor module disclosed in JP-A-2023-161017 includes a plurality of semiconductor elements. The semiconductor elements are, for example, MOSFETs. The semiconductor elements are electrically connected in parallel and driven in parallel by a common drive signal.

### BRIEF DESCRIPTION OF THE DRAWINGS

FIG. 1 is a circuit diagram illustrating an exemplary circuit configuration of an intelligent power module according to a first embodiment.

FIG. 2 is a perspective view illustrating a power conversion unit including the intelligent power module according to the first embodiment.

FIG. 3 is a perspective view corresponding to FIG. 2, in which a portion of the wiring board (the upper-side circuit board) is omitted together with components mounted on the portion of the wiring board.

FIG. 4 is a perspective view corresponding to FIG. 3, in which another portion of the wiring board (the lower-side circuit board) is omitted together with components mounted on the portion of the wiring board.

FIG. 5 is a plan view illustrating the power conversion unit including the intelligent power module according to the first embodiment.

FIG. 6 is a plan view corresponding to FIG. 5, in which a portion of the wiring board (the upper-side circuit board) is omitted together with components mounted on the portion of the wiring board.

FIG. 7 is a plan view corresponding to FIG. 6, in which another portion of the wiring board (the lower-side circuit board) is omitted together with components mounted on the portion of the wiring board.

FIG. 8 is a front view illustrating the power conversion unit including the intelligent power module according to the first embodiment.

FIG. 9 is a bottom view illustrating the power conversion unit including the intelligent power module according to the first embodiment.

FIG. 10 is a left-side view illustrating the power conversion unit including the intelligent power module according to the first embodiment.

FIG. 11 is a right-side view illustrating the power conversion unit including the intelligent power module according to the first embodiment.

FIG. 12 is a sectional view taken along line XII-XII in FIG. 6.

FIG. 13 is a sectional view taken along line XIII-XIII in FIG. 6.

FIG. 14 is an enlarged sectional view illustrating a portion of the power conversion unit including the intelligent power module according to the first embodiment.

FIG. 15 is an enlarged plan view illustrating a portion of FIG. 6.

FIG. 16 is an enlarged left-side view illustrating a portion of FIG. 10.

FIG. 17 is an enlarged sectional view illustrating a portion of the power conversion unit including the intelligent power module according to the first embodiment.

FIG. 18 is a plan view illustrating a module section of the intelligent power module according to the first embodiment.

FIG. 19 is a plan view corresponding to FIG. 18, in which the sealing resin is shown in phantom.

FIG. 20 is a plan view corresponding to FIG. 19, in which the sealing resin and one of the two conductive members are omitted.

FIG. 21 is an enlarged plan view illustrating a portion of FIG. 20.

FIG. 22 is a front view illustrating the module section of the intelligent power module according to the first embodiment.

FIG. 23 is a bottom view illustrating the module section of the intelligent power module according to the first embodiment.

FIG. 24 is a sectional view taken along line XXIV-XXIV in FIG. 19.

FIG. 25 is an enlarged sectional view illustrating a portion of FIG. 24.

FIG. 26 is an enlarged sectional view illustrating a portion of FIG. 24.

FIG. 27 is a sectional view taken along line XXVII-XXVII in FIG. 19.

FIG. 28 is a sectional view taken along line XXVIII-XXVIII in FIG. 19.

FIG. 29 is a sectional view taken along line XXIX-XXIX in FIG. 19.

FIG. 30 is a plan view illustrating a semiconductor element (IGBT) of the intelligent power module according to the first embodiment.

FIG. 31 is a sectional view taken along line XXXI-XXXI in FIG. 30.

FIG. 32 is a sectional view taken along line XXXII-XXXII in FIG. 30.

FIG. 33 is a sectional view, corresponding to FIG. 31, illustrating a variation of the semiconductor element (IGBT) of the intelligent power module according to the first embodiment.

FIG. 34 is a plan view illustrating a semiconductor element (MOSFET) of the intelligent power module according to the first embodiment.

FIG. 35 is a sectional view taken along line XXXV-XXXV in FIG. 34.

FIG. 36 is an enlarged sectional view illustrating a portion of FIG. 35.

FIG. 37 is a sectional view, corresponding to FIG. 35, illustrating a variation of the semiconductor element (MOSFET) of the intelligent power module according to the first embodiment.

FIG. 38 is an enlarged sectional view illustrating a portion of FIG. 37.

FIG. 39 is a schematic diagram illustrating a vehicle equipped with the power conversion unit including the intelligent power module according to the first embodiment.

FIG. 40 is an enlarged plan view illustrating a main portion of a module section according to a variation.

FIG. 41 is a plan view illustrating a power conversion unit according to a variation.

FIG. 42 is a plan view corresponding to FIG. 41, in which a portion of the wiring board (the upper-side circuit board) is omitted together with components mounted on the portion of the wiring board.

FIG. 43 is a plan view corresponding to FIG. 42, in which another portion of the wiring board (the lower-side circuit board) is omitted together with components mounted on the portion of the wiring board.

FIG. 44 is a plan view illustrating a power conversion unit according to a variation.

FIG. 45 is a circuit diagram illustrating an exemplary circuit configuration of an intelligent power module according to a second embodiment.

FIG. 46 is a circuit diagram illustrating an exemplary circuit configuration of an intelligent power module according to a third embodiment.

FIG. 47 is a circuit diagram illustrating an exemplary circuit configuration of an intelligent power module according to a fourth embodiment.

### DETAILED DESCRIPTION OF EMBODIMENTS

With reference to the drawings, the following describes preferred embodiments of an intelligent power module and a semiconductor module according to the present disclosure. In the description, identical or similar components are designated by the same reference numerals, and overlapping descriptions are omitted. In the present disclosure, the terms such as “first”, “second”, “third”, and so on are used only as labels and are not intended to imply any order of the items to which they refer.

In the present disclosure, the expressions “An object A is formed in an object B”, and “An object A is formed on an object B” imply the situations where, unless otherwise specifically noted, “the object A is formed directly in or on the object B”, and “the object A is formed in or on the object B, with something else interposed between the object A and the object B.” Likewise, the expressions “An object A is arranged in an object B”, and “An object A is arranged on an object B” imply the situations where, unless otherwise specifically noted, “the object A is arranged directly in or on the object B”, and “the object A is arranged in or on the object B, with something else interposed between the object A and the object B”. Likewise, the expression “An object A is positioned on an object B” implies the situations where, unless otherwise specifically noted, “the object A is positioned on the object B, in contact with the object B”, and “the object A is positioned on the object B, with something else interposed between the object A and the object B.” The expression “An object A overlaps with an object B as viewed in a certain direction” implies the situations where, unless otherwise specifically noted, “the object A overlaps with the entirety of the object B”, and “the object A overlaps with a portion of the object B.” The expression “An object A contains (or the material of an object A includes) a material C” implies the situations where “the object A consists of the material C” and “the object A is made primarily of the material C”. In the present disclosure, the expression “A surface A faces a direction B (one side or the other side in that direction)” is not limited to the situation where the surface A forms an angle of 90°with the direction B, but includes the situation where the surface A is inclined relative to the direction B. In the present disclosure, the expression “A surface A is perpendicular to a surface B” is not limited to the situation where the surface A forms an angle of 90° with the surface B, but includes the situation where the surface A is inclined relative to the surface B.

### Intelligent Power Module A10: Circuit Configuration

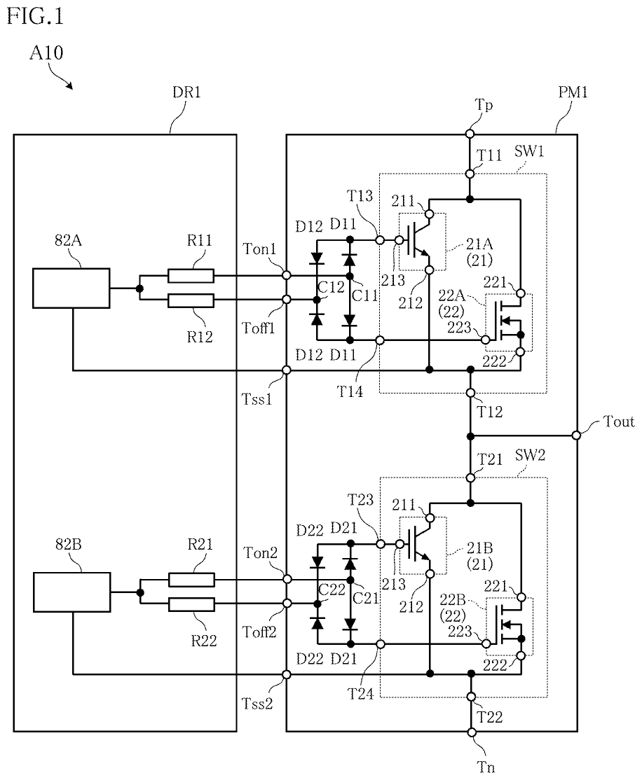

FIG. 1 is a circuit diagram illustrating an exemplary circuit configuration of an intelligent power module A10 according to a first embodiment. The intelligent power module A10 may be used to control an inverter-driven motor, while its applications and/or uses are not particularly limited. The intelligent power module A10 includes a module section PM1 and a drive circuit section DR1 in its circuit configuration.

The module section PM1 converts received power and outputs the resulting power. The module section PM1 is controlled by the drive circuit section DR1. The module section PM1 is an example of the “semiconductor module” recited in the claims. The module section PM1 includes two switching sections SW1 and SW2, and a plurality of rectifying elements D11, D12, D21, and D22.

The switching sections SW1 and SW2 perform the electrical function of the module section PM1. In the present embodiment, the two switching sections SW1 and SW2 are identically configured. Each of the two switching sections SW1 and SW2 includes two semiconductor elements 21 and 22. The following description of the semiconductor elements 21 and 22 is common to both the switching sections SW1 and SW2. For convenience of description, the semiconductor elements 21 and 22 of the switching section SW1 are respectively referred to as the semiconductor elements 21A and 22A, and the semiconductor elements 21 and 22 of the switching section SW2 are respectively referred to as semiconductor elements 21B and 22B.

In the example illustrated in FIG. 1, each semiconductor element 21 is an IGBT. The semiconductor element 21 includes a first semiconductor substrate (a n⁻-type semiconductor substrate G31 described later). The constituent material of the first semiconductor substrate includes, for example, silicon (Si). As an alternative to Si, the constituent material of the first semiconductor substrate may include silicon carbide (SiC), gallium arsenide (GaAs), gallium nitride (GaN), or gallium oxide (Ga₂O₃). In another example, the semiconductor element 21 may be a transistor other than an IGBT (for example, a MOSFET or a bipolar transistor). The semiconductor element 21 is an example of the “first semiconductor element” recited in the claims.

The semiconductor element 21 includes three electrodes 211, 212, and 213. In the case where the semiconductor element 21 is an IGBT, the electrode 211 is the collector electrode, the electrode 212 is the emitter electrode, and the electrode 213 is the gate electrode. The electrode 213 receives a drive signal. The semiconductor element 21 is switched between ON and OFF in response to a drive signal input to the electrode 213. In the ON state, electrical conduction between the electrodes 211 and 212 is established, and in the OFF state, electrical conduction between the electrodes 211 and 212 is interrupted. Thus, the semiconductor element 21 is configured such that electrical conduction between the electrodes 211 and 212 is controlled in response to a drive signal applied to the electrode 213. The electrodes 211, 212, and 213 are respectively examples of the “first electrode”, “second electrode”, and “third electrode” recited in the claims.

In the example illustrated in FIG. 1, each semiconductor element 22 is a MOSFET. The semiconductor element 22 includes a second semiconductor substrate (a semiconductor substrate M102 described later). The constituent material of the second semiconductor substrate has a wider band gap than that of the first semiconductor substrate and includes, for example, SiC. As an alternative to SiC, the constituent material of the second semiconductor substrate may include Si, GaAs, GaN, or Ga₂O₃. In another example, the semiconductor element 22 may be a transistor other than a MOSFET (for example, an IGBT or a bipolar transistor). The semiconductor element 22 is an example of the “second semiconductor element” recited in the claims.

The semiconductor element 22 includes three electrodes 221, 222, and 223. In the case where the semiconductor element 22 is a MOSFET, the electrode 221 is the drain electrode, the electrode 222 is the source electrode, and the electrode 223 is the gate electrode. The electrode 223 receives a drive signal. The semiconductor element 22 is switched between ON and OFF in response to a drive signal applied to the electrode 223. In the ON state, electrical conduction between the electrodes 221 and 222 is established, and in the OFF state, electrical conduction between the electrodes 221 and 222 is interrupted. Thus, the semiconductor element 22 is configured such that electrical conduction between the electrodes 221 and 222 is controlled in response to a drive signal applied to the electrode 223. The electrodes 221, 222, and 223 are respectively examples of the “fourth electrode”, “fifth electrode”, and “sixth electrode” recited in the claims.

In each of the switching sections SW1 and SW2, the two semiconductor elements 21 and 22 are electrically connected in parallel. Specifically, the electrode 211 (the collector electrode) of the semiconductor element 21 and the electrode 221 (the drain electrode) of the semiconductor element 22 are electrically connected. Also, the electrode 212 (the emitter electrode) of the semiconductor element 21 and the electrode 222 (the source electrode) of the semiconductor element 22 are electrically connected. In each of the switching sections SW1 and SW2, the two semiconductor elements 21 and 22 receive a common drive signal. For convenience of description, the drive signal applied to the semiconductor elements 21A and 22A of the switching section SW1 may be referred to as a “first drive signal.” Similarly, the drive signal applied to the semiconductor elements 21B and 22B of the switching section SW2 may be referred to as a “second drive signal.”

The switching section SW1 includes two connection ends T11 and T12, and two signal ends T13 and T14. The connection end T11 is electrically connected to the electrode 211 of the semiconductor element 21A and the electrode 221 of the semiconductor element 22A. The connection end T12 is electrically connected to the electrode 212 of the semiconductor element 21A and the electrode 222 of the semiconductor element 22A. The signal end T13 is electrically connected to the electrode 213 of the semiconductor element 21A, whereas the signal end T14 is electrically connected to the electrode 223 of the semiconductor element 22A. When at least one of the semiconductor elements 21A and 22A is in the ON state, electrical conduction between the connection ends T11 and T12 is established, so that the switching section SW1 is turned on. On the other hand, when both the semiconductor elements 21A and 22A are in the OFF state, electrical conduction between the connection ends T11 and T12 is interrupted, so that the switching section SW1 is turned off. The switching section SW1 is an example of the “first switching section” recited in the claims.

The switching section SW2 includes two connection ends T21 and T22 and two signal ends T23 and T24. The connection end T21 is electrically connected to the electrode 211 of the semiconductor element 21B and the electrode 221 of the semiconductor element 22B. The connection end T22 is electrically connected to the electrode 212 of the semiconductor element 21B and the electrode 222 of the semiconductor element 22B. The signal end T23 is electrically connected to the electrode 213 of the semiconductor element 21B, whereas the signal end T24 is electrically connected to the electrode 223 of the semiconductor element 22B. In the present embodiment, the connection end T21 is electrically connected to the connection end T12. Thus, the switching sections SW1 and SW2 are electrically connected in series. When at least one of the semiconductor elements 21B and 22B is in the ON state, electrical conduction between the connection ends T21 and T22 is established, so that the switching section SW2 is turned on. On the other hand, when both the semiconductor elements 21B and 22B are in the OFF state, electrical conduction between the connection ends T21 and T22 is interrupted, so that the switching section SW2 is turned off. The switching section SW2 is an example of the “second switching section” recited in the claims.

The rectifying elements D11, D12, D21, and D22 are electronic components each of which allows electric current to flow in only one direction. In the example illustrated in FIG. 1, the rectifying elements D11, D12, D21, and D22 are diodes. The rectifying elements D11, D12, D21, and D22, however, are not limited to diodes, provided each allows current to flow in only one direction. For example, each of the rectifying elements D11, D12, D21, and D22 may be a switching element that is controlled with timing such that current flows only in one direction.

A pair of rectifying elements D11 are connected in series via a connection point C11. One of the rectifying elements D11 is connected to allow forward current to flow from the connection point C11 to the electrode 213 of the semiconductor element 21A. The other rectifying element D11 is connected to allow forward current to flow from the connection point C11 to the electrode 223 of the semiconductor element 22A. In the example illustrated in FIG. 1, the anode electrode of each rectifying element D11 is connected to the connection point C11. Each rectifying element D11 is an example of the “first rectifying element” recited in the claims, and the connection point C11 is an example of the “first connection point” recited in the claims.

A pair of rectifying elements D12 are connected in series via a connection point C12. One of the rectifying elements D12 is connected to allow forward current to flow from the electrode 213 of the semiconductor element 21A to the connection point C12. The other rectifying element D12 is connected to allow forward current to flow from the electrode 223 of the semiconductor element 22A to the connection point C12. In the example illustrated in FIG. 1, the cathode electrode of each rectifying element D12 is connected to the connection point C12. Each rectifying element D12 is an example of the “second rectifying element” recited in the claims, and the connection point C12 is an example of the “second connection point” recited in the claims.

A pair of rectifying elements D21 are connected in series via a connection point C21. One of the rectifying elements D21 is connected to allow forward current to flow from the connection point C21 to the electrode 213 of the semiconductor element 21B. The other rectifying element D21 is connected to allow forward current to flow from the connection point C21 to the electrode 223 of the semiconductor element 22B. In the example illustrated in FIG. 1, the anode electrode of each rectifying element D21 is connected to the connection point C21.

A pair of rectifying elements D22 are connected in series via a connection point C22. One of the rectifying elements D22 is connected to conduct forward current from the electrode 213 of the semiconductor element 21B to the connection point C22. The other rectifying element D22 is connected to conduct forward current from the electrode 223 of the semiconductor element 22B to the connection point C22. In the example illustrated in FIG. 1, the cathode electrode of each rectifying element D22 is connected to the connection point C22.

The module section PM1 includes a plurality of power terminals Tp, Tn, and Tout, and a plurality of signal terminals Ton1, Toff1, Ton2, Toff2, Tss1, and Tss2. The signal terminal Ton1 is an example of the “first signal terminal” recited in the claims, and the signal terminal Toff1 is an example of the “second signal terminal” recited in the claims.

The power terminal Tp is electrically connected to the connection end T11 of the switching section SW1. Thus, the power terminal Tp is electrically connected to the electrode 211 of the semiconductor element 21A and the electrode 221 of the semiconductor element 22A. The power terminal Tn is electrically connected to the connection end T22 of the switching section SW2. Thus, the power terminal Tn is electrically connected to the electrode 212 of the semiconductor element 21B and the electrode 222 of the semiconductor element 22B. The power terminal Tout is electrically connected to the connection end T12 of the switching section SW1 and also to the connection end T21 of the switching section SW2. Thus, the power terminal Tout is electrically connected to the electrode 212 of the semiconductor element 21A and the electrode 222 of the semiconductor element 22A, as well as to the electrode 211 of the semiconductor element 21B and the electrode 221 of the semiconductor element 22B. The power terminals Tp, Tn, and Tout are respectively examples of the “first power terminal”, “second power terminal”, and “third power terminal” recited in the claims.

The module section PM1 converts a power supply voltage (e.g., DC) applied between the power terminals Tp and Tn into AC power, by switching the switching sections SW1 and SW2 between ON and OFF states (i.e., through switching operations of the semiconductor elements 21 and 22 of each switching section SW1 or SW2). The converted AC power is output from the power terminal Tout and input to a power-receiving target, such as a motor.

The two signal terminals Ton1 and Toff1 serve as input terminals for the first drive signal described above. The signal terminal Ton1 is electrically connected to the connection point C11 and is connected to the two signal ends T13 and T14 via the pair of rectifying elements D11. The signal terminal Ton1 is connected to the electrode 213 (gate electrode) of the semiconductor element 21A and the electrode 223 (gate electrode) of the semiconductor element 22A via the pair of rectifying elements D11. The signal terminal Toff1 is electrically connected to the connection point C12 and is connected to the two signal ends T13 and T14 via the pair of rectifying elements D12. The signal terminal Toff1 is connected to the electrode 213 (gate electrode) of the semiconductor element 21A and the electrode 223 (gate electrode) of the semiconductor element 22A via the pair of rectifying elements D12.

The two signal terminals Ton2 and Toff2 serve as input terminals for the second drive signal described above. The signal terminal Ton2 is electrically connected to the connection point C21 and is connected to the two signal ends T23 and T24 via the pair of rectifying elements D21. The signal terminal Ton2 is connected to the electrode 213 (gate electrode) of the semiconductor element 21B and the electrode 223 (gate electrode) of the semiconductor element 22B via the pair of rectifying elements D21. The signal terminal Toff2 is electrically connected to the connection point C22 and is connected to the two signal ends T23 and T24 via the pair of rectifying elements D22. The signal terminal Toff2 is connected to the electrode 213 (gate electrode) of the semiconductor element 21B and the electrode 223 (gate electrode) of the semiconductor element 22B via the pair of rectifying elements D22.

The signal terminal Tss1 is electrically connected to the electrode 212 of the semiconductor element 21A and the electrode 222 of the semiconductor element 22A. The signal terminal Tss1 outputs a voltage signal corresponding to the currents flowing through the electrode 212 (the emitter electrode) of the semiconductor element 21A and the electrode 222 (the source electrode) of the semiconductor element 22A. This voltage signal is used to detect the currents flowing through the semiconductor element 21A and the semiconductor element 22A (the switching section SW1), and may be hereinafter referred to as the first sensing signal.

The signal terminal Tss2 is electrically connected to the electrode 212 of the semiconductor element 21B and the electrode 222 of the semiconductor element 22B. The signal terminal Tss2 outputs a voltage signal corresponding to the currents flowing through the electrode 212 (the emitter electrode) of the semiconductor element 21B and the electrode 222 (the source electrode) of the semiconductor element 22B. This voltage signal is used to detect the currents flowing through the semiconductor element 21B and the semiconductor element 22B (the switching section SW2), and may be hereinafter referred to as the second sensing signal.

The drive circuit section DR1 controls the power conversion conducted by the module section PM1. The drive circuit section DR1 generates a first drive signal and a second drive signal. The first drive signal is supplied to the switching section SW1 to control switching of the switching section SW1 between an ON state and an OFF state, and the second drive signal is supplied to the switching section SW2 to control switching of the switching section SW2 between an ON state and an OFF state. The drive circuit section DR1 includes two drive elements 82A and 82B, and a plurality of resistors R11, R12, R21, and R22.

The resistor R11 is electrically connected between the signal terminal Ton1 and the drive element 82A. The resistor R12 is electrically connected between the signal terminal Toff1 and the drive element 82A. The resistor R21 is electrically connected between the signal terminal Ton2 and the drive element 82B. The resistor R22 is electrically connected between the signal terminal Toff2 and the drive element 82B. The resistor R11 is an example of the “first resistor” recited in the claims, and the resistor R12 is an example of the “second resistor” recited in the claims.

The drive element 82A is, for example, a gate drive IC and generates a first drive signal. The first drive signal generated by the drive element 82A includes a first turn-on signal and a first turn-off signal. The drive element 82A is connected to the signal terminal Tss1 and receives the first sensing signal. The drive element 82A generates a first drive signal based on the first sensing signal and/or other signals.

The first turn-on signal causes the semiconductor elements 21A and 22A to turn ON. The first turn-on signal raises the potentials at the electrode 213 (gate electrode) of the semiconductor element 21A and at the electrode 223 (gate electrode) of the semiconductor element 22A. As a result, the voltage between the electrodes 212 and 213 (gate-emitter voltage) of the semiconductor element 21A exceeds a predetermined threshold, which turns ON the semiconductor element 21A. Similarly, the voltage between the electrodes 222 and 223 (gate-source voltage) of the semiconductor element 22A exceeds a predetermined threshold, which turns ON the semiconductor element 22A. In response to the first turn-on signal, charge is supplied from the drive element 82A to the signal terminal Ton1 via the resistor R11. The charge supplied to the signal terminal Ton1 is then supplied, via the pair of rectifying elements D11, to the electrode 213 of the semiconductor element 21A and the electrode 223 of the semiconductor element 22A. As a result, the potentials at the electrode 213 of the semiconductor element 21A and at the electrode 223 of the semiconductor element 22A increase. The resistor R11 functions as a gate resistor during turn-on of the switching section SW1 (the two semiconductor elements 21A and 22A).

The first turn-off signal causes the semiconductor elements 21A and 22A to turn OFF. The first turn-off signal lowers the potentials at the electrode 213 (gate electrode) of the semiconductor element 21A and at the electrode 223 (gate electrode) of the semiconductor element 22A. As a result, the voltage between the electrodes 212 and 213 (gate-emitter voltage) of the semiconductor element 21A falls below the predetermined threshold, which turns OFF the semiconductor element 21A. Similarly, the voltage between the electrodes 222 and 223 (gate-source voltage) of the semiconductor element 22A falls below the predetermined threshold, which turns OFF the semiconductor element 22A. In response to the first turn-off signal, charge is discharged from the electrode 213 of the semiconductor element 21A and the electrode 223 of the semiconductor element 22A to the signal terminal Toff1 via the pair of rectifying elements D12. Then, charge is transferred from the signal terminal Toff1 to the drive element 82A via the resistor R12. As a result, the potentials at the electrode 213 of the semiconductor element 21A and at the electrode 223 of the semiconductor element 22A decrease. The resistor R12 functions as a gate resistor during turn-off of the switching section SW1 (the two semiconductor elements 21A and 22A).

The drive element 82B is, for example, a gate drive IC and generates a second drive signal. The second drive signal generated by the drive element 82B includes a second turn-on signal and a second turn-off signal. The drive element 82B is connected to the signal terminal Tss2 and receives the second sensing signal. The drive element 82B generates a second drive signal based on the second sensing signal and/or other signals.

The second turn-on signal causes the semiconductor elements 21B and 22B to turn ON. The second turn-on signal raises the potentials at the electrode 213 (gate electrode) of the semiconductor element 21B and at the electrode 223 (gate electrode) of the semiconductor element 22B. As a result, the voltage between the electrodes 212 and 213 (gate-emitter voltage) of the semiconductor element 21B exceeds a predetermined threshold, which turns ON the semiconductor element 21B. Similarly, the voltage between the electrodes 222 and 223 (gate-source voltage) of the semiconductor element 22B exceeds a predetermined threshold, which turns ON the semiconductor element 22B. In response to the second turn-on signal, charge is supplied from the drive element 82B to the signal terminal Ton2 via the resistor R21. The charge supplied to the signal terminal Ton2 is then supplied, via the pair of rectifying elements D21, to the electrode 213 of the semiconductor element 21B and the electrode 223 of the semiconductor element 22B. As a result, the potentials at the electrode 213 of the semiconductor element 21B and at the electrode 223 of the semiconductor element 22B increase. The resistor R21 functions as a gate resistor during turn-on of the switching section SW2 (the two semiconductor elements 21B and 22B).

The second turn-off signal causes the semiconductor elements 21B and 22B to turn OFF. The second turn-off signal lowers the potentials at the electrode 213 (gate electrode) of the semiconductor element 21B and at the electrode 223 (gate electrode) of the semiconductor element 22B. As a result, the voltage between the electrodes 212 and 213 (gate-emitter voltage) of the semiconductor element 21B falls below the predetermined threshold, which turns OFF the semiconductor element 21B. Similarly, the voltage between the electrodes 222 and 223 (gate-source voltage) of the semiconductor element 22B falls below the predetermined threshold, which turns OFF the semiconductor element 22B. In response to the second turn-off signal, charge is discharged from the electrode 213 of the semiconductor element 21B and the electrode 223 of the semiconductor element 22B to the signal terminal Toff2 via the pair of rectifying elements D22. Then, charge is transferred from the signal terminal Toff2 to the drive element 82B via the resistor R22. As a result, the potentials at the electrode 213 of the semiconductor element 21B and at the electrode 223 of the semiconductor element 22B decrease. The resistor R22 functions as a gate resistor during turn-off of the switching section SW2 (the two semiconductor elements 21B and 22B).

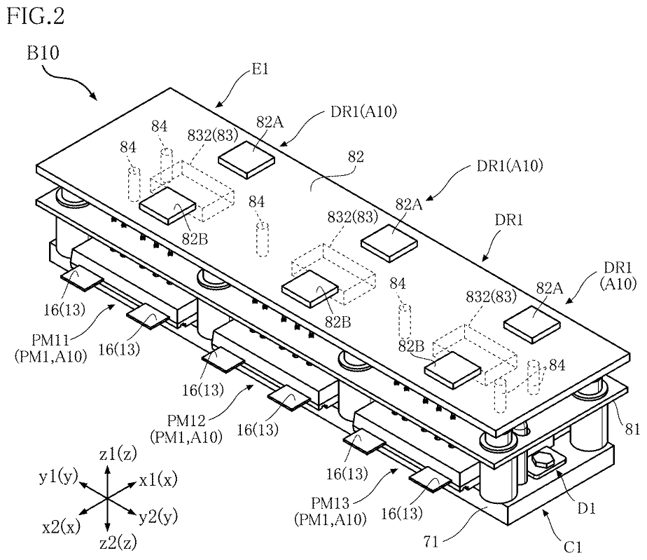

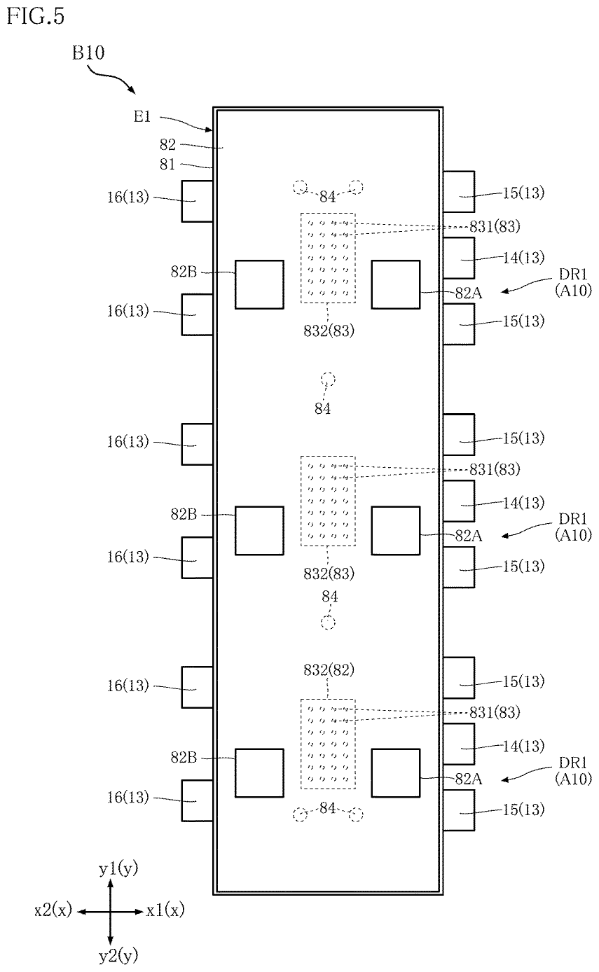

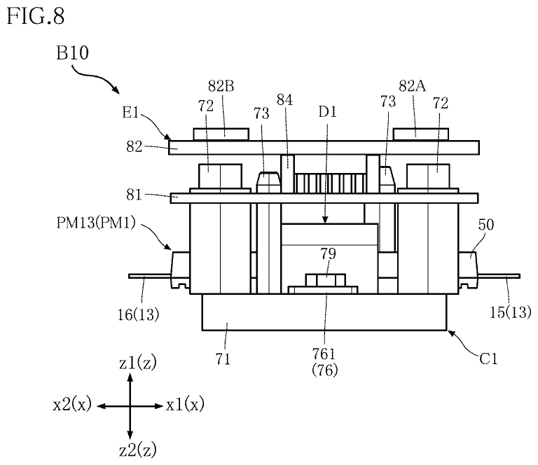

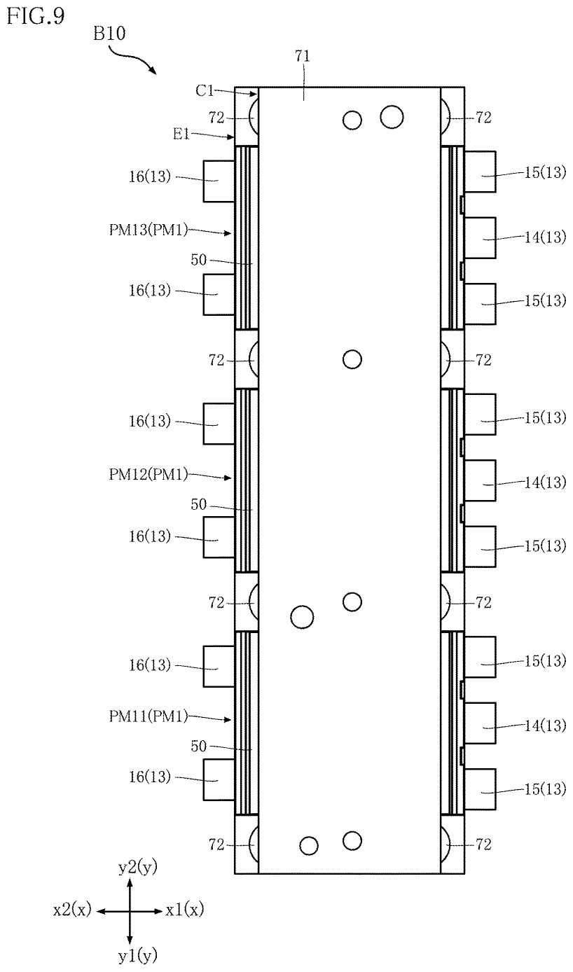

Power Conversion Unit B10 (Intelligent Power Module A10): Exemplary Configuration:
FIGS. 2 to 17 illustrate an exemplary configuration of a power conversion unit B10 that includes the intelligent power module A10. The power conversion unit B10 includes a plurality of intelligent power modules A10 (a plurality of module sections PM1 and a plurality of drive circuit sections DR1), a mounting object C1, a mounting member D1, and a wiring board E1. In the illustrated example, the power conversion unit B10 includes three intelligent power modules A10 (three module sections PM1 and three drive circuit sections DR1), but the number of the intelligent power modules A10 is not limited. In other words, the power conversion unit B10 may include a single intelligent power module A10, two intelligent power modules A10, or four or more intelligent power modules A10.

The following description is given with reference to three mutually perpendicular directions, namely a first direction z, a second direction x, and a third direction y. The first direction z corresponds to the thickness direction of the power conversion unit B10. Note that “in plan view” refers to a view as seen in the first direction z. The second direction x is perpendicular to the first direction z. The third direction y is perpendicular to the first direction z and the second direction x. One side along the second direction x is referred to as the x1 side in the second direction x, and the other side along the second direction x is referred to as the x2 side in the second direction x. One side along the third direction y is referred to as the y1 side in the third direction y, and the other side along the third direction y is referred to as the y2 side in the third direction y. One side along the first direction z is referred to as the z1 side in the first direction z, and the other side along the first direction z is referred to as the z2 side in the first direction z. The z1 side in the first direction z may be referred to also as an upper side, and z2 side in the first direction z as a lower side. Note that the terms such as “top”, “bottom”, “upward”, “downward”, “upper surface”, “lower surface”, and the like are used to describe the relative positions of components along the first direction z, and not necessarily describe their positions with respect to the direction of gravity.

As shown in FIGS. 2 to 4, 7, and 9 to 13, the module sections PM1 are arranged along the third direction y. Each module section PM1 includes a plurality of semiconductor elements 21 and 22 and has the circuit configuration shown in FIG. 1. That is, each module section PM1 may constitute, for example, a half-bridge switching circuit. Each module section PM1 includes a plurality of power terminals 13, a plurality of signal terminals 17, and a sealing resin 50. In each module section PM1, the semiconductor elements 21 and 22 are covered with the sealing resin 50. Each power terminal 13 protrudes from one of the side surfaces (either a side surface 531 or 532, described below) of the sealing resin 50 in the second direction x. Each signal terminal 17 protrudes from the upper surface (top surface 51 described later) of the sealing resin 50 in the first direction z. The exemplary configuration of a module section PM1 will be described.

In the illustrated example, the power conversion unit B10 includes three module sections PM1. In the following description, the three module sections PM1, when distinguished, may be referred to as a first module section PM11, a second module section PM12, and a third module section PM13. The first module section PM11 is the outermost one on the y1 side in the third direction y among the plurality of module sections PM1. The third module section PM13 is the outermost one on the y2 side in the third direction y among the plurality of module sections PM1.

As shown in FIGS. 2 to 4, the mounting object C1 supports the plurality of module sections PM1. The mounting object C1 is, for example, a heat sink. The mounting object C1 is not limited to a heat sink, and may be a housing (such as a frame) of an electronic device or an electric vehicle, instead of a heat sink. The majority of the mounting object C1 is located below the plurality of module sections PM1 in the first direction z (on the z2 side). The mounting object C1 faces the lower surfaces (the bottom surfaces 52 described later) of the sealing resins 50 of the module sections PM1. The material of the mounting object C1 includes, for example, aluminum. The material is not limited to aluminum, and may be other metal or resin materials (preferably those with high thermal conductivity). The mounting object C1 includes a main body 71, a plurality of pedestal portions 72, and a plurality of positioning portions 73.

The main body 71 is a plate member. The module sections PM1 are mounted on the main body 71. As shown in FIGS. 2 to 4, 7, and 10 to 13, the plurality of module sections PM1 are arranged on the main body 71 along the third direction y. The main body 71 faces the lower surfaces (the bottom surfaces 52 described later) of the sealing resins 50 of the module sections PM1. The main body 71 is in contact with each module section PM1. The main body 71 is, for example, rectangular in plan view.

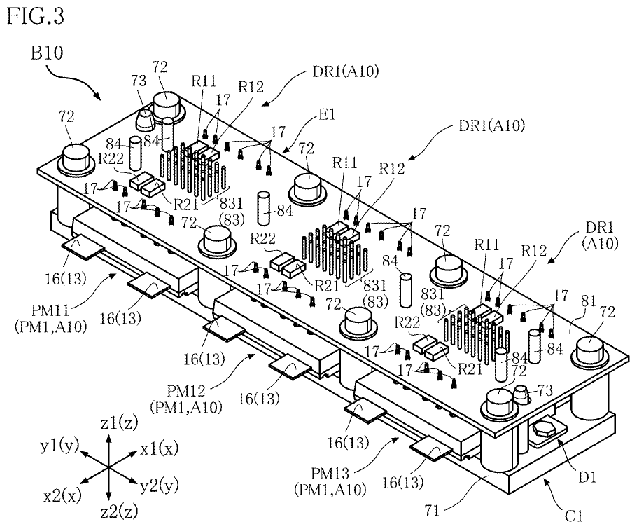

As shown in FIGS. 3, 4, 7, 8, and 10 to 13, each pedestal portion 72 protrudes upward in the first direction z from the main body 71. In the illustrated example, the pedestal portions 72 are integrally formed with the main body 71, but they may alternatively be separate components attached to the main body 71.

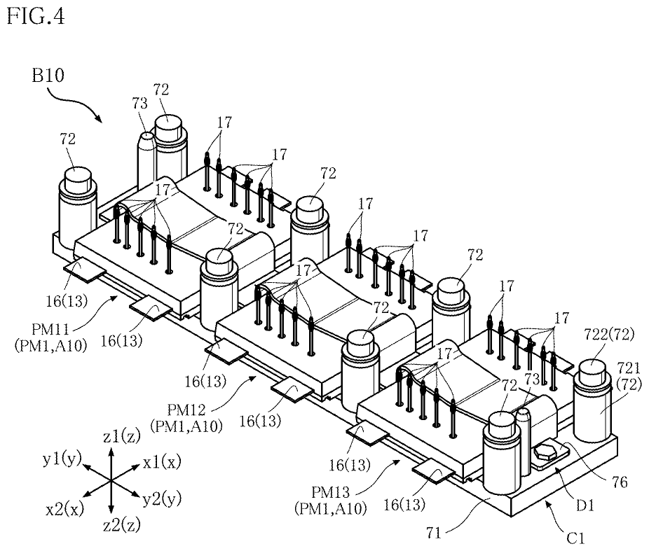

As shown in FIGS. 4, 12, and 13, each pedestal portion 72 includes a first portion 721 and a second portion 722. The first portion 721 is interposed between the wiring board E1 (the circuit board 81 described later) and the main body 71 in the first direction z. The dimension of the first portion 721 in the first direction z is greater than the dimension of the sealing resin 50 of each module section PM1 in the first direction z. The second portion 722 is disposed on the first portion 721. The wiring board E1 (the circuit board 81 described later) is sandwiched between the first portion 721 and the second portion 722. With this configuration, the wiring board E1 is held a predetermined distance apart from the upper surface of the main body 71.

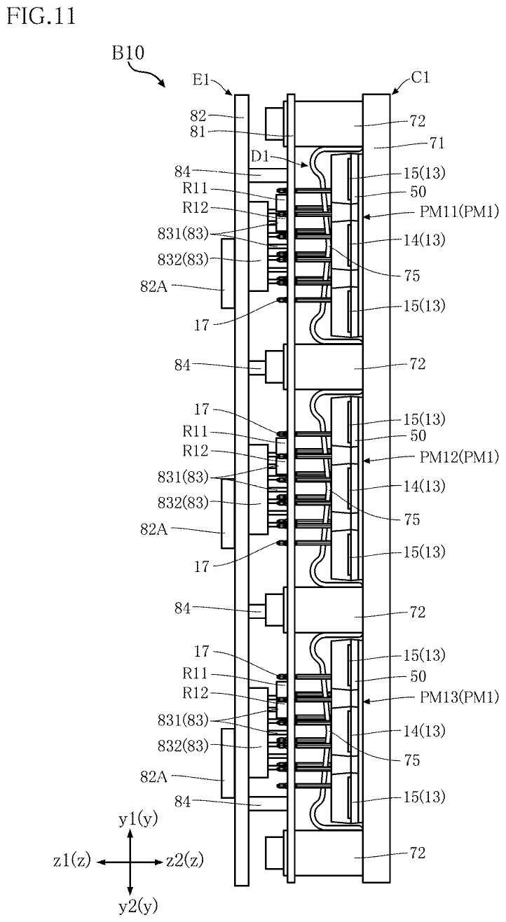

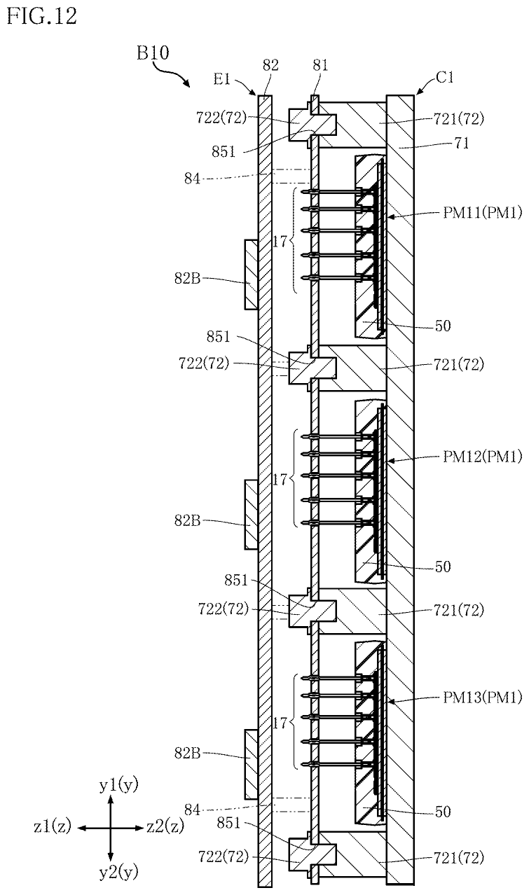

In the illustrated example, as shown in FIG. 12, the first portion 721 includes an internally threaded recess, and the second portion 722 includes an externally threaded projection. The second portion 722 is fastened to the first portion 721 by inserting the external thread (the projection) of the second portion 722 into the internal thread (the recess) of the first portion 721. Each pedestal portion 72 may have a different configuration, provided that the first portion 721 and the second portion 722 fit together. For example, the second portion 722 may be press-fitted into the first portion 721. In another example, the first portion 721 may have a projection, and the second portion 722 may have a recess.

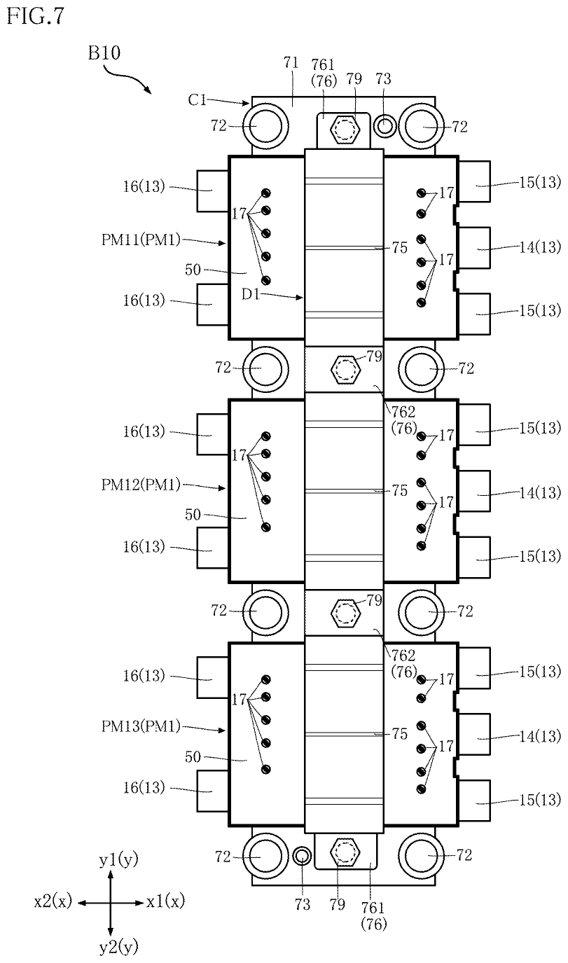

As shown in FIGS. 3, 4, 6, and 7, each positioning portion 73 protrudes upward in the thickness direction z from the main body 71. In the present embodiment, each positioning portion 73 is a separate component attached to the main body 71. In a different example, each positioning portion 73 may be formed integrally with the main body 71. Each positioning portion 73 is, for example, press-fitted into a through-hole formed in the main body 71. Each positioning portion 73 has a columnar shape with a tapered end on the z1 side in the first direction z. In the illustrated example, each positioning portion 73 has a smaller diameter than each pedestal portion 72 in plan view. As shown in FIG. 7, the plurality of positioning portions 73 include one located on the y1 side in the third direction y from the first module section PM11, and one located on the y2 side in th third direction y from the third module section PM13. The mounting member D1 holds the module sections PM1 against the mounting object

C1. The mounting member D1 is, for example, a leaf spring. The mounting member D1 elastically presses the module sections PM1 against the mounting object C1. The material of the mounting member D1 is not particularly limited and may be copper, iron, titanium, or an alloy of such metals (including stainless steel, for example). As shown in FIGS. 4, 7, and 13, the mounting member D1 includes a plurality of pressing portions 75 and a plurality of fixed portions 76.

The pressing portions 75 are provided for the respective module sections PM1. Each pressing portion 75 is in contact with the sealing resin 50 (the top surface 51) of the corresponding module section PM1. Each pressing portion 75 presses the contacting module section PM1 against the main body 71 of the mounting object C1.

The fixed portions 76 are secured to the mounting object C1 or to the main body 71 in the present embodiment. Each fixed portion 76 is, for example, a flat-plate that is parallel to the x-y plane. Each fixed portion 76 has a through-hole. The through-hole is for insertion of a fastener 79 (a hexagon head bolt in the illustrated example). The fixed portion 76 is secured to the main body 71 by the fastener 79.

The fixed portions 76 include a plurality of end-position portions 761 and a plurality of intermediate-position portions 762. In the power conversion unit B10, the fixed portions 76 include a pair of end-position portions 761 and two intermediate-position portions 762. As shown in FIGS. 7 and 13, one of the end-position portions 761 is located on the y1 side in the third direction y from the first module section PM11, and the other end-position portion 761 is located on the y2 side in the third direction y from the third module section PM13. One of the intermediate-position portions 762 is located between the first module section PM11 and the second module section PM12, and the other intermediate-position portion 762 is positioned between the second module section PM12 and the third module section PM13.

In the example shown in FIG. 7, the width (the dimension in the second direction x) of each end-position portion 761 is narrower than the width (the dimension in the second direction x) of each pressing portion 75 as well as the width (the dimension in the second direction x) of each intermediate-position portion 762. This configuration prevents interference between the mounting member D1 (the end-position portions 761) and the positioning portions 73. In a different example, the pressing portions 75 and the intermediate-position portions 762 may have the same (or substantially the same) width as the end-position portions 761. In this case, the mounting member D1 has a rectangular shape (band shape) in plan view. In another example, the intermediate-position portions 762 may have the same (or substantially the same) width as the end-position portions 761.

The wiring board E1 is a component on which the drive circuit sections DR1 are mounted. In the present embodiment, the wiring board E1 includes two circuit boards 81 and 82, a plurality of interconnect wirings 83, and a plurality of positioning pins 84. The circuit board 81 is an example of the “first circuit board” recited in the claims, and the circuit board 82 is an example of the “second circuit board” recited in the claims.

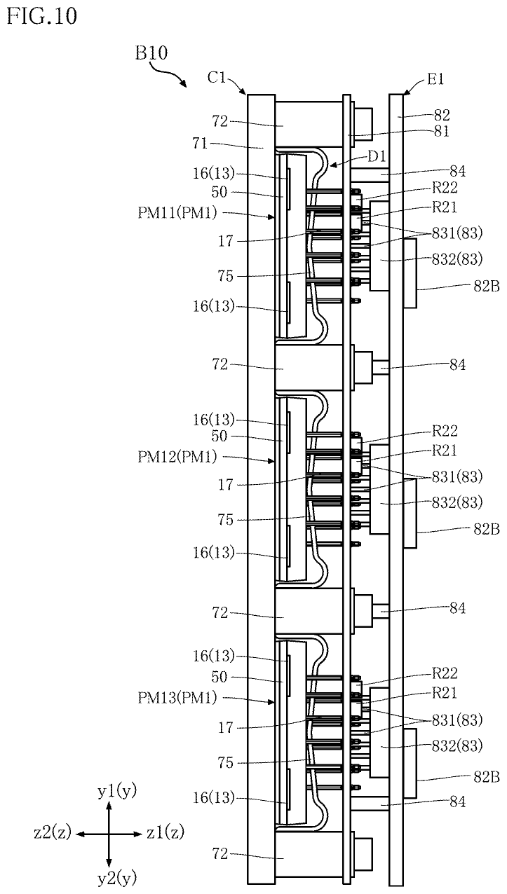

As shown in FIGS. 3, 6, and 10 to 13, the circuit board 81 is commonly provided for the plurality of module sections PM1. In contrast to this configuration, a plurality of circuit boards 81 may be provided for the respective module sections PM1. The circuit board 81 faces the upper surface (the top surface 51) of the sealing resin 50 of each module section PM1. The circuit board 81 is positioned on the side opposite the main body 71 of the mounting object C1 with respect to the plurality of module sections PM1. In plan view, the circuit board 81 overlaps with the sealing resins 50 of the module sections PM1. The circuit board 81 is supported by the pedestal portions 72 with a predetermined distance from the main body 71 in the first direction z. As can be seen from FIGS. 10 and 11, each signal terminal 17 of the module sections PM1 extends through the circuit board 81. The circuit board 81 is electrically connected to each signal terminal 17. In the present embodiment, a plurality of resistors R11, R12, R21, and R22 are mounted on the circuit board 81. The resistors R11, R12, R21, and R22 are mounted on the upper surface (the surface facing upward in the first direction z) of the circuit board 81. That is, the resistors R11, R12, R21, and R22 are disposed on a surface of the circuit board 81 opposite the surface facing the module sections PM1. Additionally, an overheat protection circuit (a protection circuit electrically connected to a pair of thermistors TH of each module sections PM1), a surge voltage protection circuit, an active mirror circuit, and the like may be mounted on the circuit board 81. These additional circuits may be disposed on, for example, the upper surface of the circuit board 81.

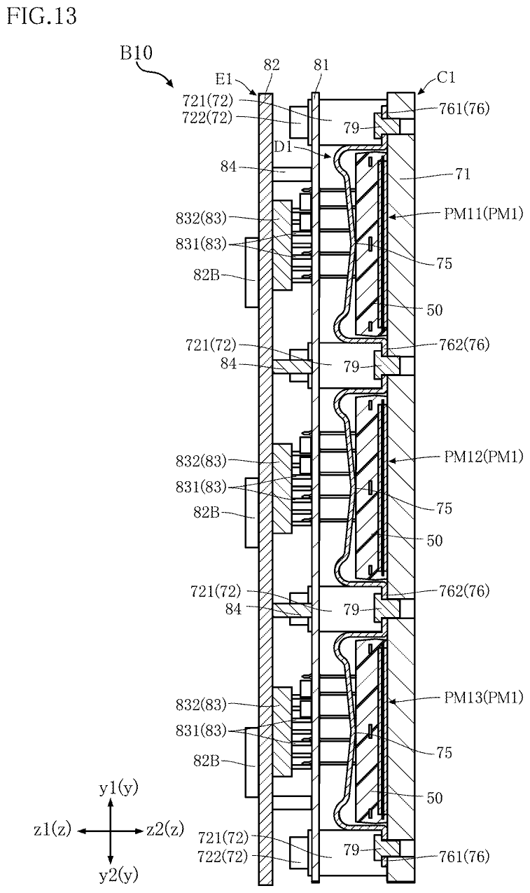

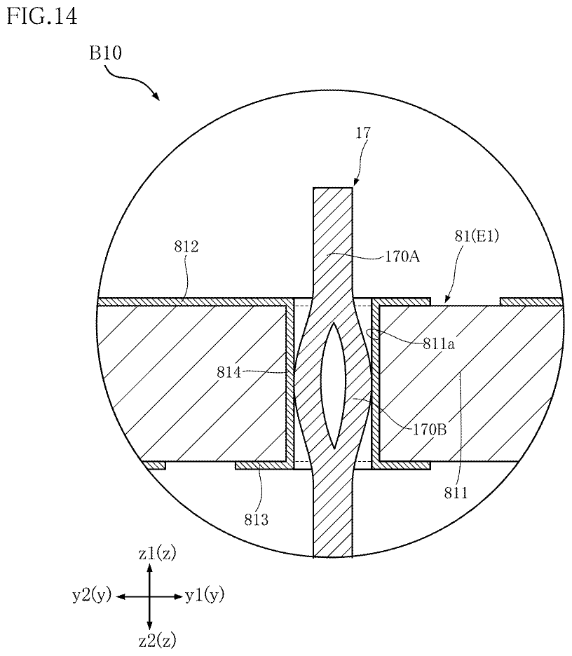

As shown in FIG. 14, the circuit board 81 includes a base material 811, a front-side wiring 812, a rear-side wiring 813, and inner wiring 814. The base material 811 has a plurality of through-holes 811a extending in the first direction z. The front-side wiring 812 is formed on the upper surface (the surface facing the z1 side in the first direction z) of the base material 811. The rear-side wiring 813 is formed on the lower surface (the surface facing the z2 side in the first direction z) of the base material 811. The inner wiring 814 is disposed on the inner surfaces of the through-holes 811a. The inner wiring 814 is continuous with the front-side wiring 812 and the rear-side wiring 813. The front-side wiring 812 forms a conductive path that electrically connects the rear-side wiring 813 and the inner wiring 814 to the circuits (e.g., resistors R11, R12, R21, and R22) provided on the circuit board 81.

Each signal terminal 17 of the plurality of module sections PM1 extends through a corresponding through-hole 811a in the circuit board 81. FIG. 14 shows a signal terminal 17 of the module sections PM1 that extends through a through-hole 811a in the base material 811. All of the signal terminals 17 of the module sections PM1 extend through the corresponding through-holes 811a in the base material 811, as shown in FIG. 14.

As shown in FIG. 14, each signal terminal 17 includes a base portion 170A and a bulging portion 170B. One end of the base portion 170A in the first direction z is press-fitted into one of a plurality of sleeves 64 (described later) of the module sections PM1. The bulging portion 170B is positioned on one side (z1 side) in the first direction z from the base portion 170A. The bulging portion 170B is enlarged in a direction perpendicular to the first direction z.

As shown in FIG. 14, each signal terminal 17 is press-fitted into one of the through-holes 811a in the circuit board 81. This brings the bulging portion 170B of the signal terminal 17 into contact with the inner wiring 814 disposed inside the corresponding through-hole 811a. That is, each signal terminal 17 press-fitted into a through-hole 811a in the first direction z is electrically connected to the circuit board 81. The circuit board 81 is supported by the signal terminals 17 that are press-fitted into the corresponding through-holes 811a. In contrast to this configuration, each signal terminal 17 may consist only of a base portion 170A and include no bulging portion 170B. In short, each signal terminal 17 may be a straight pin with no variation in diameter. In this case, each signal terminal 17 is inserted through a through-hole 811a and then soldered to the circuit board 81.

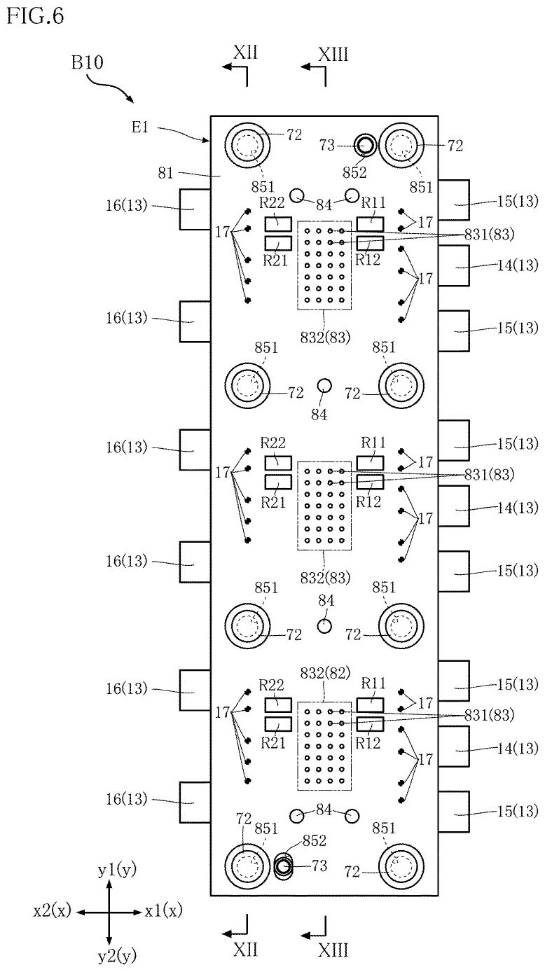

As shown in FIGS. 6 and 12, the circuit board 81 includes a plurality of mounting holes 851 and a plurality of positioning holes 852.

As shown in FIGS. 6 and 12, each mounting hole 851 receives a corresponding pedestal portion 72 (e.g., the second portion 722). Each mounting hole 851 has a perfectly circular shape in plan view. The diameter of each mounting hole 851 in plan view is smaller than the diameter of each pedestal portion 72 (the first portion 721, in particular) in plan view. Thus, the circuit board 81 is held above the first portion 721 in the first direction z (the z1 side).

As shown in FIG. 6, each positioning hole 852 receives a corresponding positioning portion 73. In the illustrated example, the circuit board 81 has two positioning holes 852. One of the two positioning holes 852 (the positioning hole 852 on the y1 side in the third direction y) is perfectly circular, whereas the other positioning hole 852 (the positioning hole 852 on the y2 side in the third direction y) is slotted. This facilitates positioning of the circuit board 81 relative to the mounting object C1. Forming one of the positioning holes 852 as a slotted hole helps absorb slight misalignment between the mounting object C1 and the circuit board caused by manufacturing tolerances.

The circuit board 82 is electrically connected to the circuit board 81 via the interconnect wirings 83. As shown in FIGS. 2, 5, and 10 to 13, the circuit board 82 extends in the third direction y. The circuit board 82 is provided with those circuits among the circuits for driving and controlling the module sections PM1 (i.e., the drive circuit sections DR1) that are not provided on the circuit board 81. In the present embodiment, the circuit board 82 is provided with one drive element 82A and one drive element 82B for each module section PM1 (in the illustrated example, three drive elements 82A and three drive elements 82B). In the first direction z, the circuit board 82 is disposed on the side opposite the mounting object C1 (the main body 71) with the circuit board 81 between them. As viewed in the first direction z, the two circuit boards 81 and 82 overlap with each other.

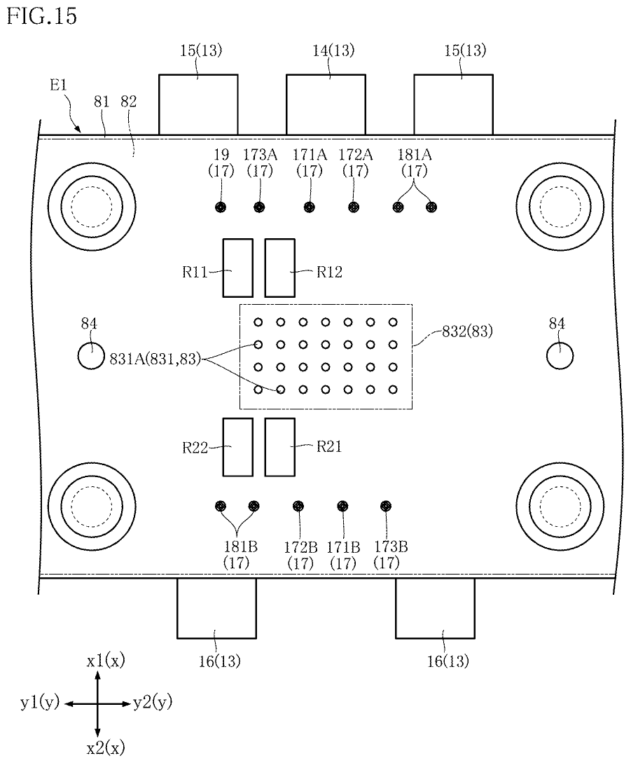

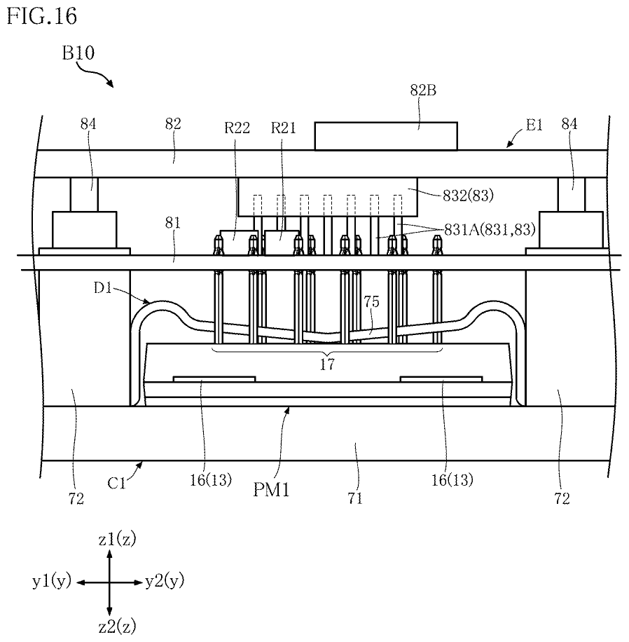

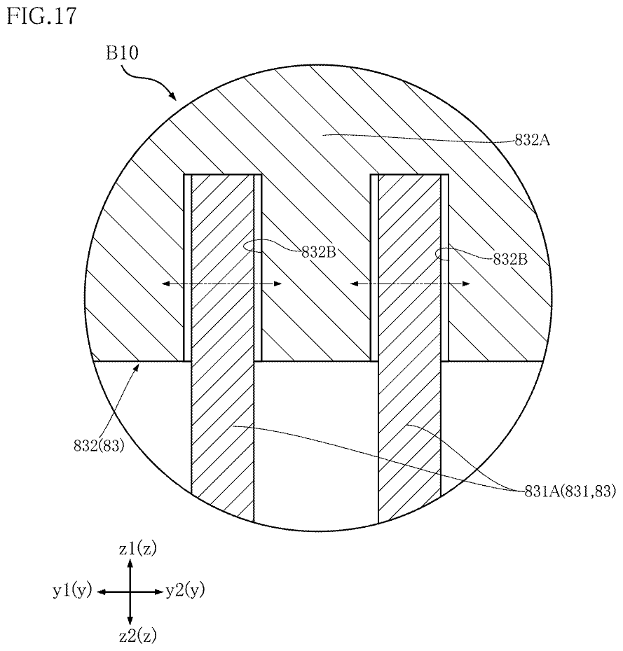

As shown in FIG. 16, the interconnect wirings 83 electrically connect the two circuit boards 81 and 82. In the power conversion unit B10, each interconnect wiring 83 includes a pair of connection portions 831 and 832. As shown in FIGS. 15 and 16, the connection portion 831 is electrically bonded to the circuit board 81. As shown in FIGS. 15 and 16, the connection portion 831 includes a plurality of connection pins 831A. The connection pins 831A extend in the first direction z. As shown in FIG. 16, the connection portion 832 is electrically bonded to the circuit board 82 and faces the connection portion 831. As shown in FIG. 17, the connection portion 832 includes a housing 832A and a plurality of connection holes 832B. The connection pins 831A are inserted into the corresponding connection holes 832B. As a result, the connection portion 831 is electrically connected to the connection portion 832.

As shown in FIG. 17, the housing 832A of the connection portion 832 is movable relative to the connection pins 831A in a direction perpendicular to the first direction z. This allows the connection portion 832 to move relative to the connection portion 831 in a direction perpendicular to the first direction z. Thus, the interconnect wirings 83 are configured to be movable in a direction perpendicular to the first direction z. Such a configuration of the interconnect wirings 83 may use a known connector configuration disclosed in JP-A-2018-113163, JP-A-2018-63886, and JP-A-2017-139101, for example.

As shown in FIGS. 10, 11, 13, and 16, the positioning pins 84 are positioned between the two circuit boards 81 and 82 in the first direction z. The positioning pins 84 are spaced apart from each other in the third direction y. Each positioning pin 84 is positioned between two adjacent module sections PM1 in the third direction y among the plurality of module sections PM1. The positioning pins 84 are used to position the circuit board 82 relative to the circuit board 81 and also to support the circuit board 82.

### Module Section PM1: Exemplary Configuration

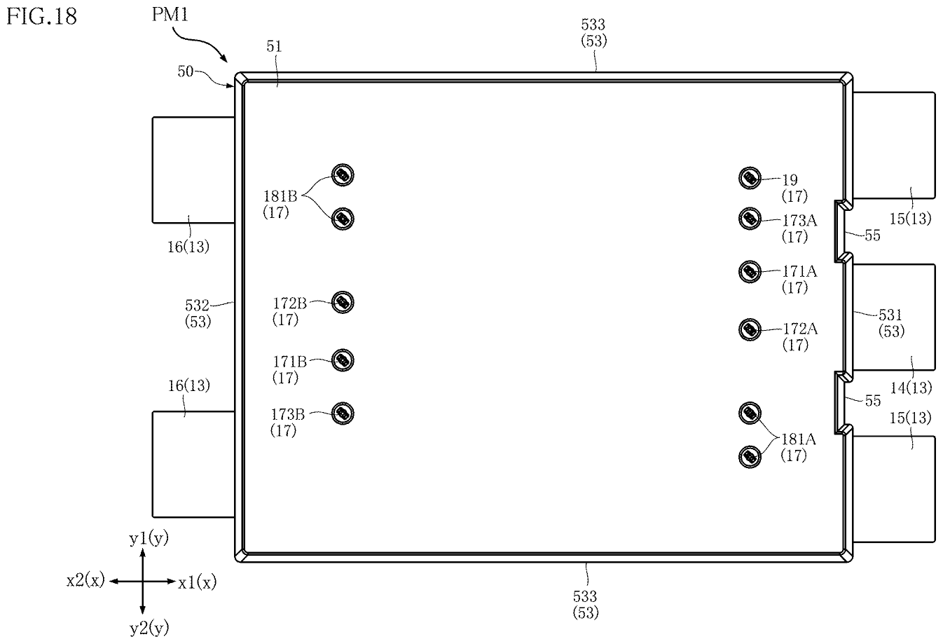

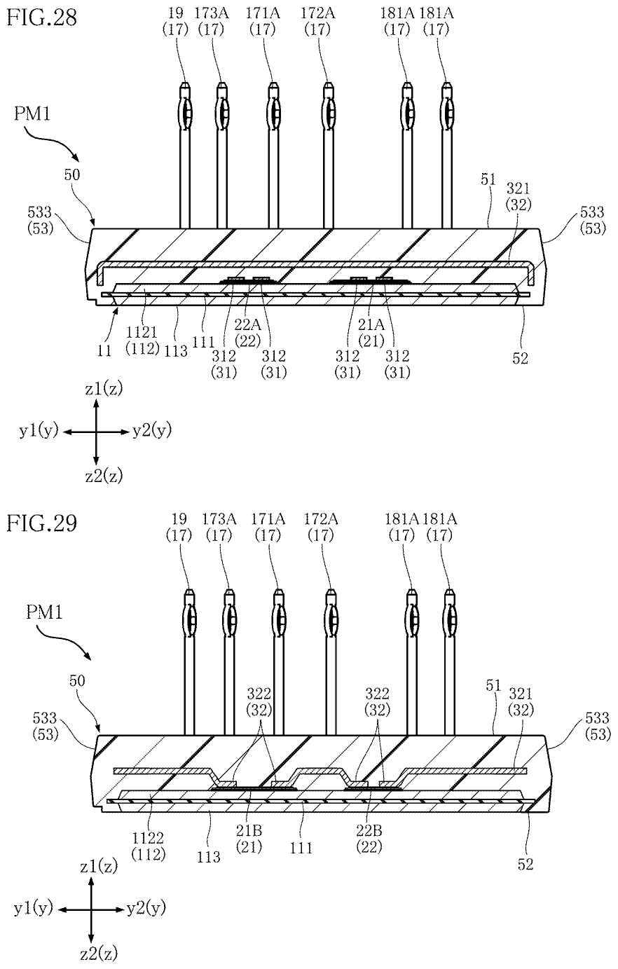

FIGS. 18 to 29 show examples of the configuration of the module sections PM1. FIGS. 18 to 28 are enlarged views of one of the module sections PM1. The plurality of module sections PM1 are identical in configuration. Unless otherwise specifically noted, the description of one module section PM1 commonly applies to the first module section PM11, the second module section PM12, and the third module section PM13.

As shown in FIGS. 18 to 29, each module section PM1 (each of the first module section PM11, the second module section PM12, and the third module section PM13) includes the power terminals 13, the signal terminals 17, the semiconductor elements 21 and 22, and the sealing resin 50 as described above. The module section PM1 additionally includes a supporting substrate 11, a pair of thermistors TH, two conductive members 31 and 32, a plurality of wires 41 to 45, and a pair of control wirings 601 and 602. The power terminals 13 include a power terminal 14, two second power terminals 15, and two power terminals 16. The signal terminals 17 include signal terminals 171A, 171B, 172A, 172B, 173A, 173B, 181A, 181B, and 19. In the present embodiment, the semiconductor elements 21 and 22 include two semiconductor elements 21A and 21B and two semiconductor elements 22A and 22B as in the circuit configuration shown in FIG. 1.

The power terminal 14 corresponds to the power terminal Tp in the circuit configuration, each of the two power terminals 15 corresponds to the power terminal Tn, and the two power terminals 16 correspond to the power terminal Tout. The module section PM1 converts the power supply voltage (e.g., DC) applied to the power terminal 14 and the two power terminals 15 into AC power using the semiconductor elements 21 and 22. The AC power thus converted is output from the two power terminals 16 to a load, such as a motor.

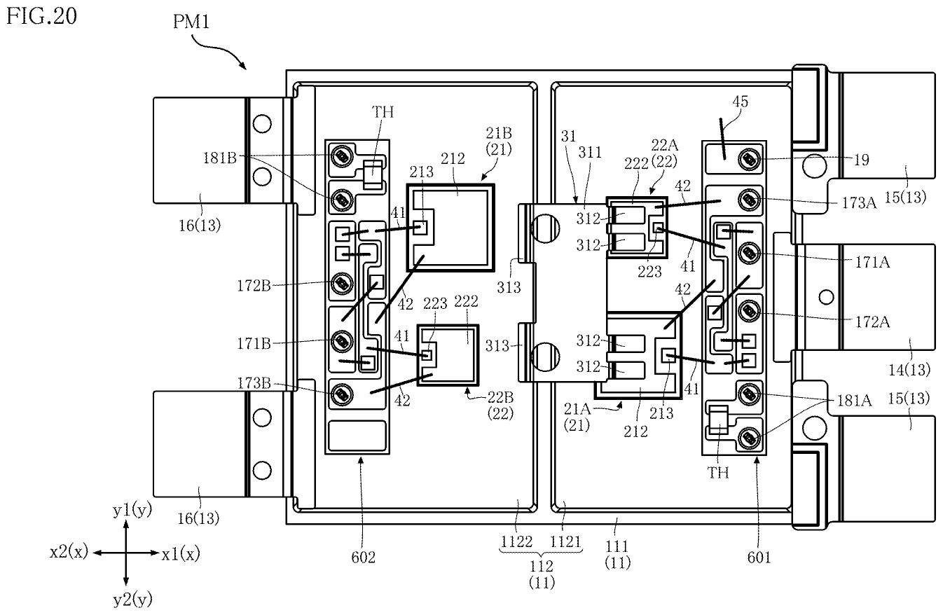

As shown in FIGS. 20, 24 to 26, 28, and 29, the supporting substrate 11 supports the semiconductor elements 21A, 21B, 22A, and 22B in the first direction z. The supporting substrate 11 may be formed with a DBC (direct bonded copper) substrate. The supporting substrate 11 includes an insulating layer 111, a wiring layer 112, and a wiring layer 113. The supporting substrate 11 is covered with the sealing resin 50, except over a portion of the wiring layer 113.

As shown in FIGS. 20 and 24 to 29, the insulating layer 111 includes regions interposed between the wiring layer 112 and the wiring layer 113 in the first direction z. The insulating layer 111 is made of a material with relatively high thermal conductivity. For example, the insulating layer 111 is made of a ceramic material, such as one containing aluminum nitride (AlN). Alternatively, the insulating layer 111 may be formed from an insulating resin sheet rather than a ceramic material.

As shown in FIGS. 20 and 24 to 29, the wiring layer 112 are positioned above the insulating layer 111 in the first direction z (the z1 side). The composition of the wiring layers 112 includes copper (Cu). As shown in FIG. 20, the wiring layer 112 is surrounded by the peripheral edge of the insulating layer 111 in plan view. As shown in FIGS. 20 and 24 to 29, the wiring layer 112 includes two mounting sections 1121 and 1122. The mounting sections 1121 and 1122 are each rectangular in plan view. The mounting sections 1121 and 1122 are spaced apart from each other in the second direction x. Each of the semiconductor elements 21A, 21B, 22A, and 22B is bonded to either of the two mounting sections 1121 and 1122.

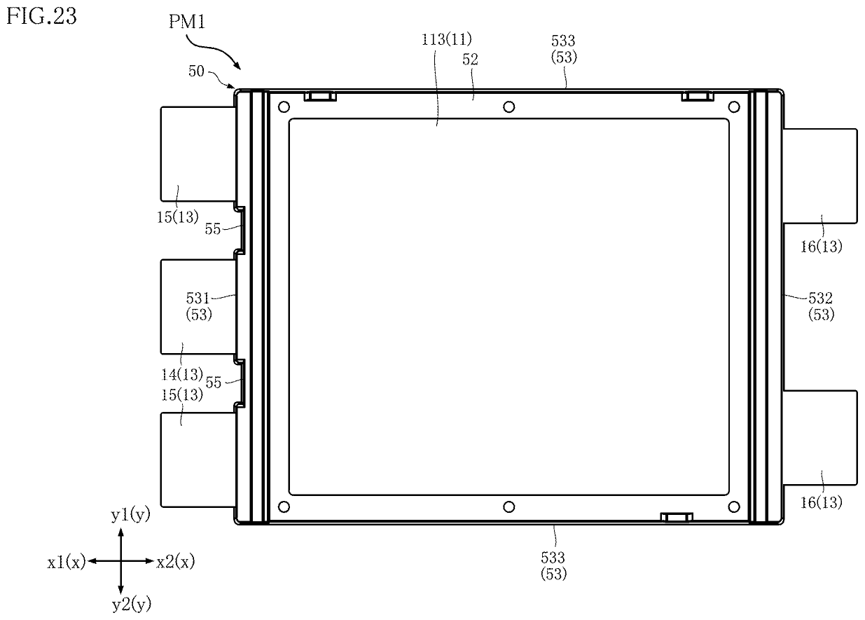

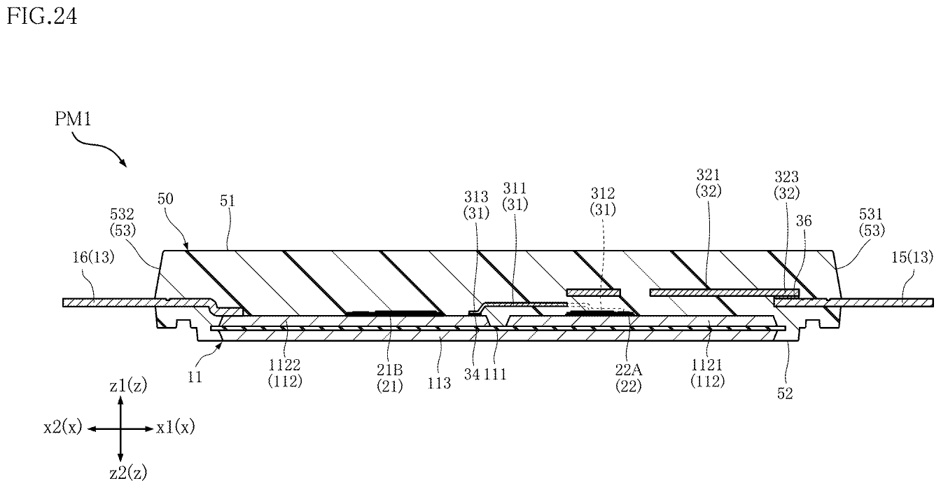

As shown in FIGS. 24 to 29, the wiring layer 113 is positioned below the insulating layer 111 in the first direction z (the z2 side). As shown in FIG. 23, the wiring layer 113 is exposed from the sealing resin 50. The wiring layer 113 is in contact with the upper surface (the surface facing the z1 side in the first direction z) of the main body 71 of the mounting object C1. The composition of the wiring layers 113 includes copper. The wiring layer 113 is rectangular in plan view. The wiring layer 113 is surrounded by the peripheral edge of the insulating layer 111 in plan view.

The semiconductor elements 21A and 22A are mounted on the mounting section 1121. The semiconductor elements 21A and 22A are arranged along the third direction y. The semiconductor elements 21B and 22B are mounted on the mounting section 1122. The semiconductor elements 21B and 22B are arranged along the third direction y.

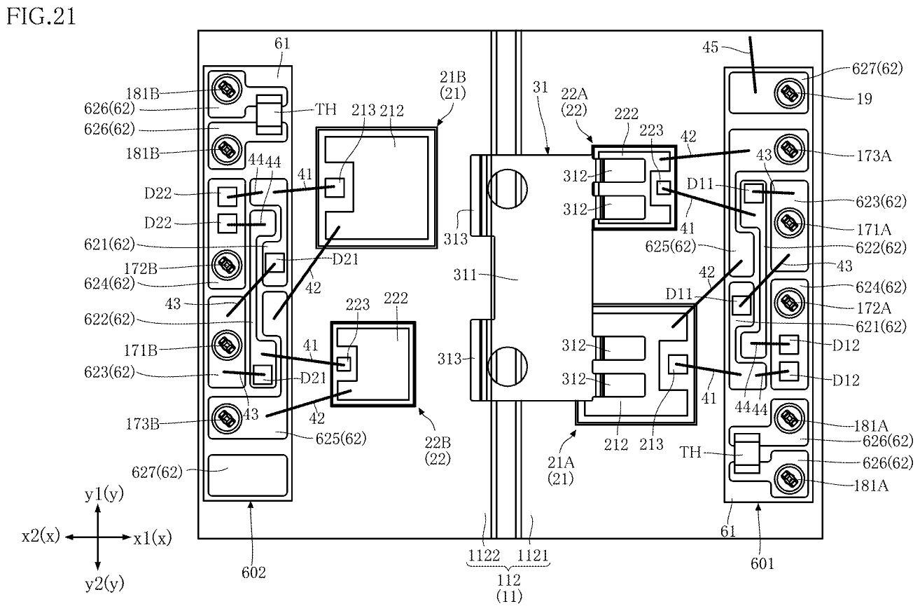

As described above, each of the two semiconductor elements 21A and 21B includes a plurality of electrodes 211, 212, and 213. In each of the semiconductor element 21A and 21B, the electrode 211 (collector electrode) is disposed on the surface facing downward in the first direction z, the electrode 212 (emitter electrode) and the electrode 213 (gate electrode) are disposed on the surface facing upward in the first direction z. The electrode 211 faces a corresponding one of the mounting sections 1121 and 1122. The electrode 211 carries the current corresponding to the power before conversion by the semiconductor element 21. The electrode 212 is positioned on the side opposite the electrode 211 in the first direction z. The electrode 212 carries the current corresponding to the power after conversion by the semiconductor element 21. The electrode 213 is positioned on the same side as the electrode 212 in the first direction z. The electrode 213 receives a drive signal (a first drive signal or a second drive signal) for driving the semiconductor element 21. As shown in FIG. 21, the electrode 213 has a smaller area than the electrode 212 in plan view.

As described above, each of the two semiconductor elements 22A and 22B includes a plurality of electrodes 221, 222, and 223. In each of the semiconductor element 22A and 22B, the electrode 221 (drain electrode) is disposed on the surface facing downward in the first direction z, the electrode 222 (source electrode) and the electrode 223 (gate electrode) are disposed on the surface facing upward in the first direction z. The electrode 221 faces a corresponding one of the mounting sections 1121 and 1122. The electrode 221 carries the current corresponding to the power before conversion by the semiconductor element 22. The electrode 222 is positioned on the side opposite the electrode 221 in the first direction z. The electrode 222 carries the current corresponding to the power after conversion by the semiconductor element 22. The electrode 223 is positioned on the same side as the electrode 222 in the first direction z. The electrode 223 receives a drive signal (a first drive signal or a second drive signal) for driving the semiconductor element 22. As shown in FIG. 21, the electrode 223 has a smaller area than the electrode 222 in plan view.

A conductive bonding layer 23 electrically bonds each of the mounting sections 1121 and 1122 to the electrode 211 of either semiconductor element 21A or 21B, and the electrode 221 of either semiconductor element 22A or 22B. FIG. 25 shows the conductive bonding layer 23 interposed between the mounting section 1121 and the electrode 221 of the semiconductor element 22A, and FIG. 26 shows the conductive bonding layer 23 interposed between the mounting section 1122 and the electrode 211 of the semiconductor element 21B. For example, the conductive bonding layer 23 is solder. In another example, the conductive bonding layer 23 may contain sintered metal particles. The electrode 211 of the semiconductor element 21A and the electrode 221 of the semiconductor element 22A are electrically bonded to the mounting section 1121 via the conductive bonding layer 23. The electrode 211 of the semiconductor element 21B and the electrode 221 of the semiconductor element 22B are electrically bonded to the mounting section 1122 via the conductive bonding layer 23.

The power terminals 13 are electrically connected to the semiconductor elements 21 and 22. The power terminals 13 carry the current corresponding to either the power before conversion by the semiconductor elements 21 and 22 (the two switching sections SW1 and SW2) or the power after conversion by the semiconductor elements 21 and 22 (the two switching sections SW1 and SW2). The power terminals 13 include a power terminal 14, two power terminals 15, and two power terminals 16. As with the power terminal Tp, the power terminal 14 is an example of the “first power terminal” recited in the claims. As with the power terminal Tn, each power terminal 15 is an example of the “second power terminal” recited in the claims. As with the power terminal Tout, each power terminal 16 is an example of the “third power terminal” recited in the claims.

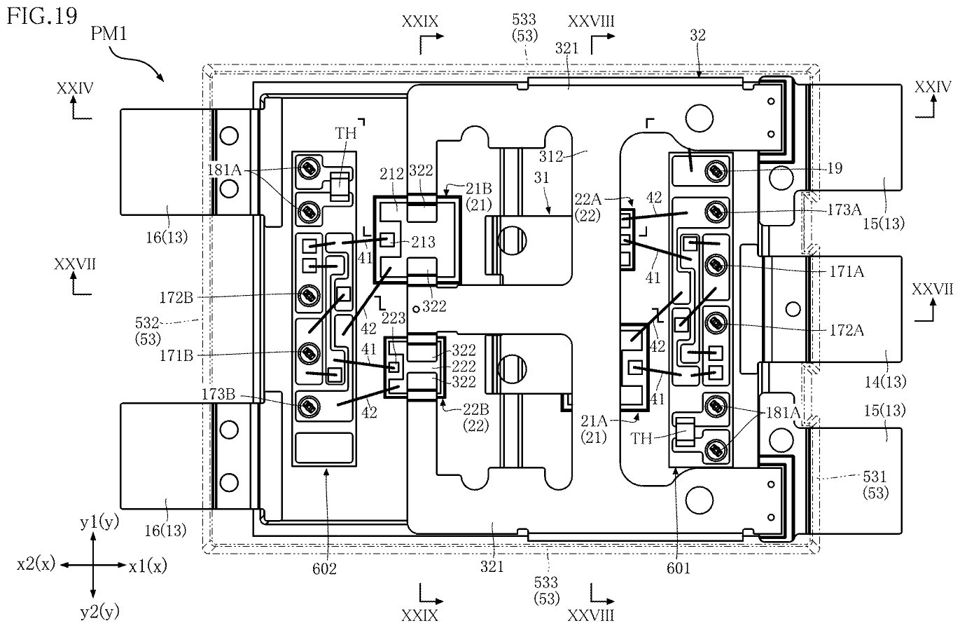

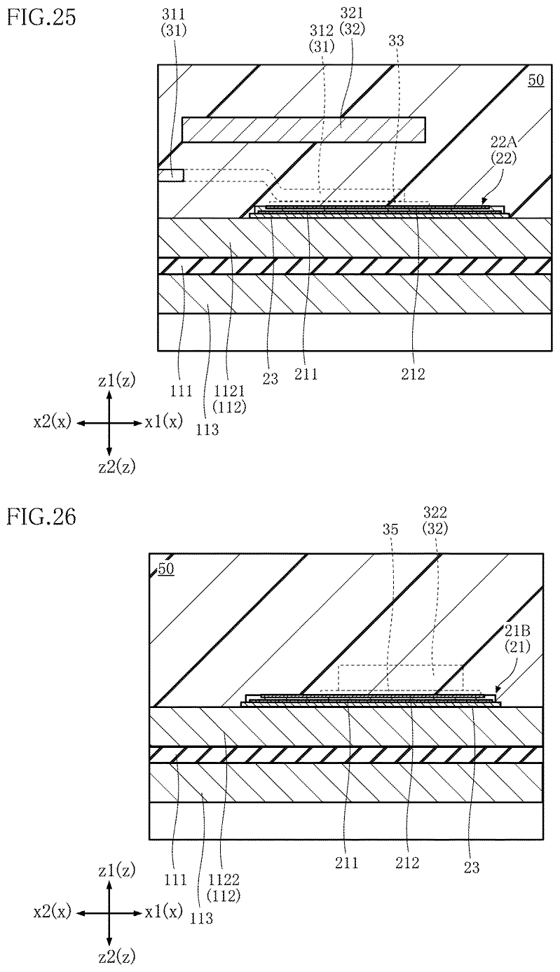

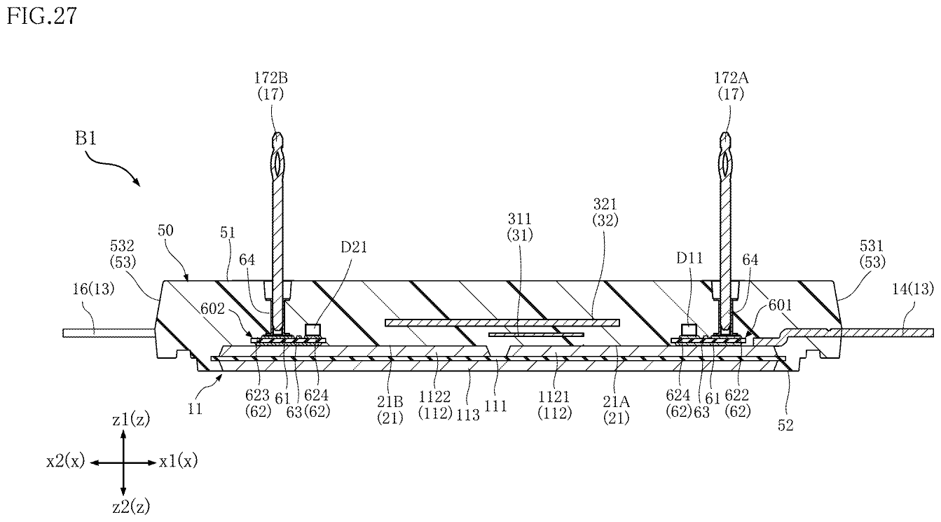

As shown in FIGS. 20 and 27, the power terminal 14 is bonded to the mounting section 1121. The method of bonding is not particularly limited, and may be performed using a conductive bonding material (e.g., solder) not shown in the figures, by laser welding, or by crimping. The power terminal 14 is electrically connected to the electrode 211 of the semiconductor element 21A and the electrode 221 of the semiconductor element 22A (i.e., to the connection end T11 of the switching section SW1) via the mounting section 1121. The power terminal 14 is a P terminal (positive terminal) to which the DC power supply voltage to be converted is applied. As shown in FIG. 20, the power terminal 14 is positioned on the side opposite the mounting section 1122 with the mounting section 1121 between them in the second direction x. The power terminal 14 extends from the mounting section 1121 toward the first side (the x1 side) in the second direction x, and protrudes from the sealing resin 50 toward the first side (the x1 side) in the second direction x. As shown in FIGS. 19 and 27, the power terminal 14 includes a portion covered with the sealing resin 50 and a portion exposed from the sealing resin 50. The portion of the power terminal 14 that is covered with the sealing resin 50 is bonded to the mounting section 1121. The portion of the power terminal 14 that is exposed from the sealing resin 50 is used as the P terminal of the module section PM1 described above.

The two power terminals 15 are bonded to the conductive member 32. The two power terminals 15 are electrically connected to the electrode 212 of the semiconductor element 21B and the electrode 222 of the semiconductor element 22B (i.e., to the connection end T22 of the switching section SW2) via the conductive member 32. The two power terminals 15 are N terminals (negative terminals) to which the DC power supply voltage to be converted is applied. The two power terminals 15 are spaced apart from each other in the third direction y. The power terminal 14 is positioned between the two power terminals 15. As shown in FIG. 20, the two power terminals 15 are positioned on the same side as the power terminal 14 in the second direction x, with respect to the mounting sections 1121 and 1122. The power terminals 15 are each spaced apart from the mounting section 1121 and 1122. Each power terminal 15 extends in the second direction x, and protrudes from the sealing resin 50 toward the first side (the x1 side) in the second direction x. As shown in FIGS. 19 and 24, each power terminal 15 includes a portion covered with the sealing resin 50 and a portion exposed from the sealing resin 50. The portion of each power terminal 15 that is covered with the sealing resin 50 is bonded to the conductive member 32. The portion of the power terminal 15 that is exposed from the sealing resin 50 is used as the N terminal of the module section PM1 described above.

As shown in FIGS. 20 and 24, the two power terminals 16 are bonded to the mounting section 1122. The method of bonding is not particularly limited, and may be performed using a conductive bonding material (e.g., solder) not shown in the figures, by laser welding, or by crimping. Each power terminal 16 is electrically connected to the electrode 211 of the semiconductor element 21B and the electrode 221 of the semiconductor element 22B (i.e., to the connection end T21 of the switching section SW2) via the mounting section 1122. Each power terminal 16 is also electrically connected to the electrode 212 of the semiconductor elements 21A and the electrode 222 of the semiconductor element 22A (i.e., to the connection end T12 of the switching section SW1) via the mounting section 1122 and the conductive member 31. The two power terminals 16 output AC power converted by the semiconductor elements 21 and 22. In short, each power terminal 16 is an AC output terminal. The two power terminals 16 are spaced apart from each other in the third direction y. As shown in FIG. 20, the two power terminals 16 are positioned on the side opposite the mounting section 1121 with the mounting section 1122 between them in the second direction x. The two power terminals 16 extend from the mounting section 1122 toward the second side (the x2 side) in the second direction x, and protrude from the sealing resin 50 toward the second side (x2 side) in the second direction x. As shown in FIGS. 19 and 24, each power terminal 16 includes a portion covered with the sealing resin 50 and a portion exposed from the sealing resin 50. The portion of each power terminal 16 that is covered with the sealing resin 50 is bonded to the mounting section 1122. The portion of each power terminal 16 that is exposed from the sealing resin 50 is used as the output terminal of the module section PM1 described above.

The pair of control wirings 601 and 602 form a portion of a conduction path that connects the signal terminals 17 and the semiconductor elements 21 and 22. The control wiring 601 is positioned between the semiconductor elements 21A and 22A on one side, and the power terminal 14 and the two power terminals 15 on the other side. As shown in FIGS. 20 and 27, the control wiring 601 is bonded to the mounting section 1121. In the second direction x, the control wiring 602 is positioned between the semiconductor elements 21B and 22B on one side, and the two power terminals 16 on the other side. As shown in FIGS. 20 and 27, the control wiring 602 is bonded to the mounting section 1122. Each of the control wirings 601 and 602 includes an insulating layer 61, a plurality of wiring layers 62, a metal layer 63, and a plurality of sleeves 64. The control wirings 601 and 602 are covered with the sealing resin 50, except over a portion of each sleeve 64. Unless otherwise specifically noted, the description of the insulating layer 61, the wiring layers 62, the metal layer 63, and the sleeves 64 given below commonly applies to both the control wirings 601 and 602.

As shown in FIG. 27, the insulating layer 61 includes regions interposed between the wiring layers 62 and the metal layer 63 in the first direction z. The insulating layer 61 is made of a ceramic material, for example. Alternatively, the insulating layer 61 may be formed from an insulating resin sheet rather than a ceramic material.

As shown in FIG. 27, the wiring layers 62 are positioned above the insulating layer 61 in the first direction z (the z1 side). The composition of the wiring layers 62 includes copper. In each of the control wirings 601 and 602, the wiring layers 62 include a plurality of wiring sections 621 to 627 spaced apart from each other as shown in FIG. 21. The shapes and locations of the wiring sections 621 to 627 are not limited to those in the illustrated example.

As shown in FIG. 27, the metal layer 63 is positioned on the side opposite the wiring layers 62 with the insulating layer 61 between them in the first direction z. The composition of the metal layer 63 includes copper. The metal layer 63 of the control wiring 601 is bonded to the mounting section 1121 via an adhesive layer not shown in the figures. The metal layer 63 of the control wiring 602 is bonded to the mounting section 1122 via an adhesive layer not shown in the figures. The material of these adhesive layers may be either conductive or non-conductive. For example, the adhesive layers may be solder.

As shown in FIG. 27, each sleeve 64 is bonded to one of the wiring sections 621 to 627 via a conductive bonding layer (such as solder) not shown in the figures. The sleeves 64 are made of a conductive material, such as metal. Each sleeve 64 has a tubular shape extending along the first direction z. Each sleeve 64 is electrically bonded to one of the wiring sections 621 to 627 at one end (the end on the z2 side in the first direction z). As shown in FIG. 27, the other end of each sleeve 64 (the end on the z1 side in the first direction z) is exposed from the sealing resin 50.

As shown in FIG. 21, one of the rectifying elements D11 is bonded to the wiring section 621 of the control wiring 601, whereas the other rectifying element D11 is bonded to the wiring section 622 of the control wiring 601. Each rectifying element D11 includes two electrodes not shown in the figures. In each rectifying element D11, the two electrodes are individually disposed on the upper and lower surfaces in the first direction z. In an example where each rectifying element D11 is a diode, the electrode on the upper surface (the upper-surface electrode) is an anode electrode, and the electrode on the lower surface (the lower-surface electrode) is a cathode electrode. In this example, the wiring sections 621 and 622 of the control wiring 601 are each electrically connected to the lower-surface electrode (the cathode electrode) of a corresponding rectifying elements D11.

As shown in FIG. 21, the pair of rectifying elements D12 are bonded to the wiring section 624 of the control wiring 601. Each rectifying element D12 includes two electrodes not shown in the figures. In each rectifying element D12, the two electrodes are individually disposed on the upper and lower surfaces in the first direction z. In an example where each rectifying element D12 is a diode, the electrode on the upper surface (the upper-surface electrode) is an anode electrode, and the electrode on the lower surface (the lower-surface electrode) is a cathode electrode. In this example, the wiring section 624 of the control wiring 601 is electrically connected to the lower-surface electrode (the cathode electrode) of each rectifying element D12.

As shown in FIG. 21, one of the rectifying elements D21 is bonded to the wiring section 621 of the control wiring 602, whereas the other rectifying element D21 is bonded to the wiring section 622 of the control wiring 602. Each rectifying element D21 includes two electrodes not shown in the figures. In each rectifying element D21, the two electrodes are individually disposed on the upper and lower surfaces in the first direction z. In an example where each rectifying element D21 is a diode, the electrode on the upper surface (the upper-surface electrode) is an anode electrode, and the electrode on the lower surface (the lower-surface electrode) is a cathode electrode. In this example, the wiring sections 621 and 622 of the control wiring 602 are each electrically connected to the lower-surface electrode (the cathode electrode) of a corresponding rectifying elements D21.

As shown in FIG. 21, the pair of rectifying elements D22 are bonded to the wiring section 624 of the control wiring 602. Each rectifying element D22 includes two electrodes not shown in the figures. In each rectifying element D22, the two electrodes are individually disposed on the upper and lower surfaces in the first direction z. In an example where each rectifying element D22 is a diode, the electrode on the upper surface (the upper-surface electrode) is an anode electrode, and the electrode on the lower surface (the lower-surface electrode) is a cathode electrode. In this example, the wiring section 624 of the control wiring 602 is electrically connected to the lower-surface electrode (the cathode electrode) of each rectifying element D22.

As shown in FIG. 21, one of the thermistors TH spans and is electrically bonded to the pair of wiring sections 626 of the control wiring 601. As shown in FIG. 21, the other thermistor TH spans and is electrically bonded to the pair of wiring sections 626 of the control wiring 602. Each thermistor TH is an NTC (negative temperature coefficient) thermistor, for example. An NTC thermistor has a resistance that gradually decreases as the temperature increases. Each thermistor TH is used as a temperature sensor for the module section PM1.

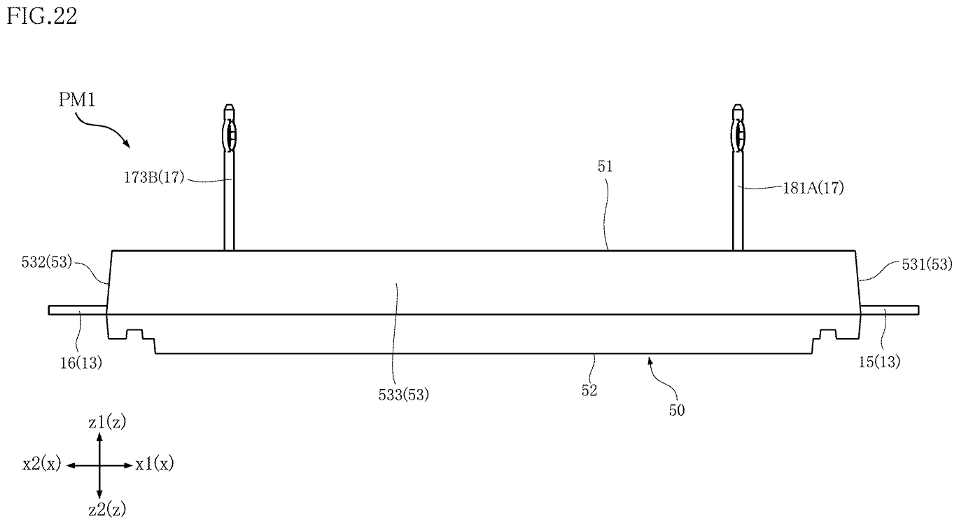

As shown in FIGS. 22 and 27, each signal terminal 17 is made with a metal pin extending in the first direction z. Each signal terminal 17 protrudes from the top surface 51 of the sealing resin 50, which will be described later. Each signal terminal 17 is press-fitted into the corresponding sleeve 64 of the control wirings 601 and 602. Thus, each signal terminal 17 is supported by the sleeve 64 and is electrically connected to a corresponding wiring layer 62 of the control wirings 601 and 602. The signal terminals 17 include a pair of signal terminals 171A and 172A, a pair of signal terminals 171B and 172B, a signal terminal 173A, a signal terminal 173B, a pair of signal terminals 181A, a pair of signal terminals 181B, and a signal terminal 19. Each of the signal terminals 171A, 172A, 171B, 172B, 173A, 173B, 181A, 181B, and 19 is inserted through the circuit board 81 and transmits a signal to and from the circuit board 81.

The signal terminal 171A is press-fitted into a sleeve 64, among the plurality of sleeves 64, that is bonded to the wiring section 623 of the control wiring 601. Thus, the signal terminal 171A is supported by the sleeve 64 and is electrically connected to the wiring section 623 of the control wiring 601. In addition, the signal terminal 171A is electrically connected to the electrode 213 of the semiconductor element 21A and the electrode 223 of the semiconductor element 22A. The signal terminal 172A is press-fitted into a sleeve 64, among the plurality of sleeves 64, that is bonded to the wiring section 624 of the control wiring 601. Thus, the signal terminal 172A is supported by the sleeve 64 and is electrically connected to the wiring section 624 of the control wiring 601. In addition, the signal terminal 172A is electrically connected to the electrode 213 of the semiconductor element 21A and the electrode 223 of the semiconductor element 22A.

The pair of signal terminals 171A and 172A receive a drive signal (first drive signal) for driving the semiconductor elements 21A and 22A. The signal terminal 171A receives a first turn-on signal, whereas the signal terminal 172A receives a first turn-off signal. The signal terminals 171A and 172A respectively correspond to the signal terminals Ton1 and Toff1 in the circuit configuration of the intelligent power module A10 (see FIG. 1).

The signal terminal 171B is press-fitted into a sleeve 64, among the plurality of sleeves 64, that is bonded to the wiring section 623 of the control wiring 602. Thus, the signal terminal 171B is supported by the sleeve 64 and is electrically connected to the wiring section 623 of the control wiring 602. In addition, the signal terminal 171B is electrically connected to the electrode 213 of the semiconductor element 21B and the electrode 223 of the semiconductor element 22B. The signal terminal 172B is press-fitted into a sleeve 64, among the plurality of sleeves 64, that is bonded to the wiring section 624 of the control wiring 602. Thus, the signal terminal 172B is supported by the sleeve 64 and is electrically connected to the wiring section 624 of the control wiring 602. In addition, the signal terminal 172B is electrically connected to the electrode 213 of the semiconductor element 21B and the electrode 223 of the semiconductor element 22B.

The pair of signal terminals 171B and 172B receive a drive signal (second drive signal) for driving the semiconductor elements 21B and 22B. The signal terminal 171B receives a second turn-on signal, whereas the signal terminal 172B receives a second turn-off signal. The signal terminals 171B and 172B respectively correspond to the signal terminals Ton2 and Toff2 in the circuit configuration of the intelligent power module A10 (see FIG. 1).

As shown in FIG. 21, the signal terminal 173A is adjacent to the signal terminal 171A in the third direction y. The signal terminal 173A is press-fitted into a sleeve 64, among the plurality of sleeves 64, that is bonded to the wiring section 625 of the control wiring 601. Thus, the signal terminal 173A is supported by the sleeve 64 and is electrically connected to the wiring section 625 of the control wiring 601. In addition, the signal terminal 173A is electrically connected to the electrode 212 of the semiconductor element 21A and the electrode 222 of the semiconductor element 22A. The signal terminal 173A receives a voltage that corresponds to the maximum current flowing through the electrode 212 of the semiconductor element 21A and the electrode 222 of the semiconductor element 22A. The signal terminal 173A corresponds to the signal terminal Tss1 in the circuit configuration of the intelligent power module A10 (see FIG. 1).

As shown in FIG. 21, the signal terminal 173B is adjacent to the signal terminal 171B in the third direction y. The signal terminal 173B is press-fitted into a sleeve 64, among the plurality of sleeves 64, that is bonded to the wiring section 625 of the control wiring 602. Thus, the signal terminal 173B is supported by the sleeve 64 and is electrically connected to the wiring section 625 of the control wiring 602. Thus, the signal terminal 173B is electrically connected to the electrode 212 of the semiconductor element 21B and the electrode 222 of the semiconductor element 22B. The signal terminal 173B receives a voltage that corresponds to the maximum current flowing through the electrode 212 of the semiconductor element 21B and the electrode 222 of the semiconductor element 22B. The signal terminal 173B corresponds to the signal terminal Tss2 in the circuit configuration of the intelligent power module A10 (see FIG. 1).

As shown in FIG. 21, the pair of signal terminals 181A are positioned on the side opposite the signal terminal 171A with the signal terminal 172A between them in the third direction y. The signal terminals 181A are adjacent to each other in the third direction y. Each signal terminal 181A is press-fitted into a corresponding one of a pair of sleeves 64 bonded to the respective wiring sections 626 of the control wiring 601. Thus, each signal terminal 181A is supported by the sleeve 64 and is electrically connected to the corresponding wiring section 626 of the control wiring 601. In addition, each signal terminal 181A is electrically connected to the thermistor TH that is disposed on the control wiring 601.

As shown in FIG. 21, the pair of signal terminals 181B are positioned on the side opposite the signal terminal 171B with the signal terminal 172B between them in the third direction y. The signal terminals 181B are adjacent to each other in the third direction y. Each signal terminal 181B is press-fitted into a corresponding one of a pair of sleeves 64 bonded to the respective wiring sections 626 of the control wiring 602. Thus, each signal terminal 181B is supported by the sleeve 64 and is electrically connected to the corresponding wiring section 626 of the control wiring 602. Also, each signal terminal 181B is electrically connected to the thermistor TH that is disposed on the control wiring 602.

As shown in FIG. 21, the signal terminal 19 is positioned on the side opposite the signal terminal 171A with the signal terminal 173A between them in the third direction y. The signal terminal 19 is press-fitted into a sleeve 64 that is bonded to the wiring section 627 of the control wiring 601. Thus, the signal terminal 19 is supported by the sleeve 64 and is electrically connected to the wiring section 627 of the control wiring 601. In addition, the signal terminal 19 is electrically connected to the mounting section 1121. The signal terminal 19 receives a voltage that corresponds to the DC power supplied to the power terminal 14.

The wires 41 to 45 electrically connect portions spaced apart from each other. The wires 41 to 45 are bonding wires. The composition of each of the wires 41 to 45 includes gold (Au). In another example, the composition of each of the wires 41 to 45 may include copper or aluminum. Note that FIGS. 24 and 27 omit the illustration of the wires 41 to 45 as necessary.

As shown in FIG. 21, one of the wires 41 is bonded to the electrode 213 of the semiconductor element 21A and to the wiring section 621 of the control wiring 601, thereby electrically connecting them. One of the wires 43 is bonded to the upper-surface electrode (anode electrode) of one of the rectifying elements D11 (the rectifying element D11 bonded to the wiring section 621 of the control wiring 601) and to the wiring section 623 of the control wiring 601, thereby electrically connecting them. Thus, the electrode 213 of the semiconductor element 21A is electrically connected to the signal terminal 171A via the corresponding one of the rectifying elements D11. In this conduction path, the electrode 213 of the semiconductor element 21A is electrically connected to the lower-surface electrode (cathode electrode) of the rectifying element D11, and the signal terminal 171A is electrically connected to the upper-surface electrode (anode electrode) of the rectifying element D11. That is, the rectifying element D11 is connected to conduct forward current from the signal terminal 171A to the electrode 213 of the semiconductor element 21A. Additionally, one of the wires 44 is bonded to the wiring section 621 of the control wiring 601 and to the upper-surface electrode (anode electrode) of one of the rectifying elements D12, thereby electrically connecting them. Thus, the electrode 213 of the semiconductor element 21A is electrically connected to the signal terminal 172A via the corresponding one of the rectifying elements D12. In this conduction path, the electrode 213 of the semiconductor element 21A is electrically connected to the upper-surface electrode (anode electrode) of the rectifying element D12, and the signal terminal 172A is electrically connected to the lower-surface electrode (cathode electrode) of the rectifying element D12. That is, the rectifying element D12 is connected to conduct forward current from the electrode 213 of the semiconductor element 21A to the signal terminal 172A.

As shown in FIG. 21, one of the wires 41 is bonded to the electrode 223 of the semiconductor element 22A and to the wiring section 622 of the control wiring 601, thereby electrically connecting them. One of the wires 43 is bonded to the upper-surface electrode (anode electrode) of the other rectifying element D11 (the rectifying element D11 bonded to the wiring section 622 of the control wiring 601) and to the wiring section 623 of the control wiring 601, thereby electrically connecting them. Thus, the electrode 223 of the semiconductor element 22A is electrically connected to the signal terminal 171A via the other rectifying elements D11. In this conduction path, the electrode 223 of the semiconductor element 22A is electrically connected to the lower-surface electrode (cathode electrode) of the rectifying element D11, and the signal terminal 171A is electrically connected to the upper-surface electrode (anode electrode) of the rectifying element D11. That is, the rectifying element D11 is connected to conduct forward current from the signal terminal 171A to the electrode 223 of the semiconductor element 22A. Additionally, one of the wires 44 is bonded to the wiring section 622 of the control wiring 601 and to the upper-surface electrode (anode electrode) of the other rectifying element D12, thereby electrically connecting them. Thus, the electrode 223 of the semiconductor element 22A is electrically connected to the signal terminal 172A via the other rectifying elements D12. In this conduction path, the electrode 223 of the semiconductor element 22A is electrically connected to the upper-surface electrode (anode electrode) of the rectifying element D12, and the signal terminal 172A is electrically connected to the lower-surface electrode (cathode electrode) of the rectifying element D12. That is, the rectifying element D12 is connected to conduct forward current from the electrode 223 of the semiconductor element 22A to the signal terminal 172A.

As shown in FIG. 21, one of the wires 41 is bonded to the electrode 213 of the semiconductor element 21B and to the wiring section 621 of the control wiring 602, thereby electrically connecting them. Another one of the wires 43 is bonded to the upper-surface electrode (anode electrode) of one of the rectifying elements D21 (the rectifying element D21 bonded to the wiring section 621 of the control wiring 602) and to the wiring section 623 of the control wiring 602, thereby electrically connecting them. Thus, the electrode 213 of the semiconductor element 21B is electrically connected to the signal terminal 171B via the corresponding one of the rectifying elements D21. In this conduction path, the electrode 213 of the semiconductor element 21B is electrically connected to the lower-surface electrode (cathode electrode) of the rectifying element D21, and the signal terminal 171B is electrically connected to the upper-surface electrode (anode electrode) of the rectifying element D21. That is, the rectifying element D21 is connected to conduct forward current from the signal terminal 171B to the electrode 213 of the semiconductor element 21B. Additionally, one of the wires 44 is bonded to the wiring section 621 of the control wiring 602 and to the upper-surface electrode (anode electrode) of one of the rectifying elements D22, thereby electrically connecting them. Thus, the electrode 213 of the semiconductor element 21B is electrically connected to the signal terminal 172B via the corresponding one of the rectifying elements D22. In this conduction path, the electrode 213 of the semiconductor element 21B is electrically connected to the upper-surface electrode (anode electrode) of the rectifying element D22, and the signal terminal 172B is electrically connected to the lower-surface electrode (cathode electrode) of the rectifying element D22. That is, the rectifying element D22 is connected to conduct forward current from the electrode 213 of the semiconductor element 21B to the signal terminal 172B.

As shown in FIG. 21, one of the wires 41 is bonded to the electrode 223 of the semiconductor element 22B and to the wiring section 622 of the control wiring 602, thereby electrically connecting them. One of the wires 43 is bonded to the upper-surface electrode (anode electrode) of the other rectifying element D21 (the rectifying element D21 bonded to the wiring section 622 of the control wiring 602) and to the wiring section 623 of the control wiring 602, thereby electrically connecting them. Thus, the electrode 223 of the semiconductor element 22B is electrically connected to the signal terminal 171B via the other rectifying element D21. In this conduction path, the electrode 223 of the semiconductor element 22B is electrically connected to the lower-surface electrode (cathode electrode) of the rectifying element D21, and the signal terminal 171B is electrically connected to the upper-surface electrode (anode electrode) of the rectifying element D21. That is, the rectifying element D21 is connected to conduct forward current from the signal terminal 171B to the electrode 223 of the semiconductor element 22B. Additionally, one of the wires 44 is bonded to the wiring section 622 of the control wiring 602 and to the upper-surface electrode (anode electrode) of the other rectifying element D22, thereby electrically connecting them. Thus, the electrode 223 of the semiconductor element 22B is electrically connected to the signal terminal 172B via the other rectifying element D22. In this conduction path, the electrode 223 of the semiconductor element 22B is electrically connected to the upper-surface electrode (anode electrode) of the rectifying element D22, and the signal terminal 172B is electrically connected to the lower-surface electrode (cathode electrode) of the rectifying element D22. That is, the rectifying element D22 is connected to conduct forward current from the electrode 223 of the semiconductor element 22B to the signal terminal 172B.

One of the wires 42 is bonded to the electrode 212 of the semiconductor element 21A and to the wiring section 625 of the control wiring 601, thereby electrically connecting them. One of the wires 42 is bonded to the electrode 222 of the semiconductor element 22A and to the wiring section 625 of the control wiring 601, thereby electrically connecting them. Thus, the electrode 212 of the semiconductor element 21A and the electrode 222 of the semiconductor element 22A are each electrically connected to the signal terminal 173A.

One of the wires 42 is bonded to the electrode 212 of the semiconductor element 21B and to the wiring section 625 of the control wiring 602, thereby electrically connecting them. One of the wires 42 is bonded to the electrode 222 of the semiconductor element 22B and to the wiring section 625 of the control wiring 602, thereby electrically connecting them. Thus, the electrode 212 of the semiconductor element 21B and the electrode 222 of the semiconductor element 22B are each electrically connected to the signal terminal 173B.

The wire 45 is bonded to the wiring section 627 of the control wiring 601 and to the mounting section 1121, thereby electrically connecting them. Thus, the signal terminal 19 is electrically connected to the electrode 211 of the semiconductor element 21A and the electrode 221 of the semiconductor element 22A.

As shown in FIGS. 20, 21, and 24, the conductive member 31 is electrically bonded to the electrode 212 of the semiconductor element 21A, the electrode 222 of the semiconductor element 22A, and the mounting section 1122. Thus, the electrode 212 of the semiconductor element 21A and the electrode 222 of the semiconductor element 22A are electrically connected to the mounting section 1122. The composition of the conductive member 31 includes copper. The conductive member 31 is what is known as a metal clip. The conductive member 31 includes a main body 311, a plurality of bonding portions 312, and a plurality of bonding portions 313.

The main body 311 forms the major part of the conductive member 31. As shown in FIGS. 20 and 21, the main body 311 extends in the second direction x. As shown in FIGS. 20, 21, and 24, the main body 311 spans the gap between the mounting sections 1121 and 1122. In the example shown in FIGS. 20 and 21, the main body 311 has a plurality of through-holes. Each through-hole penetrates the main body 311 in the first direction z. In plan view, the through-holes overlap with the gap between the mounting sections 1121 and 1122. During the molding of the sealing resin 50, this facilitates the flow of the molten resin for forming the sealing resin 50 into the region below the main body 311 (the z2 side in the first direction z).

As shown in FIGS. 20, 21, 24, 25, and 28, each bonding portion 312 is bonded to either the electrode 212 of the semiconductor element 21A or the electrode 222 of the semiconductor element 22A. Each bonding portion 312 faces either the electrode 212 of the semiconductor element 21A or the electrode 222 of the semiconductor element 22A. In plan view, each bonding portion 312 extends from the main body 311 toward the x1 side in the second direction x. In the illustrated example, the bonding portions 312 extend from the main body 311 in a bifurcated arrangement, but such bifurcation is not required. The base end of each bonding portion 312 (the end connected to the main body 311) is bent downward in the first direction z (the z2 side in the first direction z). Thus, the distal end of each bonding portion 312 (the end remote from the main body 311) is positioned below the main body 311 in the first direction z (the z2 side in the first direction z).

As shown in FIGS. 20, 21, and 24, the bonding portions 313 are bonded to the mounting section 1122. Each bonding portion 313 faces the mounting section 1122. In plan view, each bonding portion 313 extends from the main body 311 toward the x2 side in the second direction x. The base end of each bonding portion 313 (the end connected to the main body 311) is bent downward in the first direction z (the z2 side in the first direction z). Thus, the distal end of each bonding portion 313 (the end remote from the main body 311) is positioned below the main body 311 in the first direction z (the z2 side in the first direction z).

As can be seen from FIG. 25, the module section PM1 additionally includes a plurality of conductive bonding layers 33. The plurality of conductive bonding layers 33 include one interposed between the electrode 212 of the semiconductor element 21A and the bonding portion 312 that faces the electrode 212, and one interposed between the electrode 222 of the semiconductor element 22A and the bonding portion 312 that faces the electrode 222. Each conductive bonding layer 33 electrically bonds either the electrode 212 of the semiconductor element 21A and the electrode 222 of the semiconductor element 22A to the bonding portions 312. For example, the conductive bonding layers 33 are solder. In another example, the conductive bonding layers 33 may contain sintered metal particles.

As can be seen from FIG. 24, the module section PM1 additionally includes a plurality of conductive bonding layers 34. Each conductive bonding layer 34 is interposed between one of the bonding portions 313 of the conductive member 31 and the mounting section 1122. Each conductive bonding layer 34 electrically bonds the corresponding bonding portions 313 to the mounting section 1122. For example, the conductive bonding layers 34 are solder. In another example, the conductive bonding layers 34 may contain sintered metal particles.

As shown in FIG. 19, the conductive member 32 is electrically bonded to the electrode 212 of the semiconductor element 21B, the electrode 222 of the semiconductor element 22B, and the two power terminals 15. Thus, the electrode 212 of the semiconductor element 21B and the electrode 222 of the semiconductor element 22B are electrically connected to the two power terminals 15. The composition of the conductive member 32 includes copper. The conductive member 32 is what is called a metal clip. The conductive member 32 includes a main body 321, a plurality of bonding portions 322, and a pair of bonding portions 323.

The main body 321 forms the major part of the conductive member 32. As shown in FIGS. 24 and 27 to 29, the main body 321 is parallel to the upper surfaces of the mounting sections 1121 and 1122. The main body 321 is spaced apart from the main body 311 of the conductive member 31 and also from the mounting sections 1121 and 1122.

As shown in FIGS. 26 and 29, each bonding portion 322 is bonded either to the electrode 212 of the semiconductor element 21B or to the electrode 222 of the semiconductor element 22B. Each bonding portion 322 faces either the electrode 212 of the semiconductor element 21B or the electrode 222 of the semiconductor element 22B. In plan view, each bonding portion 322 extends from the main body 321 in the second direction x. The base end of each bonding portion 322 (the end connected to the main body 321) is bent downward in the first direction z (the z2 side in the first direction z). Thus, the distal end of each bonding portion 322 (the end remote from the main body 321) is positioned below the main body 321 in the first direction z (the z2 side in the first direction z).

As shown in FIGS. 19 and 24, each bonding portion 323 is bonded to a corresponding one of the two power terminals 15. Each bonding portion 323 faces the corresponding power terminal 15.

As can be seen from FIG. 26, the module section PM1 additionally includes a plurality of conductive bonding layers 35. The plurality of conductive bonding layers 35 include one interposed between the electrode 212 of the semiconductor element 21B and the bonding portion 322 that faces the electrode 212, and one interposed between the electrode 222 of the semiconductor element 22B and the bonding portion 322 that faces the electrode 222. Each conductive bonding layer 35 electrically bonds either the electrode 212 of the semiconductor element 21B or the electrode 222 of the semiconductor element 22B to the bonding portions 322. For example, the conductive bonding layers 35 are solder. In another example, the conductive bonding layers 35 may contain sintered metal particles.

As can be seen from FIG. 24, the module section PM1 additionally includes a plurality of conductive bonding layers 36. Each conductive bonding layer 36 is interposed between one of the two power terminals 15 and a corresponding one of the bonding portions 323. Each conductive bonding layer 36 electrically bonds the power terminal 15 and the bonding portion 323. For example, the conductive bonding layers 36 are solder. In another example, the conductive bonding layers 36 may contain sintered metal particles.

As shown in FIGS. 18, 19, and 22 to 29, the sealing resin 50 covers the semiconductor elements 21 and 22, the conductive members 31 and 32, and the wires 41 to 45. The sealing resin 50 also covers a portion of each of the supporting substrate 11, the power terminals 13, and the signal terminals 17. The sealing resin 50 is electrically insulative. For example, the sealing resin 50 contains a black epoxy resin. The sealing resin 50 may be formed by molding. The sealing resin 50 includes a top surface 51, a bottom surface 52, a plurality of resin side surfaces 53, and a pair of recesses 55.

As shown in FIGS. 18, 22, 24, and 27 to 29, the top surface 51 faces the same side as the upper surface of the mounting sections 1121 and the upper surface of the mounting section 1122 in the first direction z. The top surface 51 of each module section PM1 is in contact with the mounting member D1. As shown in FIGS. 22 to 24 and 27 to 29, the bottom surface 52 faces away from the top surface 51 in the first direction z. As shown in FIGS. 23, 24, and 27 to 29, the wiring layer 113 of the supporting substrate 11 is exposed at the bottom surface 52. The bottom surface 52 of each module section PM1 is in contact with the main body 71 of the mounting object C1.

Each resin side surface 53 is connected to the top surface 51. The plurality of resin side surfaces 53 include a pair of side surfaces 531 and 532, and a pair of side surfaces 533.

As shown in FIGS. 18, 19, 22, 23, 24, and 27, the side surfaces 531 and 532 are spaced apart from each other in the second direction x. The side surfaces 531 and 532 are contiguous with the top surface 51. The side surfaces 531 and 532 face away from each other in the second direction x and extend in the third direction y. The side surface 531 faces the x1 side in the second direction x, and the side surface 532 faces the x2 side in the second direction x. The power terminal 14 and the two power terminals 15 protrude from the side surface 531. The two power terminals 16 protrude from the side surface 532. The side surface 531 is an example of the “first resin side surface” recited in the claims, and the side surface 532 is an example of the “second resin side surface” recited in the claims.

As shown in FIGS. 18, 19, 23, 28, and 29, the two side surfaces 533 are spaced apart from each other in the third direction y. The two side surfaces 533 face away from each other in the third direction y and extend in the second direction x. The side surfaces 533 are contiguous with the top surface 51 and the bottom surface 52.

As shown in FIG. 18, the pair of recesses 55 are recessed from the side surface 531 in the second direction x. In the first direction z, each recess 55 extends from the top surface 51 to the bottom surface 52. The two recesses 55 are positioned on either side of the power terminal 14 in the third direction y.

The specific configuration of each module section PM1 described above is merely an example and is not limited to the example described. For example, the number of signal terminals 17, the signals input to or output from the signal terminals 17, the number of semiconductor elements 21 and 22, the configuration of the pair of control wirings 601 and 602 may be modified as appropriate. Additionally, the supporting substrate 11 may include a conductive plate bonded to the wiring layers 112 (each of the mounting sections 1121 and 1122). In this case, the semiconductor elements 21 and 22, the control wirings 601 and 602, and other appropriate components are mounted on the conductive plate.

In each module section PM1, one or more semiconductor elements 21 may have, on their upper surfaces, an additional electrode at the same potential as the electrode 212. Similarly, one or more semiconductor elements 22 may each have, on their upper surfaces, an additional electrode at the same potential as the electrode 222. In this case, each wire 42 is connected to one of the additional electrodes, rather than to the electrode 212 or 222. In other words, in each module section PM1, the semiconductor elements 21 and 22 may each include an electrode for current sensing.

### Semiconductor Element 21 (IGBT)

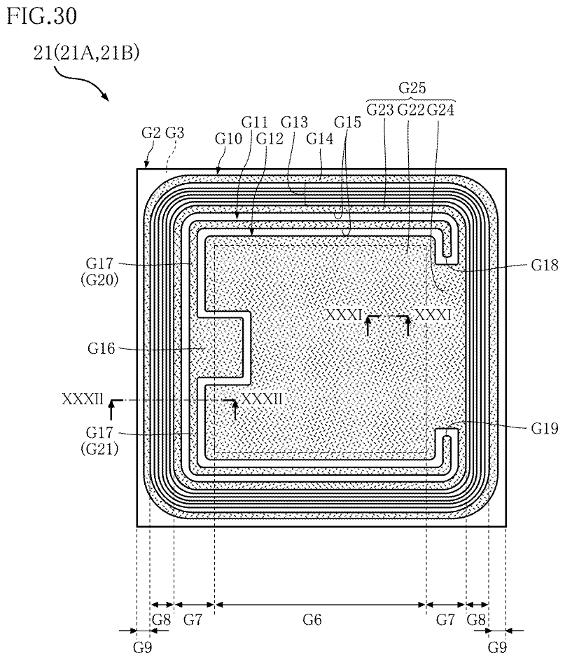

FIGS. 30 to 32 illustrate a detailed exemplary configuration of a semiconductor element 21 configured as an IGBT. Note that the example configuration shown in FIGS. 30 to 32 is merely an example and is not limited thereto.

First, the planar structure of the semiconductor element 21 will be described with reference to FIG. 30. FIG. 30 is a plan view of the semiconductor element 21.

The semiconductor element 21 includes a semiconductor layer G2 disposed on a chip having a rectangular shape in plan view. In the semiconductor layer G2, an element formation region G6, an outer region G7, a breakdown-voltage sustaining region G8, and a scribe region G9 are defined.

The element formation region G6 is the central region of the semiconductor layer G2 as viewed along the direction normal to the first main surface G3 of the semiconductor layer G2 (hereinafter “plan view”). The outer region G7 is a region outside the element formation region G6. The breakdown-voltage sustaining region G8 is a region outside the outer region G7. The scribe region G9 is a region outside the breakdown-voltage sustaining region G8.

The element formation region G6 is a region in which the IGBT (insulated gate bipolar transistor) is formed. The element formation region G6 is rectangular in plan view, with four sides parallel to the respective sides of the semiconductor layer G2 in plan view. The IGBT formed in the element formation region G6 includes a parasitic npn bipolar transistor inherent in its structure. The outer region G7 separates the element formation region G6 from another region (the breakdown-voltage sustaining region G8). The breakdown-voltage sustaining region G8 is provided to improve the withstand voltage of the semiconductor element 21. The scribe region G9 is where a cutting tool, such as a dicing blade, passes during manufacture.

A front-side electrode G10 is formed on the first main surface G3 of the semiconductor layer G2. The front-side electrode G10 includes a gate electrode G11 (corresponding to the electrode 213 described above), an emitter electrode G12 (corresponding to the electrode 212 described above), a field plate electrode G13, and an equipotential electrode G14. The gate electrode G11, the emitter electrode G12, the field plate electrode G13, and the equipotential electrode G14 are each surrounded by the insulating region G15 and thus electrically isolated.

The gate electrode G11 includes a gate pad G16 and a gate finger G17. In the present embodiment, the gate pad G16 is rectangular in plan view. The gate pad G16 extends from the outer region G7 into the element formation region G6, crossing the boundary region between the element formation region G6 and the outer region G7. The gate finger G17 extends, in the outer region G7, from the gate pad G16 to and encloses the element formation region G6 from three sides. The gate finger G17 has a pair of open ends G18 and G19. The gate finger G17 is a band-shaped portion extending from the gate pad G16 to the respective open ends G18 and the gate pad G16.

The emitter electrode G12 includes an emitter pad G22, an emitter routing portion G23, and an emitter connection portion G24. The emitter pad G22 is formed in a region having a recess in plan view and defined by the peripheral edges of the gate pad G16 and the gate finger G17. The emitter pad G22 has a peripheral portion that extends from the element formation region G6 into the outer region G7, crossing the boundary region between the element formation region G6 and the outer region G7. The emitter routing portion G23 is formed in the outer region G7. In the illustrated example, the emitter routing portion G23 has an endless-loop shape (a rectangular annular shape in plan view) that surrounds the gate finger G17. Alternatively, the emitter routing portion G23 may have an open-loop shape that surrounds the gate finger G17. The emitter connection portion G24 extends from the emitter pad G22. The emitter connection portion G24 extends across the region between the pair of open ends G18 and G19 of the gate finger G17 and is connected to the emitter routing portion G23. The emitter routing portion G23 is electrically connected to the emitter pad G22 via the emitter connection portion G24.

In the present embodiment, the emitter electrode G12, which includes the emitter pad G22, the emitter routing portion G23, and the emitter connection portion G24, forms an avalanche current collection structure G25. The avalanche current collection structure G25 collects avalanche current generated in a region outside the element formation region G6. More specifically, avalanche current generated in a region outside the element formation region G6 is collected by the emitter routing portion G23. The collected avalanche current is extracted from the emitter pad G22 via the emitter connection portion G24.

A plurality of (five in the illustrated example) field plate electrodes G13 are arranged at intervals so as to span from the outer region G7 to the scribe region G9. Each field plate electrode G13 has a band shape extending along the emitter routing portion G23.

The equipotential electrode G14 is formed in the scribe region G9. The equipotential electrode G14 has a band shape extending along the field plate electrodes G13.

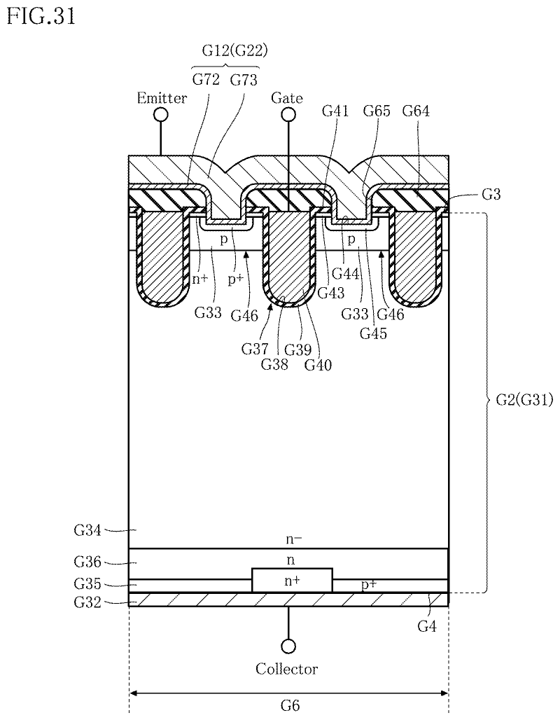

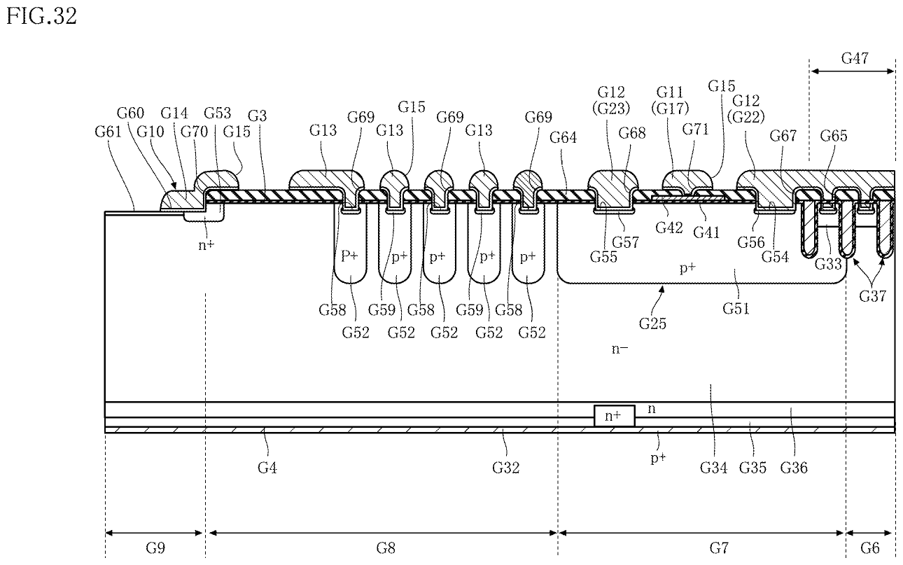

Next, the internal structure of the semiconductor element 21 will be described with reference to FIGS. 31 and 32. FIG. 31 is a sectional view taken along line XXXI-XXXI in FIG. 30. FIG. 32 is a sectional view taken along line XXXII-XXXII in FIG. 30.

The semiconductor layer G2 has a single-layer structure including an n⁻-type semiconductor substrate G31. In the present embodiment, the n⁻-type semiconductor substrate G31 is a silicon FZ (Floating Zone) substrate formed by the FZ method. A collector electrode G32 (corresponding to the electrode 211 described above), serving as a backside electrode, is connected to the second main surface G4 of the semiconductor layer G2.

In the element formation region G6, a p-type channel region G33 is formed in a surface portion of the semiconductor layer G2 near the first main surface G3. The element formation region G6 may be defined as a region surrounded by the peripheral edge of the p-type channel region G33 in plan view.

In the element formation region G6, an n⁻-type drift region G34 is formed in a region of the semiconductor layer G2 closer to the second main surface G4 with respect to the p-type channel region G33. The n⁻-type drift region G34 is electrically connected to the p-type channel region G33. The n⁻-type drift region G34 is formed by using a region of the n⁻-type semiconductor substrate G31. In addition to the element formation region G6, the n⁻-type drift region G34 is also formed in the outer region G7, the breakdown-voltage sustaining region G8, and the scribe region G9.

In the element formation region G6, a p⁺-type collector region G35 is formed in a surface portion of the semiconductor layer G2 near the second main surface G4. The p⁺-type collector region G35 is electrically connected to the collector electrode G32 at a position outside the semiconductor layer G2. The p⁺-type collector region G35 is electrically connected to the n⁻-type drift region G34 at a position within the semiconductor layer G2. In addition to the element formation region G6, the p⁺-type collector region G35 is also formed in the outer region G7, the breakdown-voltage sustaining region G8, and the scribe region G9. The p⁺-type collector region G35 is formed not only in regions facing the p-type channel region G33, but also in regions not facing the p-type channel region G33.

An n-type buffer region G36 is formed in the boundary region between the n⁻-type drift region G34 and the p⁺-type collector region G35. The n-type buffer region G36 is a high concentration and low resistance region having a higher n-type impurity concentration than the n—type drift region G34. In the illustrated example, the p⁺-type collector region G35 is electrically connected to the n⁻-type drift region G34 via the n-type buffer region G36.

In the element formation region G6, a plurality of trench gate structures G37 are formed at intervals in the first main surface G3 of the semiconductor layer G2. In the present embodiment, the trench gate structures G37 have a band shape extending in the same direction in plan view.

Each trench gate structure G37 includes a gate trench G38, a gate insulating film G39, and an embedded gate electrode G40. The gate trench G38 penetrates the p-type channel region G33 and has a bottom in the n⁻-type drift region G34. The gate insulating film G39 is formed along the inner wall surfaces of the gate trench G38. The embedded gate electrode G40 is embedded in the gate trench G38 with the gate insulating film G39 interposed between them. A surface insulating film G41 is formed on the first main surface G3 of the semiconductor layer G2, covering regions of the first main surface G3 outside the gate trench G38. The gate insulating film G39 is connected to the surface insulating film G41 at a position outside the gate trench G38.

The trench gate structures G37 include trench gate structures G37 formed near the outer region G7, as illustrated in FIG. 32. The embedded gate electrode G40 of such a trench gate structure G37 includes a gate lead-out portion G42 that extends from within the gate trench G38 toward the outer region G7.

The gate lead-out portion G42 extends from within the gate trench G38 to the region immediately beneath the gate pad G16 (not shown) and/or to the region immediately beneath the gate finger G17. FIG. 32 shows an example in which the gate lead-out portion G42 is formed in the region immediately beneath the gate finger G17. The gate lead-out portion G42 is electrically connected to the gate pad G16 and the gate finger G17. Thus, the trench gate structure G37 is electrically connected to the gate electrode G11.

Along the sides of each trench gate structure G37, an n⁺-type emitter region G43 is formed in a surface portion of the p-type channel region G33. Along the sides of each trench gate structure G37, the n⁺-type emitter region G43, the p-type channel region G33, and the n⁻-type drift region G34 are arranged in this order from the first main surface G3 toward the second main surface G4 of the semiconductor layer G2.

In the region between adjacent trench gate structures G37, a first contact recess G44 for the emitter pad G22 is formed in a surface portion of the p-type channel region G33. The first contact recess G44 is shallower than each gate trench G38 and has a bottom within the p-type channel region G33. The p-type channel region G33 is exposed relative to the first contact recess G44. The p-type channel region G33 and the n⁺-type emitter region G43 are exposed relative to the sides of the first contact recess G44.

The p-type channel region G33 includes a p⁺-type contact region G45 having a higher p-type impurity concentration than the other regions. The p⁺-type contact region G45 is formed in the p-type channel region G33 along the bottom of the first contact recess G44.

The p-type channel region G33 is shared by adjacent trench gate structures G37. The embedded gate electrode G40 faces the n⁺-type emitter region G43, the p-type channel region G33, and the n⁻-type drift region G34 across the gate insulating film G39.

The channel structure G46 of the IGBT is formed by the trench gate structure G37, the n⁺-t emitter region G43, the p-type channel region G33, and the n—type drift region G34. The channel of the IGBT is formed along the sides of the trench gate structure G37, in the p-type channel region G33 between the n⁺-type emitter region G43 and the n⁻-type drift region G34.

As shown in FIG. 32, a dummy channel structure G47 is formed in the boundary region between the element formation region G6 and the outer region G7. The dummy channel structure G47 is similar in configuration to the channel structure G46, except that the n⁺-type emitter region G43 is not included. In the dummy channel structure G47 that does not include the n⁺-type emitter region G43, no IGBT channel is formed along the sides of the trench gate structure G37.

In the boundary region between the element formation region G6 and the outer region G7, currents from inside and outside the element formation region G6 merge, and thus the current density tends to be relatively high. In the channel structure G46 of the IGBT, a parasitic npn bipolar transistor is inherently formed due to its structure, as described above. In the dummy channel structure G47 that does not include the n⁺-type emitter region G43, no parasitic npn bipolar transistor is inherently formed due to its structure. Therefore, by forming the dummy channel structure G47 in the boundary region between the element formation region G6 and the outer region G7, latch-up caused by parasitic bipolar transistor can be suppressed.

As shown in FIG. 32, in the outer region G7, a p⁺-type termination region G51 is formed in a surface portion of the semiconductor layer G2 near the first main surface G3. The p⁺-type termination region G51 defines the outer region G7. The p⁺-type termination region G51 is a high concentration and low resistance region having a higher p-type impurity concentration than the p-type channel region G33. In the thickness direction of the semiconductor layer G2, the bottom of the p⁺-type termination region G51 is located closer to the second main surface G4 of the semiconductor layer G2 than the bottom of the gate trench G38 is.

The inner edge region of the p⁺-type termination region G51 that is located on the side of the p-type channel region G33 overlaps with the bottom of the trench gate structure G37 of the dummy channel structure G47. The inner edge region of the p⁺-type termination region G51 may overlap with the bottom of the p-type channel region G33. The bottom of the p⁺-type termination region is spaced apart from the p⁺-type collector region G35 in a direction toward the first main surface G3 of the semiconductor layer G2. The p⁺-type termination region G51 faces the p⁺-type collector region G35 across a portion of the n⁻-type drift region G34. The p⁺-type termination region G51 faces the gate pad G16 and/or the gate finger G17 across the surface insulating film G41. The p⁺-type termination region G51 faces the gate lead-out portion G42 across the surface insulating film G41.

As shown in FIG. 32, in the breakdown-voltage sustaining region G8, a p⁺-type field-limit region G52 is formed in a surface portion of the semiconductor layer G2 near the first main surface G3. The p⁺-type field-limit region G52 serves to relax the electric field in the breakdown-voltage sustaining region G8. The p⁺-type field-limit region G52 has a p-type impurity concentration substantially equal to that of the p⁺-type termination region G51. The p⁺-type field-limit region G52 has a depth substantially equal to that of the p⁺-type termination region G51.

As shown in FIG. 32, in the scribe region G9, an n⁺-type channel stop region G53 is formed in a surface portion of the semiconductor layer G2 near the first main surface G3. The n⁺-type channel stop region G53 is a high concentration and low resistance region having a higher n-type impurity concentration than the n⁻-type drift region G34. The n⁺-type channel stop region G53 inhibits the expansion of the depletion layer from the pn junction formed in the inner region of the semiconductor layer G2.

In the outer region G7, a second contact recess G54 for the emitter pad G22 and a third contact recess G55 for the emitter routing portion G23 are formed in a surface portion of the p+-type termination region G51. The second contact recess G54 extends downward from the first main surface G3 of the semiconductor layer G2. The second contact recess G54 has a bottom located within the p⁺-type termination region G51. The second contact recess G54 has a depth substantially equal to that of the first contact recess G44. The third contact recess G55 extends downward from the first main surface G3 of the semiconductor layer G2. The third contact recess G55 has a bottom located within the p⁺-type termination region G51. The third contact recess G55 has a depth substantially equal to that of the first contact recess G44.

The p⁺-type termination region G51 includes a p⁺-type contact region G56 formed along the bottom of the second contact recess G54. The p⁺-type contact region G56 is a high concentration region having a higher p-type impurity concentration than the other regions of the p⁺-type termination region G51. The p⁺-type termination region G51 includes a p⁺-type contact region G57 formed along the bottom of the third contact recess G55. The p⁺-type contact region G57 is a high concentration region having a higher p-type impurity concentration than the other regions of the p⁺-type termination region G51.

In the breakdown-voltage sustaining region G8, a fourth contact recess G58 for the field plate electrode G13 is formed in a surface portion of the p⁺-type field-limit region G52. The fourth contact recess G58 extends downward from the first main surface G3 of the semiconductor layer G2. The fourth contact recess G58 has a bottom located within the p⁺-type field-limit region G52. The fourth contact recess G58 has a depth substantially equal to that of the first contact recess G44.

The p⁺-type field-limit region G52 includes a p⁺-type contact region G59 formed along the bottom of the fourth contact recess G58. The p⁺-type contact region G59 is a high concentration region having a higher p-type impurity concentration than the other regions of the p⁺-type field-limit region G52.

In the scribe region G9, a fifth contact recess G60 for the equipotential electrode G14 is formed in a surface portion of the semiconductor layer G2 near the first main surface G3. The fifth contact recess G60 extends downward from the first main surface G3 of the semiconductor layer G2. The fifth contact recess G60 has a depth substantially equal to that of the first contact recess G44. The n⁺-type channel stop region G53 is exposed at the fifth contact recess G60.

In the semiconductor layer G2, a p⁺-type contact region G61 is formed along the bottom of the fifth contact recess G60.

As shown in FIGS. 31 and 32, an insulating layer G64 is formed on the first main surface G3 of the semiconductor layer G2. The insulating layer G64 covers the element formation region G6, the outer region G7, the breakdown-voltage sustaining region G8, and the scribe region G9.

The insulating layer G64 includes a first contact hole G65, a second contact hole G67, and a third contact hole G68 for the emitter electrode G12. The first contact hole G65, the second contact hole G67, and the third contact hole G68 are each in one-to-one correspondence with, and are flush-connected to, the first contact recess G44, the second contact recess G54, and the third contact recess G55, respectively. The insulating layer G64 includes a fourth contact hole G69 for the field plate electrode G13. The fourth contact hole G69 communicates with the fourth contact recess G58 without a step therebetween. The insulating layer G64 includes a fifth contact hole G70 for the equipotential electrode G14. The fifth contact hole G70 communicates with the fifth contact recess G60 without a step therebetween. The insulating layer G64 includes a gate contact hole G71 for the gate electrode G11. Through the gate contact hole G71, the gate lead-out portion G42 is exposed in a region directly beneath the gate pad G16 and/or in a region directly beneath the gate finger G17.

The front-side electrode G10 described above is formed on the insulating layer G64. The front-side electrode G10 has a multilayer structure composed of a first conductive layer G72 formed on the insulating layer G64 and a second conductive layer G73 formed on the first conductive layer G72. The first conductive layer G72 may have a single-layer structure composed of a titanium nitride layer or a titanium layer, or may have a multilayer structure including a titanium nitride layer and a titanium layer formed on the titanium nitride layer. The first conductive layer G72, which includes the titanium nitride layer and/or a titanium layer, functions as a barrier electrode layer. The second conductive layer G73 may contain, for example, at least one conductive material from among copper, a copper-containing alloy, aluminum, and an aluminum-containing alloy.

The gate pad G16 and/or the gate finger G17, each of which is part of the front-side electrode G10, extend into the gate contact hole G71 from above the insulating layer G64. The gate pad G16 and/or gate finger G17 are electrically connected to the gate lead-out portion G42 within the gate contact hole G71.

The emitter pad G22 of the front-side electrode G10 extends into the first contact hole G65 and the second contact hole G67 from above the insulating layer G64. The emitter pad G22 is electrically connected to the p-type channel region G33 and the n⁺-type emitter region G43 within the first contact hole G65. The emitter pad G22 is electrically connected to the p⁺-type termination region G51 within the second contact hole G67.

The emitter routing portion G23 of the front-side electrode G10 extends into the third contact hole G68 from above the insulating layer G64. The emitter routing portion G23 is electrically connected to the p⁺-type termination region G51 within the third contact hole G68.

In the semiconductor layer G2, avalanche current flowing in a region outside the element formation region G6 is collected by the emitter electrode G12 via the p⁺-type termination region G51. Thus, in addition to the emitter pad G22, the emitter routing portion G23, and the emitter connection portion G24 as described above, the avalanche current collection structure G25 includes the p⁺-type termination region G51 electrically connected to these.

The field plate electrode G13 of the front-side electrode G10 extends into the fourth contact hole G69 from above the insulating layer G64. The field plate electrode G13 is electrically connected to the p⁺-type field-limit region G52 within the fourth contact hole G69.

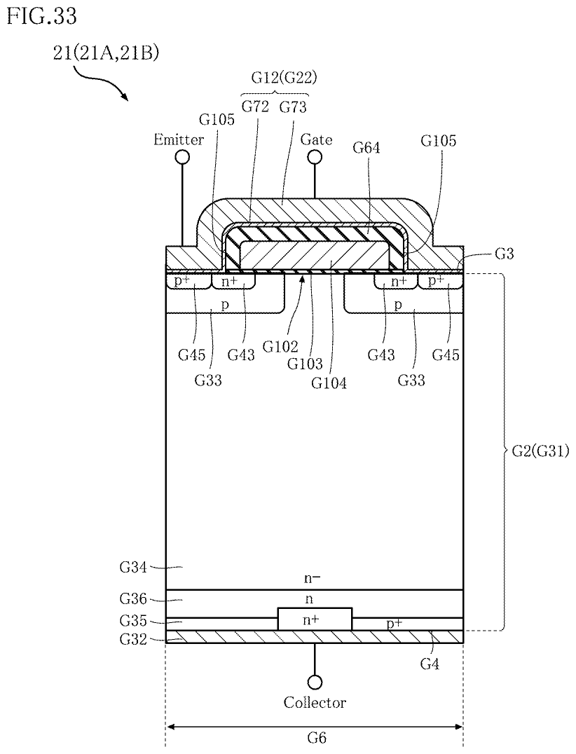

Each semiconductor element 21 included in an intelligent power module A10 (power conversion unit B10) may be implemented, for example, as an IGBT having the planar structure and the internal structure shown in FIGS. 30 to 32. Note that the planar structure and the internal structure shown in FIGS. 30 to 32 are merely an example and are not limited thereto. For example, while FIGS. 30 to 32 show the semiconductor element 21 being a trench-gate IGBT, the semiconductor element 21 may be a planar-gate IGBT. FIG. 33 shows an exemplary configuration of the semiconductor element 21 in which a planar-gate IGBT is formed in the element formation region G6. FIG. 33 is a schematic sectional view of a semiconductor element 21 implemented as a planar-gate IGBT.

The semiconductor element 21 shown in FIG. 33 includes the semiconductor layer G2 described above. As shown in FIG. 33, the p-type channel region G33 as described above is formed at positions spaced apart from each other in a surface portion of the semiconductor layer G2 near the first main surface G3. The n⁺-type emitter region G43 and the p⁺-type contact region G45 as described above are formed in a surface portion of the p-type channel region G33 at positions inwardly spaced from the peripheral edge of the p-type channel region G33. The n-type buffer region G36 and the p⁺-type collector region G35 as described above are formed in a surface portion of the semiconductor layer G2 near the second main surface G4. The n⁻-type drift region G34 described above is the region between the p-type channel region G33 and the n-type buffer region G36 in the semiconductor layer G2.

In the element formation region G6, a planar-gate structure G102 is formed on the first main surface G3 of the semiconductor layer G2. The planar-gate structure G102 includes a gate insulating film G103 and a gate electrode G104.

The gate electrode G104 faces the n⁺-type emitter region G43, the p-type channel region G33, and the n⁻-type drift region G34 across the gate insulating film G103. The planar-gate structure G102 is covered with the insulating layer G64 described above. In this variation, the element formation region G6 is defined by a region surrounded by the p⁺-type termination region G51.

The insulating layer G64 includes a contact hole G105 through which the p-type channel region G33 and the n⁺-type emitter region G43 are exposed. The emitter electrode G12 described above extends into the contact hole G105 from above the insulating layer G64 and is electrically connected to the p-type channel region G33 and the n⁺-type emitter region G43 within the contact hole G105. The collector electrode G32 described above is formed on the second main surface G4 of the semiconductor layer G2 and is electrically connected to the p⁺-type collector region G35.

As described above, each semiconductor element 21 included in the intelligent power module A10 (power conversion unit B10) of the present disclosure is not limited to being a trench-gate type (see FIGS. 30 to 32) or a planar-gate type (see FIG. 33). In addition, each semiconductor element 21 included in the intelligent power module A10 (power conversion unit B10) of the present disclosure is not limited to being either a p-channel type or an n-channel type.

### Semiconductor Element 22 (MOSFET)

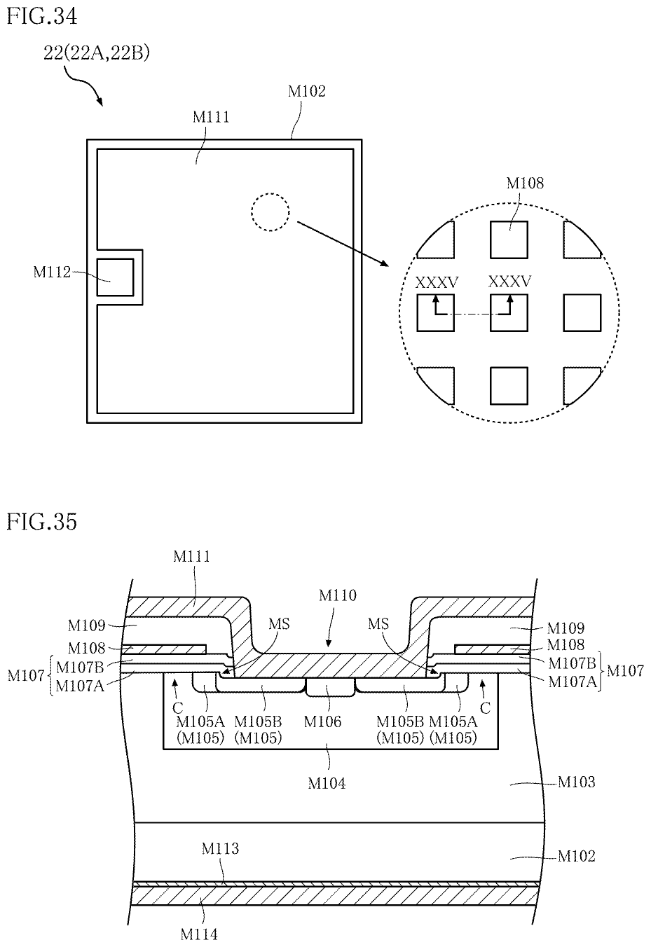

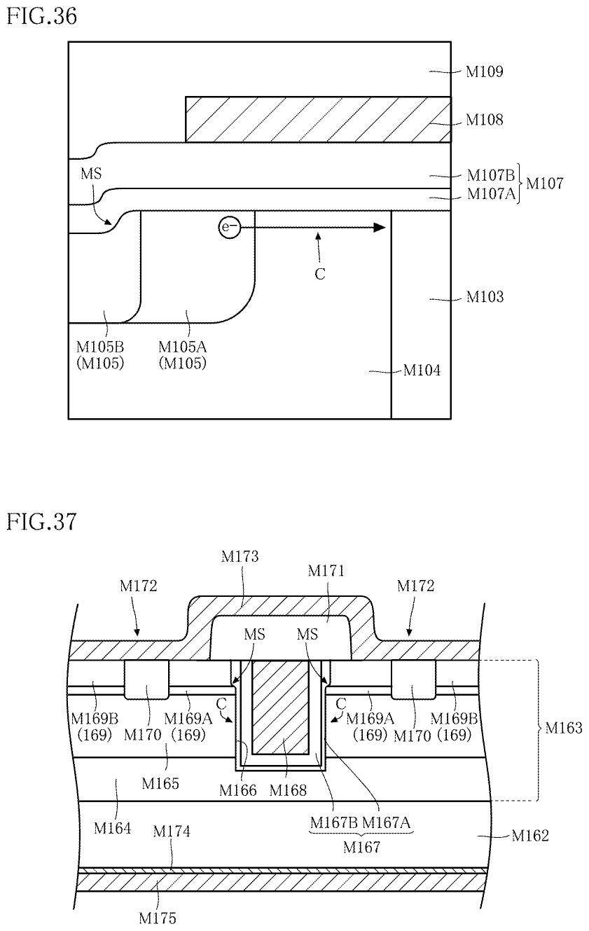

FIGS. 34 to 36 illustrate a detailed exemplary configuration of a semiconductor element 22 configured as a MOSFET. FIG. 34 is a schematic plan view of the semiconductor element 22. FIG. 35 is a sectional view taken along line XXXV-XXXV in FIG. 34. In FIG. 35, hatching is applied only to the conductive portions, and no hatching is provided for the other portions. FIG. 36 is a schematic enlarged cross-sectional view of FIG. 35, showing a first region of the source region and a region in the vicinity of the channel region. Note that the exemplary configuration shown in FIGS. 34 to 36 is merely an example and is not limited thereto.

As shown in FIG. 35, the semiconductor element 22 includes a semiconductor substrate M102. The semiconductor substrate M102 is made of SiC doped with an N-type impurity (N-type SiC). On the semiconductor substrate M102, a semiconductor layer M103 is formed by epitaxial growth. That is, the semiconductor layer M103 is an epitaxial layer made of N-type SiC.

In a surface portion of the semiconductor layer M103, a plurality of p-type well regions M104 are formed. The well regions M104 have a quadrilateral (substantially square) shape in plan view and are arranged in a matrix pattern.

In a surface portion of each well region M104, an n-type source region M105 is formed at a position spaced apart from the peripheral edge of the well region M104. As shown in FIG. 35, the source region M105 includes a first region M105A having a predetermined width (e.g., 0.2 μm) from its peripheral edge in plan view, and the first region M105A has an n-type impurity concentration that is lower by one to three orders of magnitude than that of a remaining second region M105B (the region inside the first region M105A). That is, the source region M105 includes the N⁺-type second region M105B having a relatively high n-type impurity concentration, and the n⁻-type first region M105A that annularly surrounds the second region M105B and has a relatively low n-type impurity concentration. A step MS is formed between the upper surface of the first region M105A and the upper surface of the second region M105B such that the upper surface of the second region M105B is lower than that of the first region M105A (see FIG. 36). No large step is formed between the upper surface of the first region M105A and the upper surface of the well region M104 (channel region C), and these upper surfaces are substantially flush with each other.

At the center of the second region M105B of each source region M105, a p⁺-type contact region M106 is formed, which is doped with a p-type impurity at a higher concentration than the well region M104. Each contact region M106 penetrates the second region M105B in the depth direction, and its deepest portion reaches the well region M104 beneath the source region M105.

A gate insulating film M107 is formed on the semiconductor layer M103. The gate insulating film M107 has an AlON/SiO₂ stacked structure that includes a relatively thin SiO₂ film M107A made of SiO₂ (silicon oxide) containing nitrogen (N), and an AlON film M107B made of AlON (aluminum oxynitride) and formed on the SiO₂ film M107A.

As shown in FIG. 35, a gate electrode M108 is formed on the gate insulating film M107 (the AlON film M107B). The gate electrode M108 faces, across the gate insulating film M107, the semiconductor layer M103 located between the well regions M104, the channel region C located between the peripheral edge of each well region M104 and the peripheral edge of the source region M105 included in that well region M104, and a portion of the first region M105A of the source region M105. As shown in FIG. 34, the gate electrode M108 is formed in a grid pattern in plan view as a whole. Thus, the semiconductor element 22 has a planar-gate MIS structure. The gate electrode M108 is made of polysilicon doped with an n-type or p-type impurity, or a metal material containing aluminum (Al).

As shown in FIG. 35, an interlayer insulating film M109 is formed on the semiconductor layer M103. The interlayer insulating film M109 covers the upper surface of the semiconductor layer M103 together with the gate electrode M108. The interlayer insulating film M109 is made of, for example, silicon oxide.

The interlayer insulating film M109 includes a plurality of contact holes M110 at positions corresponding to the respective contact regions M106. Each contact hole M110 penetrates the gate insulating film M107, exposing the entire contact region M106 and a portion of the source region M105 surrounding the contact region M106.

A source metal M111 (corresponding to the electrode 222 described above) is formed on the interlayer insulating film M109. The source metal M111 extends into each contact hole M110 formed in the interlayer insulating film M109 and is connected to the source region M105 and the contact region M106. The source metal M111 is made of, for example, a metal material containing aluminum (Al) as a main component.

As shown in FIG. 34, the semiconductor element 22 has an opening at a central portion along an edge, through which a portion of the gate electrode M108 is exposed as a gate pad M112 (corresponding to the above-described electrode 223) for external connection.

As shown in FIG. 35, an ohmic metal M113 made of, for example, nickel (Ni) is formed on the entire back surface of the semiconductor substrate M102, followed by a drain metal M114 (corresponding to the above-described electrode 221) made of a metal material containing aluminum as a main component.

As shown in FIG. 36, in the semiconductor element 22, the first region M105A of the source region M105, which is adjacent to the channel region C, has a relatively low n-type impurity concentration. As a result, no large step is formed between the upper surface of the first region M105A and the upper surface of the channel region C (the well region M104). Consequently, electrons (e-) flowing between the source metal M111 and the drain metal M114 travel from the source region M105 to the channel region C along the upper surface of the first region M105A, and then move along the upper surface of the channel region C. That is, electrons in the channel region C travel in a straight path along the upper surface of the channel region C.

Each semiconductor element 22 included in an intelligent power module A10 (power conversion unit B10) may be implemented, for example, as a MOSFET having the planar structure and the internal structure shown in FIGS. 34 to 36. Note that the planar structure and the internal structure shown in FIGS. 34 to 36 is merely an example and is not limited thereto. For example, while FIGS. 34 to 36 show the semiconductor element 22 being a planar-gate MOSFET, the semiconductor element 22 may be a trench-gate MOSFET. FIGS. 37 and 38 show an exemplary configuration of the semiconductor element 22 being a trench-gate MOSFET. FIGS. 37 and 38 are each a schematic sectional view of a semiconductor element 22 implemented as a MOSFET of a trench-gate MIS structure. In FIG. 37, hatching is applied only to the conductive portions, and no hatching is provided for the other portions. FIG. 38 is a schematic enlarged cross-sectional view of a portion of FIG. 37, showing a first region of the source region and a region in the vicinity of the channel region.

The semiconductor element 22 shown in FIGS. 37 and 38 include a semiconductor substrate M162. The semiconductor substrate M162 is made of SiC doped with an N-type impurity (N-type SiC). On the semiconductor substrate M162, a semiconductor layer M163 is formed by epitaxial growth. That is, the semiconductor layer M163 is an epitaxial layer made of N-type SiC. The base portion of the semiconductor layer M163 remains as epitaxially grown and constitutes the n⁻-type drain region M164. A surface portion of the semiconductor layer M163 is doped with a p-type impurity, forming a p-type well region M165.

The semiconductor layer M163 includes a gate trench M166 that extends downward from its surface. The gate trench M166 is formed in a grid pattern in plan view, similarly to the gate electrode M108 shown in FIG. 34, for example. The gate trench M166 penetrates the well region M165, and its deepest portion reaches the drain region M164.

A gate insulating film M167 is formed on the inner surface of the gate trench M166. The gate insulating film M167 has an AlON/SiO₂ stacked structure that includes a relatively thin SiO₂ film M167A made of SiO₂ (silicon oxide) containing nitrogen (N), and an AlON film M167B made of AlON (aluminum oxynitride). The SiO₂ film M167A is in contact with the inner surfaces of the gate trench M166, and the AlON film M167B is formed on the SiO₂ film M167A.

The region inside the gate insulating film M167 is filled with polysilicon doped with an n-type or p-type impurity, thereby forming a gate electrode M168 made of the doped polysilicon and embedded in the gate trench M166. The gate electrode M168 may be formed of a metal material containing Al (aluminum).

An n-type source region M169 is formed in a surface portion of the well region M165. The source region M169 includes a first region M169A having a predetermined depth (e.g., 0.2 μm) at its bottom, and the first region M169A has an n-type impurity concentration that is lower by one to three orders of magnitude than that of a remaining second region M169B (a region above the first region M169A). That is, the source region M169 includes the n⁺-type second region M169B having a relatively high n-type impurity concentration, and the n⁻-type first region M169A having a relatively low n-type impurity concentration, formed below the second region M169B. Due to the difference in n-type impurity concentration between the first region M169A and the second region M169B, a step MS is formed between the side surface of the first region M169A and the side surface of the second region M169B, with the side surface of the second region M169B being spaced farther from the gate electrode M168 than is the side surface of the first region M169A. No large step is formed between the side surface of the first region M169A and the side surface of the well region M165 (channel region C), and these side surfaces are substantially flush with each other.

In a surface portion of the well region M165, a p⁺-type contact region M170 is formed in each region that is surrounded by the gate trench M166. Each p⁺-type contact region M170 is spaced from the gate trench M166 and penetrates the source region M169 in the thickness direction.

An interlayer insulating film M171 is formed on the semiconductor layer M163. The interlayer insulating film M171 is made of, for example, silicon oxide. The interlayer insulating film M171 has a plurality of contact holes M172 formed at positions corresponding to the respective contact regions M170. Within each contact hole M172, the entire contact region M170 is exposed, along with a portion of the source region M169 surrounding the contact region M170. A source metal M173 is formed on the interlayer insulating film M171. The source metal M173 extends into each contact hole M172 and is connected to the source region M169 and the contact region M170. The source metal M173 is made of, for example, a metal material containing Al as a main component.

On the entire back surface of the semiconductor substrate M162, an ohmic metal M174 made of, for example, nickel (Ni), is formed, followed by a drain metal M175 made of a metal material containing aluminum as a main component.

As shown in FIG. 38, in the semiconductor element 22, the first region M169A of the source region M169, which is adjacent to the channel region C, has a relatively low n-type impurity concentration. As a result, no large step is formed between the side surface of the first region M169A and the side surface of the channel region C (the well region M165). Consequently, electrons (e-) flowing between the source metal M173 and the drain metal M175 move from the source region M169 to the channel region C along the side surface of the first region M169A (the inner surface of the gate trench M166), and then move along the side surface of the channel region C. That is, electrons in the channel region C travel in a straight path along the side surface of the channel region C.

### Vehicle F1

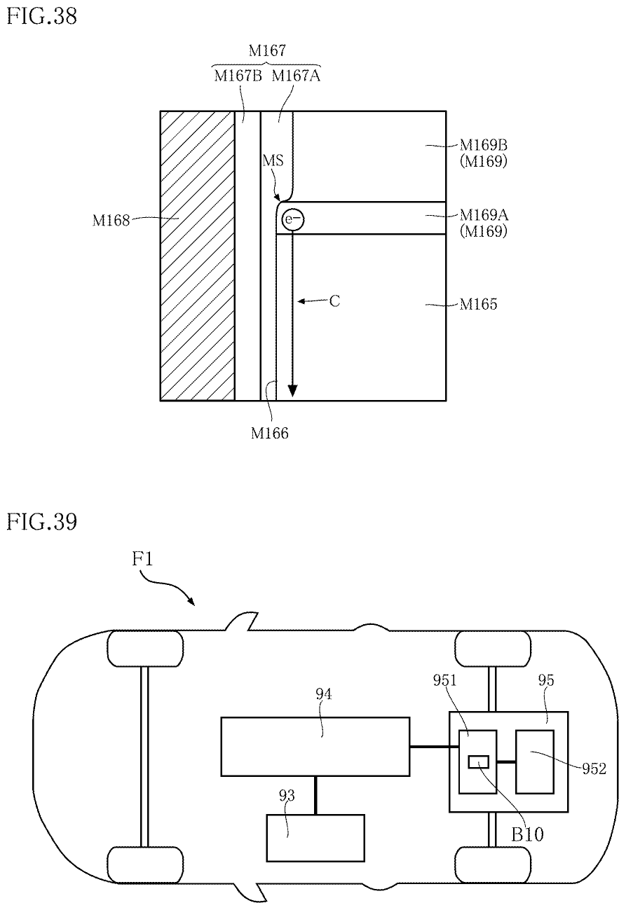

Next, a vehicle F1 equipped with an intelligent power module A10 will be described with reference to FIG. 39. For example, the vehicle F1 is an electric vehicle (EV).

As shown in FIG. 39, the vehicle F1 includes an on-board charger 93, a storage battery 94, and a drive system 95. The on-board charger 93 wirelessly receives power from an outdoor power supply facility (not shown). Alternatively, the on-board charger 93 may receive power from a power supply facility via a wired connection. The on-board charger 93 includes a step-up DC-DC converter. The voltage of the power supplied to the on-board charger 93 is increased by the converter and supplied to the storage battery 94. For example, the voltage is increased to 600 V.

The drive system 95 propels the vehicle F1. The drive system 95 includes an inverter 951 and a drive source 952. The power conversion unit B10 (the intelligent power modules A10, the module sections PM1) forms part of the inverter 951. The power stored in the storage battery 94 is supplied to the inverter 951. The storage battery 94 supplies DC power to the inverter 951. In contrast to the power system shown in FIG. 39, an additional step-up DC-DC converter may be provided between the storage battery 94 and the inverter 951. The inverter 951 converts DC power to AC power. The inverter 951, which includes the power conversion unit B10 (the intelligent power modules A10, the module sections PM1), is electrically connected to the drive source 952. The drive source 952 includes an AC motor and a transmission. When AC power converted by the inverter 951 is supplied to the drive source 952, the AC motor rotates and delivers the torque to the transmission. The transmission reduces the rotational speed transmitted from the AC motor as needed and rotates the drive shaft of the vehicle F1. As a result, the vehicle F1 is driven. In driving the vehicle F1, the rotational speed of the AC motor needs to be adjusted based on the position of the accelerator pedal and other relevant information. The power conversion unit B10 (the intelligent power modules A10, the module sections PM1) in the inverter 951 is necessary for outputting AC power with a frequency appropriately adjusted to match the target rotational speed of the AC motor.

The operations and effects of the intelligent power modules A10, the power conversion unit B10, and related components according to the first embodiment are as follows.

The intelligent power module A10 includes two semiconductor elements 21A and 22A, a pair of rectifying elements D11, and a pair of rectifying elements D12. The semiconductor element 21A includes a plurality of electrodes 211, 212, and 213, and the semiconductor element 22A includes a plurality of electrodes 221, 222, and 223. The rectifying elements D11 are connected in series between the electrodes 213 and 223 via a connection point C11. The rectifying elements D12 are connected in series between the electrodes 213 and 223 via a connection point C12. The intelligent power module A10 additionally includes a drive element 82A, a resistor R11, and a resistor R12. The resistor R11 is connected between the connection point C11 and the drive element 82A, and the resistor R12 is connected between the connection point C12 and the drive element 82A. The pair of rectifying elements D11 are connected such that one conducts forward current from the connection point C11 to the electrode 213, and the other to the electrode 223. The pair of rectifying elements D12 are connected such that one conducts forward current from the electrode 213 to the connection point C12, and the other from the electrode 223. In this configuration, in the switching section SW1, for example, the electrode 213 of the semiconductor element 21A is electrically connected to the electrode 223 of the semiconductor element 22A via one of the rectifying elements D12, the connection point C12, the signal terminal Toff1, the resistor R12, the resistor R11, the signal terminal Ton1, the connection point C11, and one of the rectifying elements D11. That is, the conduction path between the electrodes 213 and 223 of the two semiconductor elements 21 and 22 is lengthened by the pair of rectifying elements D11 and the pair of rectifying elements D12. This increases the parasitic impedance of the wiring between the electrode 213 of the semiconductor element 21A and the electrode 223 of the semiconductor element 22A. This increased parasitic impedance effectively suppresses resonance of the drive signal when the semiconductor elements 21A and 22A are driven in parallel. Consequently, even when the two semiconductor elements 21 and 22 are switched by a common drive signal, resonance of the drive signal can be suppressed. The same applies to the configuration of the two semiconductor elements 21B and 22B (the switching section SW2), the pair of rectifying elements D21, the pair of rectifying elements D22, the drive element 82B, and the two resistors R21 and R22.

The intelligent power module A10 includes a pair of rectifying elements D11. The pair of rectifying elements D11 are connected in series via the connection point C11 such that one conducts forward current from the connection point C11 to the electrode 213, and other to the electrode 223. The resistor R11 is connected between the drive element 82A and the connection point C11. In the intelligent power module A10, the resistor R11 functions as a gate resistor during turn-on of the switching section SW1 (the semiconductor elements 21A and 22A). The intelligent power module A10 includes a pair of rectifying elements D12. The pair of rectifying elements D12 are connected in series via the connection point C12 such that one conducts forward current from the electrode 213 to the connection point C12, and the other from the electrode 223. The resistor R12 is connected between the drive element 82A and the connection point C12. In the intelligent power module A10, the resistor R12 functions as a gate resistor during turn-off of the switching section SW1 (the semiconductor elements 21A and 22A). Typically, when separate gate resistors are formed for turn-on and for turn-off, diodes are connected in series with the respective gate resistors. In the intelligent power module A10, the pair of rectifying elements D11 and the pair of rectifying elements D12 serve as such diodes. In other words, the intelligent power module A10 does not require a separate turn-on gate resistor (resistor R11) or turn-off gate resistor (resistor R12). The same also applies to the pair of rectifying elements D21 and the pair of rectifying elements D22.

In the intelligent power module A10, the semiconductor element 21 is an IGBT, and the semiconductor element 22 is a MOSFET. In general, MOSFETs and IGBTs are known to exhibit the following electrical characteristics due to differences in their material properties and structures. For example, MOSFETs have a higher switching speed and lower switching losses than IGBTs. Switching loss is a loss that occurs during switching (turn-on or turn-off) of each switching element. On the other hand, an IGBT exhibits lower on-resistance and lower steady-state losses than a MOSFET in a high current region. Steady-state loss is a loss that occurs in each switching element in a steady state (conducting state), and is a loss due to on-resistance of each switching element. Therefore, in the intelligent power module A10, the semiconductor element 21, which is an IGBT, and the semiconductor element 22, which is a MOSFET, are electrically connected in parallel. As a result, the intelligent power module A10 reduces both switching loss and steady-state loss, thereby reducing power loss. That is, the intelligent power module A10 can improve conversion efficiency.

In the intelligent power module A10, the semiconductor element 21 includes a first semiconductor substrate (semiconductor substrate G31). The constituent material of the first semiconductor substrate includes, for example, silicon (Si). The semiconductor element 22 includes a second semiconductor substrate (semiconductor substrate M102). The constituent material of the second semiconductor substrate has a wider band gap than that of the first semiconductor substrate and includes, for example, SiC. SiC has a wider bandgap than Si, and a switching element using SiC has advantages such as lower power loss compared with a switching element using Si. On the other hand, a switching element using SiC is more expensive than a switching element using Si. In the intelligent power module A10, the first semiconductor substrate (semiconductor substrate G31) of the semiconductor element 21 is made of Si, and the second semiconductor substrate (semiconductor substrate M102) of the semiconductor element 22 is made of SiC. This configuration enables both reduced power loss and suppressed cost increase. In addition, a switching element using SiC has a higher switching speed than a switching element using Si. Accordingly, the use of SiC for the second semiconductor substrate (semiconductor substrate M102) is effective in suppressing power loss (switching loss) during switching (turn-on and turn-off).

In the power conversion unit B10, the wiring board E1 includes two circuit boards 81 and 82. The two circuit boards 81 and 82 are arranged along the first direction z. The electronic components forming the drive circuit section DR1 (the resistors R11, R12, R21, and R22 and the drive elements 82A and 82B) are each mounted on a corresponding one of the circuit boards 81 and 82. According to this configuration, even if the wiring board E1 (the two circuit boards 81 and 82) has a small area in plan view, a relatively large mounting area is provided for the electronic components constituting the drive circuit section DR1. Thus, even if each module section PM1 is made smaller in plan view, a sufficient mounting area for the electronic components constituting the drive circuit section DR1 can still be ensured.

In the power conversion unit B10, the circuit board 81 has the electronic components (the resistors R11, R12, R21, and R22) mounted on its upper surface, while no electronic components are mounted on its lower surface. When each module section PM1 is energized, heat generated by the semiconductor elements 21 and 22 in the module section PM1 may be radiated from the module section PM1. In addition, when each module section PM1 is energized, electromagnetic noise may be emitted from the module section PM1. In view of this, the circuit board 81 has the electronic components mounted on its upper surface, while no electronic components are mounted on its lower surface. This configuration serves to suppress malfunctions and failures of the drive circuit section DR1 due to the above-described heat radiation and electromagnetic noise emission.

The following describes other embodiments and variations of the intelligent power module A10 and the power conversion unit B10 according to the present disclosure. Note that configurations of elements and components in the embodiments and variations described below may be combined in any manner, provided that no technical inconsistencies arise.

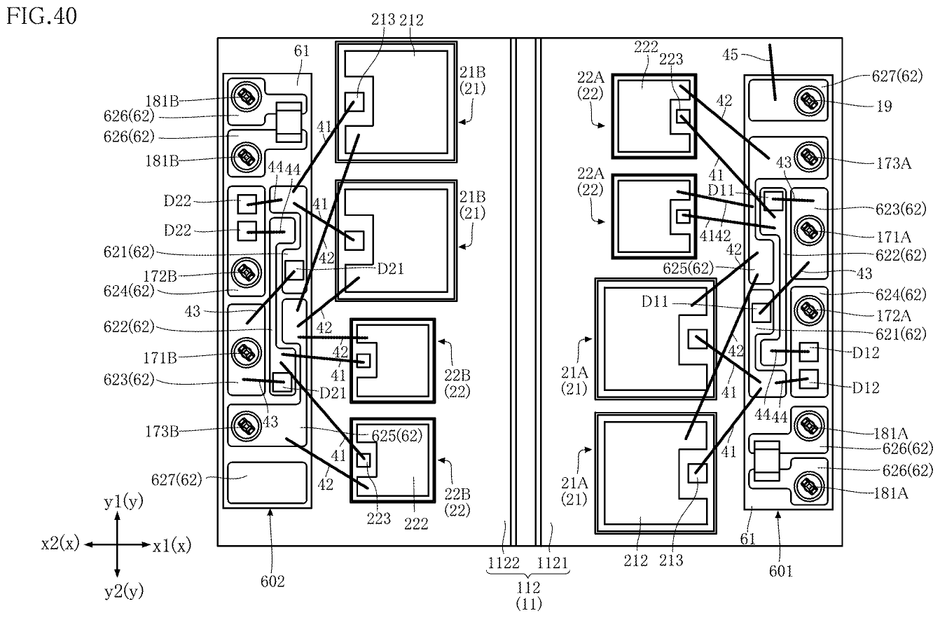

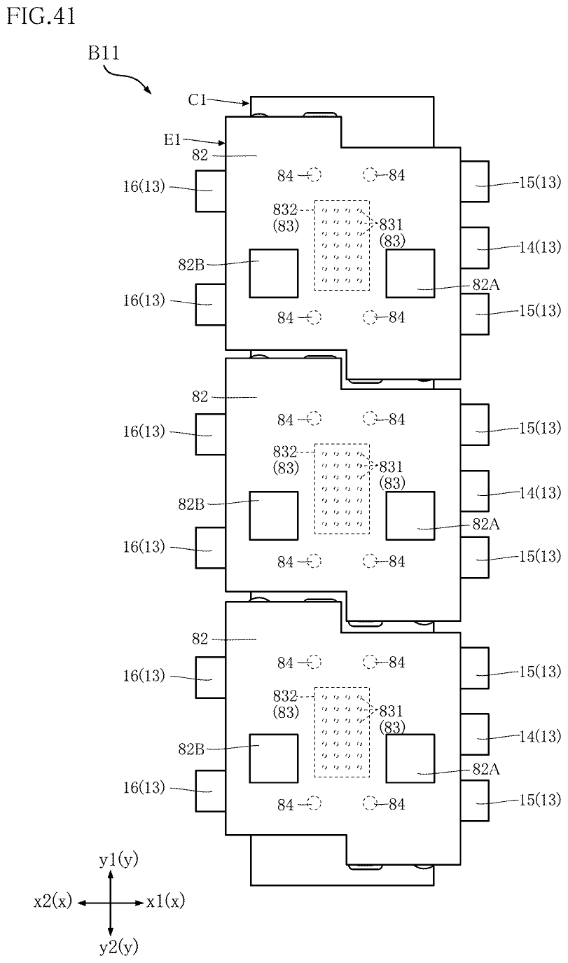

In the first embodiment, the switching sections SW1 and SW2 each include one semiconductor element 21 and one semiconductor element 22. Different from this configuring, the switching sections SW1 and SW2 may each include a plurality of semiconductor elements 21 and a plurality of semiconductor elements 22. In such a variation, in each of the switching section SW1 and SW2, the plurality of semiconductor elements 21 are connected in parallel, and the plurality of semiconductor elements 22 are connected in parallel. FIG. 40 shows an exemplary configuration of a module section PM1 according to such a variation. FIG. 40 shows the two semiconductor elements 21A and the two semiconductor elements 22A are electrically connected in parallel, and the two semiconductor elements 21B and the two semiconductor elements 22B are electrically connected in parallel. In FIG. 40, the two semiconductor elements 21A and the two semiconductor elements 22A are mounted on the mounting section 1121. The two semiconductor elements 21B and the two semiconductor elements 22B are mounted on the mounting section 1122.

As can be seen from the variation shown in FIG. 40, the intelligent power module A10 (power conversion unit B10) of the present disclosure is not limited to a configuration in which one semiconductor element 21 and one semiconductor element 22 are electrically connected in parallel. Rather, it also encompasses configurations in which a plurality of semiconductor elements 21 and a plurality of semiconductor elements 22 are electrically connected in parallel.

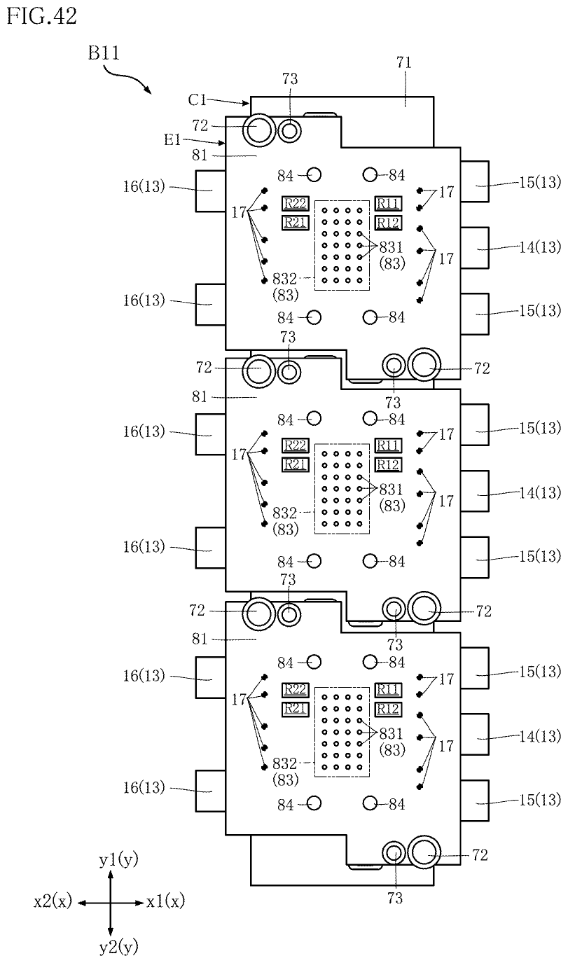

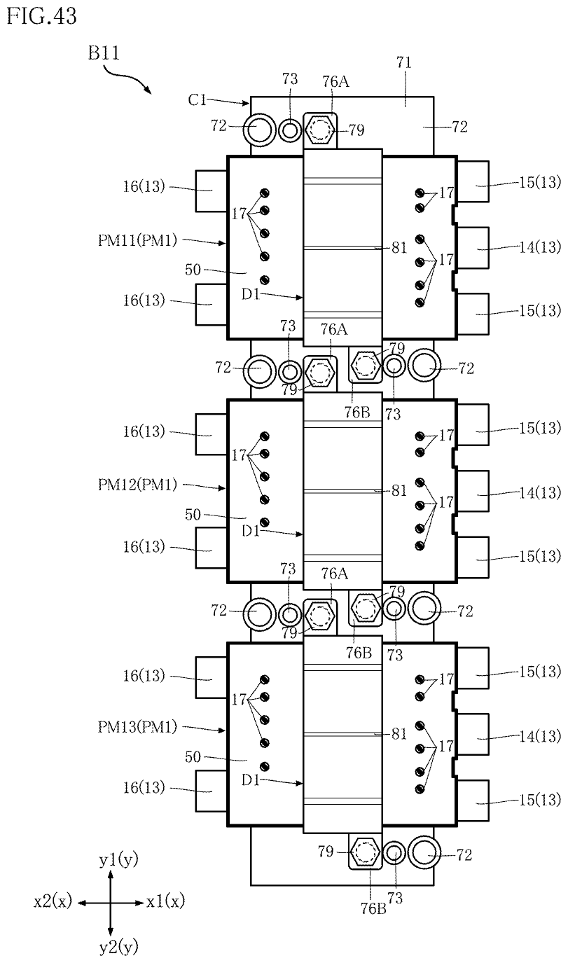

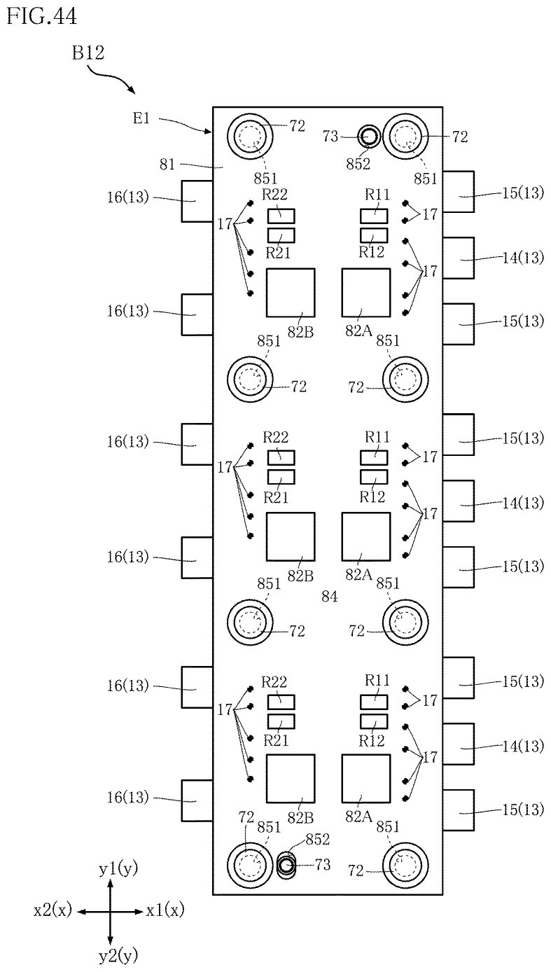

In the first embodiment, the wiring board E1 of the power conversion unit B10 includes one circuit board 81 and one circuit board 82 for the plurality of module sections PM1. Different from this configuring, the wiring board E1 may include a separate circuit board 81 and a separate circuit board 82 for each module section PM1. FIGS. 41 to 43 show an exemplary configuration of a power conversion unit B11 according to such a variation.

The wiring board E1 of the power conversion unit B11 includes three circuit boards 81 and three circuit boards 82 for the three module sections PM1. One circuit board 81 and one circuit board 82 form a pair, and each pair of the circuit boards 81 and 82 is arranged over a corresponding module section PM1.

As can be seen from the variation shown in FIGS. 41 to 43, the power conversion unit of the present disclosure (including a plurality of intelligent power modules) is not limited to a configuration in which the plurality of module sections PM1 share common circuit boards 81 and 82, but may alternatively be configured such that circuit boards 81 and 82 are provided separately for each of the module sections PM1.

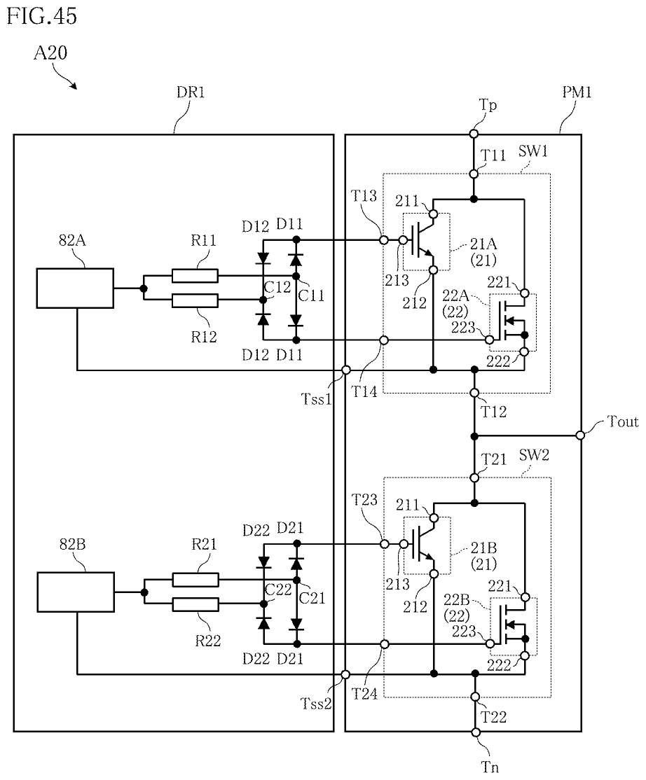

In the first embodiment described above, the wiring board E1 of the power conversion unit B10 includes two circuit boards 81 and 82. Different from this configuring, the wiring board E1 may include only the circuit board 81. FIG. 44 shows an exemplary configuration of a power conversion unit B12 according to such a variation.

In the power conversion unit B12 shown in FIG. 44, the wiring board E1 includes the circuit board 81 but does not include the circuit board 82. In addition to the resistors R11, R12, R21, and R22, the drive elements 82A and 82B are also mounted on the circuit board 81.

As can be seen from the variation shown in FIG. 44, the power conversion unit (the intelligent power module) of the present disclosure is not limited to a configuration in which the electronic components of the drive circuit section DR1 are mounted on the two circuit boards 81 and 82, but also encompasses a configuration in which the electronic components are mounted on only the circuit board 81.

In the first embodiment, the rectifying elements D11, D12, D21, and D22 each include electrodes formed on an upper surface and a lower surface. Unlike this configuration, each rectifying element may include electrodes formed on a pair of side surfaces that face in opposite directions. In this variation, the layout and shape of the wiring layers 62 of the two control wirings 601 and 602 are appropriately modified, and each of the rectifying elements D11, D12, D21, and D22 is bonded to straddle two of the modified wiring sections.

FIG. 45 shows an intelligent power module A20 according to a second embodiment. The intelligent power module A20 differs from the intelligent power module A10 as follows. First, the pair of rectifying elements D11 and the pair of rectifying elements D12 are provided in the drive circuit section DR1. Second, the pair of rectifying elements D21 and D22 are provided in the drive circuit section DR1.

Similarly to the intelligent power module A10, even when the two semiconductor elements 21 and 22 are switched by a common drive signal, the intelligent power module A20 is capable of suppressing resonance of the common drive signal. In addition, the intelligent power module A20 provides effects similar to those of the intelligent power module A10 by virtue of the configuration common to the intelligent power module A10.

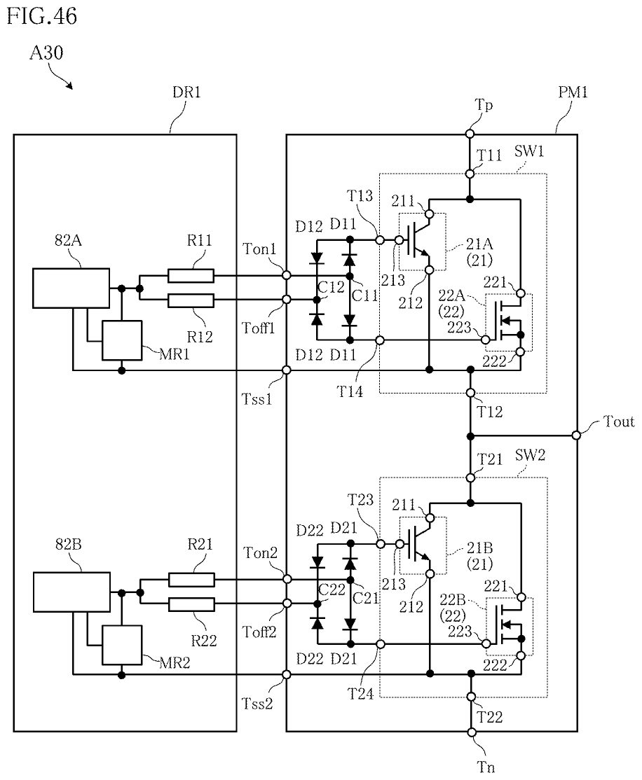

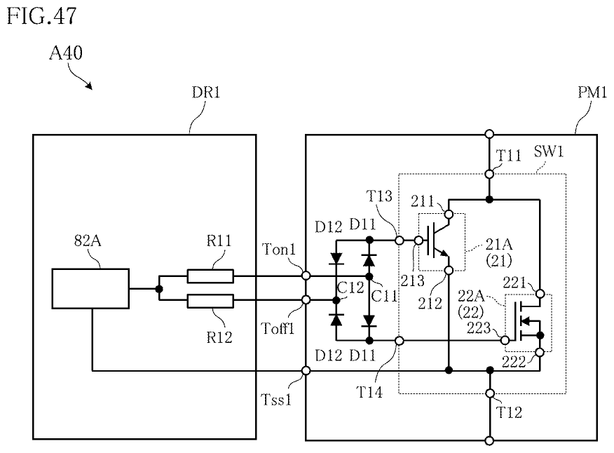

FIG. 46 shows an intelligent power module A30 according to a third embodiment. The intelligent power module A30 differs from the intelligent power module A10 as follows. That is, the intelligent power module A20 additionally includes two mirror clamp circuits MR1 and MR2.

The mirror clamp circuit MR1 is connected to the signal terminal Tss1 in the module section PM1. The mirror clamp circuit MR1 is also connected to the electrical connection point between the two resistors R11 and R12 in the drive circuit section DR1. The mirror clamp circuit MR1 includes a switching element, which is not shown in the figure, and this switching element is controlled, for example, by the drive element 82A. The mirror clamp circuit MR1 may alternatively be controlled by a component other than the drive element 82A (e.g., by a control IC). When the switching section SW1 is turned off, the mirror clamp circuit MR1 turns on its switching element. This forces the potential difference between the two signal ends T13 and T14 and the signal terminal Tss1 to be approximately 0 V, thereby suppressing an increase in the gate potentials of the semiconductor elements 21A and 22A. This prevents erroneous turn-on of each semiconductor element 21A and 22A.

Similarly, the mirror clamp circuit MR2 is connected to the signal terminal Tss2 in the module section PM1. The mirror clamp circuit MR2 is also connected to the electrical connection point between the two resistors R21 and R22 in the drive circuit section DR1. The mirror clamp circuit MR2 includes a switching element, which is not shown in the figure, and this switching element is controlled, for example, by the drive element 82B. The mirror clamp circuit MR2 may alternatively be controlled by a component other than the drive element 82B (e.g., by a control IC). When the switching section SW2 is turned off, the mirror clamp circuit MR2 turns on its switching element. This forces the potential difference between the two signal ends T23 and T24 and the signal terminal Tss2 to be approximately 0 V, thereby suppressing an increase in the gate potentials of the semiconductor elements 21B and 22B. This prevents erroneous turn-on of each semiconductor element 21B and 22B.

Similarly to the intelligent power module A10, even when the two semiconductor elements 21 and 22 are switched by a common drive signal, the intelligent power module A30 is capable of suppressing resonance of the common drive signal. In addition, the intelligent power module A30 provides effects similar to those of the intelligent power module A10 by virtue of the configuration common to the intelligent power module A10.

In intelligent power modules A10, A20, and A30 according to the first to third embodiments, one of the two switching sections SW1 and SW2 may not include both of the two semiconductor elements 21 and 22. That is, one of the two switching sections SW1 and SW2 may include only one of the semiconductor elements 21 and 22, or may include either a plurality of semiconductor elements 21 or a plurality of semiconductor elements 22 connected in parallel.

FIG. 47 shows an intelligent power module A40 according to a fourth embodiment. The intelligent power module A40 differs from the intelligent power module A10 as follows. First, the module section PM1 includes the switching section SW1 and the rectifying elements D11 and D12, and does not include the switching section SW2 and the rectifying elements D21 and D22. Second, the drive circuit section DR1 includes the drive element 82A and the two resistors R11 and R12, and does not include the drive element 82B or the resistors R21 and R22.

Similarly to the intelligent power module A10, even when the two semiconductor elements 21 and 22 are switched by a common drive signal, the intelligent power module A40 is capable of suppressing resonance of the common drive signal. In addition, the intelligent power module A40 provides effects similar to those of the intelligent power module A10 by virtue of the configuration common to the intelligent power module A10.

The intelligent power module and the semiconductor module according to the present disclosure are not limited to the embodiments described above. Various modifications in design may be made to the specific configurations of each part of the intelligent power module and semiconductor module according to the present disclosure. For example, the intelligent power module and the semiconductor module according to the present disclosure include embodiments relating to the following clauses.

### Clause 1

An intelligent power module comprising:
a first semiconductor element including a first electrode, a second electrode, and a third electrode, wherein electrical conduction between the first electrode and the second electrode is established in response to a drive signal inputted to the third electrode;
a second semiconductor element including a fourth electrode, a fifth electrode, and a sixth electrode, wherein electrical conduction between the fourth electrode and the fifth electrode is established in response to a drive signal inputted to the sixth electrode;
a drive element configured to output a common drive signal to the third electrode and the sixth electrode;
a pair of first rectifying elements connected in series between the third electrode and the sixth electrode via a first connection point;
a pair of second rectifying elements connected in series between the third electrode and the sixth electrode via a second connection point;
a first resistor connected between the first connection point and the drive element; and
a second resistor connected between the second connection point and the drive element,
wherein the first electrode and the fourth electrode are electrically connected, the second electrode and the fifth electrode are electrically connected,
each of the pair of first rectifying elements is connected to conduct forward current from the first connection point to a corresponding one of the third electrode and the sixth electrode, and
each of the pair of second rectifying elements is connected to conduct forward current from a corresponding one of the third electrode and the sixth electrode to the second connection point.

### Clause 2

The intelligent power module according to Clause 1, comprising a module section including a first switching section that includes the first semiconductor element and the second semiconductor element,
wherein the module section includes an insulating sealing resin that covers the first switching section.

### Clause 3

The intelligent power module according to Clause 2, wherein the module section includes a first signal terminal connected to the first resistor and a second signal terminal connected to the second resistor,
the sealing resin covers the pair of first rectifying elements and the pair of second rectifying elements, and
the first signal terminal and the second signal terminal protrude from the sealing resin.

### Clause 4

The intelligent power module according to Clause 3, comprising a drive circuit section that includes the drive element, the first resistor, and the second resistor.

### Clause 5

The intelligent power module according to Clause 4, further comprising a wiring board on which the drive circuit section is mounted,
wherein the wiring board includes a first circuit board on which the first resistor and the second resistor are mounted.

### Clause 6

The intelligent power module according to Clause 5, wherein
the sealing resin includes a top surface and a bottom surface facing away from each other in a first direction, and
the first signal terminal and the second signal terminal protrude from the top surface.

### Clause 7

The intelligent power module according to Clause 6, wherein the first circuit board includes a through-hole extending in the first direction and faces the top surface in the first direction, and
the first signal terminal and the second signal terminal extend through the through-hole.

### Clause 8

The intelligent power module according to Clause 7, wherein the wiring board includes a second circuit board spaced apart from the first circuit board, and an interconnect wiring electrically connecting the first circuit board and the second circuit board, and
the drive element is mounted on the second circuit board.

### Clause 9

The intelligent power module according to Clause 8, wherein the second circuit board is disposed on a side opposite the module section with respect to the first circuit board in the first direction.

### Clause 10

The intelligent power module according to any one of Clauses 6 to 8, wherein
the drive signal includes a first drive signal and a second drive signal,
the first switching section includes, in a circuit configuration, a first connection end electrically connected to the first electrode and the fourth electrode, and a second connection end electrically connected to the second electrode and the fifth electrode, and electrical conduction between the first connection end and the second connection end is switched between a conductive state and a non-conductive state in response to a first drive signal,
the module section includes a second switching section, and
the second switching section includes, in a circuit configuration, a third connection end and a fourth connection end, and electrical conduction between the third connection end and the fourth connection end is switched between a conductive state and a non-conductive state in response to the second drive signal.

### Clause 11

The intelligent power module according to Clause 10, further comprising:
a first power terminal electrically connected to the first connection end;
a second power terminal electrically connected to the fourth connection end; and
a third power terminal electrically connected to the second connection end and the third connection end.

### Clause 12

The intelligent power module according to Clause 11, wherein the sealing resin includes a first resin side surface and a second resin side surface facing away from each other in a second direction perpendicular to the first direction,
the first power terminal and the second power terminal protrude from the first resin side surface, and
the third power terminal protrudes from the second resin side surface.

### Clause 13

The intelligent power module according to any one of Clauses 1 to 12, wherein the first semiconductor element comprises an IGBT, and
the second semiconductor element comprises a MOSFET.

### Clause 14

The intelligent power module according to Clause 13, wherein the first semiconductor element includes a first semiconductor substrate, and the first semiconductor substrate contains Si, and
the second semiconductor element includes a second semiconductor substrate, and the second semiconductor substrate contains SiC.

### Clause 15

The intelligent power module according to any one of Clauses 1 to 14, wherein each of the first rectifying elements comprises a diode, and
each of the second rectifying elements comprises a diode.

### Clause 16

A semiconductor module comprising:
a first semiconductor element including a first electrode, a second electrode, and a third electrode, wherein electrical conduction between the first electrode and the second electrode is established in response to a drive signal inputted to the third electrode;
a second semiconductor element including a fourth electrode, a fifth electrode, and a sixth electrode, wherein electrical conduction between the fourth electrode and the fifth electrode is established in response to a drive signal inputted to the sixth electrode;
a pair of first rectifying elements connected in series between the third electrode and the sixth electrode via a first connection point; and
a pair of second rectifying elements connected in series between the third electrode and the sixth electrode via a second connection point,
wherein a common drive signal is inputted to the third electrode and the sixth electrode,
the first electrode and the fourth electrode are electrically connected,
the second electrode and the fifth electrode are electrically connected,
each of the pair of first rectifying elements is connected to conduct forward current from the first connection point to a corresponding one of the third electrode and the sixth electrode, and
each of the pair of second rectifying elements is connected to conduct forward current from a corresponding one of the third electrode and the sixth electrode to the second connection point.

### Clause 17

The intelligent power module according to Clause 7, wherein the drive element is mounted on the first circuit board.

### Clause 18

The intelligent power module according to Clause 1, comprising:
a module section including a first switching section that includes the first semiconductor element and the second semiconductor element; and
a drive circuit section that includes the drive element, the first resistor, the second resistor, the pair of first rectifying elements, and the pair of second rectifying elements.

### Clause 19

The intelligent power module according to Clause 6, wherein the first circuit board includes a first surface facing the top surface in the first direction, and a second surface facing away from the first surface in the first direction, and
the first resistor and the second resistor are mounted on the second surface.

### Clause 20

The intelligent power module according to any one of Clauses 1 to 15, comprising:
a mounting section on which the first semiconductor element and the second semiconductor element are mounted; and
a control board mounted on the mounting section,
wherein the control board includes an insulating layer, and a wiring layer disposed on a side opposite the mounting section with respect to the insulating layer,
the wiring layer includes a plurality of wiring sections spaced apart from each other, and
each rectifying element of the pair of first rectifying elements and of the pair of second rectifying elements is bonded to one of the plurality of wiring sections.

### Clause 21

A vehicle comprising:
a drive source; and
   the intelligent power module according to any one of Clauses 1 to 15,
wherein the intelligent power module is electrically connected to the drive source.

### Clause 22

The intelligent power module according to any one of Clauses 1 to 15, wherein the first semiconductor element includes:
a semiconductor layer of a first conductivity type and including a first main surface and a second main surface opposite the first main surface, wherein an element formation region and an outer region outside the element formation region defined in the semiconductor layer;
a channel region of a second conductivity type formed in a surface portion of the element formation region near the first main surface;
a plurality of trench gate structures formed in the element formation region and spaced apart from each other, each trench gate structure including a trench formed in the first main surface and penetrating the channel region, a gate insulating film covering an inner wall of the trench, and a gate electrode embedded in the trench with the gate insulating film interposed therebetween;
a plurality of emitter regions of the first conductivity type formed in a surface portion of the channel region so as to extend along the plurality of trench gate structures;
a termination region of the second conductivity type formed in a surface portion of the outer region near the first main surface, the termination region having a greater depth than the channel region and being connected to an outermost trench gate structure of the plurality of trench gate structures;
a collector region of the second conductivity type formed in a surface portion of the element formation region near the second main surface;
an inner cathode region of the first conductivity type formed in a surface portion of the element formation region near the second main surface; and
an outer cathode region of the first conductivity type formed in a surface portion of the outer region near the second main surface.

### Clause 23

The intelligent power module according to Clause 22, wherein a channel structure is formed in an inner region of the channel region, the channel structure including the channel region, the emitter region, and the trench gate structure,
a dummy channel structure is formed in a peripheral portion of the channel region, the dummy channel structure including the channel region and the trench gate structure but not including the emitter region,
the termination region is connected to the outermost trench gate structure that forms the dummy channel structure.

### Clause 24

The intelligent power module according to any one of Clauses 1 to 15, wherein the second semiconductor element includes:
a semiconductor layer made of SiC of the first conductivity type;
a well region of the second conductivity type formed in a surface portion of the semiconductor layer,
a source region of the first conductivity type formed in a surface portion of the well region,
a gate insulating film formed on the semiconductor layer;
a gate electrode formed on the gate insulating film and facing, across the gate insulating film, a channel region in which a channel in the well region is formed, and
the source region includes a first region adjacent to the channel region and having a predetermined width, the first region having higher impurity concentration than a second region other than the first region.

### REFERENCE NUMERALS

11: supporting substrate 13 to 16: power terminal
17: signal terminal 19: signal terminal
21, 21A, 21B, 22, 22A, 22B: semiconductor element
23: conductive bonding layer 31, 32: conductive member
33 to 36: conductive bonding layer 41 to 45: wire
50: sealing resin 51: top surface
52: bottom surface 53: resin side surface
55: recess 61: insulating layer
62: wiring layer 63: metal layer
64: sleeve 71: main body
72: pedestal portion 73: positioning portion
75: pressing portion 76: fixed portion
79: fastener 81, 82: circuit board
82A, 82B: drive element 83: interconnect wiring
84: positioning pin 93: on-board charger
94: storage battery 95: drive system
107A: SiO₂ film 111: insulating layer
112, 113: wiring layer 170A: base portion
170B: bulging portion 171A, 171B, 172A, 172B: signal terminal
173A, 173B: signal terminal 181A, 181B: signal terminal
211, 212, 213: electrode 221, 222, 223: electrode
311: main body 312, 313: bonding portion
321: main body 322, 323: bonding portion
531 to 533: side surface 601, 602: control wiring
621 to 627: wiring section 721: first portion
722: second portion 761: end-position portion
762: intermediate-position portion 811: base material
811a: through-hole 812: front-side wiring
813: rear-side wiring 814: inner wiring
831: connection portion 831A: connection pin
832: connection portion 832A: housing
832B: connection hole 851: mounting hole
852: positioning hole 951: inverter
952: drive source 1121 and 1122: mounting section
A10, A20, A30, A40: intelligent power module
B10, B11, B12: power conversion unit C: channel region
C1: mounting object C11, C12, C21, C22: connection point
D1: mounting member D11, D12, D21, D22: rectifying element
DR1: drive circuit section E1: wiring board
F1: vehicle G10: front-side electrode
G102: planar-gate structure G103: gate insulating film
G104: gate electrode G105: contact hole
G11: gate electrode G12: emitter electrode
G13: field plate electrode G14: equipotential electrode
G15: insulating region G16: gate pad
G17: gate finger G18: open end
G19: open end G2: semiconductor layer
G22: emitter pad G23: emitter routing portion
G24: emitter connection portion G25: avalanche current collection structure
G3: first main surface G31: n⁻-type semiconductor substrate
G32: collector electrode G33: p-type channel region
G34: n⁻-type drift region G35: p⁺-type collector region
G36: n-type buffer region G37: trench gate structure
G38: gate trench G39: gate insulating film
G4: second main surface G40: embedded gate electrode
G41: surface insulating film G42: gate lead-out portion
G43: n⁺-type emitter region G44: first contact recess
G45: p⁺-type contact region G46: channel structure
G47: dummy channel structure G51: p⁺-type termination region
G52: p⁺-type field-limit region G53: n⁺-type channel stop region
G54: second contact recess G55: third contact recess
G56: p⁺-type contact region G57: p⁺-type contact region
G58: fourth contact recess G59: p⁺-type contact region
G6: element formation region G60: fifth contact recess
G61: p⁺-type contact region G64: insulating layer
G65: first contact hole G67: second contact hole
G68: third contact hole G69: fourth contact hole
G7: outer region G70: fifth contact hole
G71: gate contact hole G72: first conductive layer
G73: second conductive layer G8: breakdown-voltage sustaining region
G9: scribe region M102: semiconductor substrate
M103: semiconductor layer M104: well region
M105: source region M105A: first region
M105B: second region M106: contact region
M107: gate insulating film M107A: SiO₂ film
M107B: AlON film M108: gate electrode
M109: interlayer insulating film M110: contact hole
M111: source metal M112: gate pad
M113: ohmic metal M114: drain metal
M162: semiconductor substrate M163: semiconductor layer
M164: drain region M165: well region
M166: gate trench M167: gate insulating film
M167A: SiO₂ film M167B: AlON film
M168: gate electrode M169: source region
M169A: first region M169B: second region
M170: contact region M171: interlayer insulating film
M172: contact hole M173: source metal
M174: ohmic metal M175: drain metal
MR1, MR2: mirror clamp circuit MS: step
PM1: module section PM11: first module section
PM12: second module section PM13: third module section
R11, R12, R21, and R22: resistor SW1 and SW2: switching section
T11 and T12: connection end T13, T14: signal end
T21, T22: connection end T23 and T24: signal end
TH: thermistor Tp, Tn, Tout: power terminal
Ton1, Ton2, Toff1, Toff2: signal terminal Tss1, Tss2: signal terminal

1. An intelligent power module comprising:
a first semiconductor element including a first electrode, a second electrode, and a third electrode, wherein electrical conduction between the first electrode and the second electrode is established in response to a drive signal inputted to the third electrode;
a second semiconductor element including a fourth electrode, a fifth electrode, and a sixth electrode, wherein electrical conduction between the fourth electrode and the fifth electrode is established in response to a drive signal inputted to the sixth electrode;
a drive element configured to output a common drive signal to the third electrode and the sixth electrode;
a pair of first rectifying elements connected in series between the third electrode and the sixth electrode via a first connection point;
a pair of second rectifying elements connected in series between the third electrode and the sixth electrode via a second connection point;
a first resistor connected between the first connection point and the drive element; and
a second resistor connected between the second connection point and the drive element,
wherein the first electrode and the fourth electrode are electrically connected,
the second electrode and the fifth electrode are electrically connected,
each of the pair of first rectifying elements is connected to conduct forward current from the first connection point to a corresponding one of the third electrode and the sixth electrode, and
each of the pair of second rectifying elements is connected to conduct forward current from a corresponding one of the third electrode and the sixth electrode to the second connection point.

2. The intelligent power module according to claim 1, comprising a module section including a first switching section that includes the first semiconductor element and the second semiconductor element,
wherein the module section includes an insulating sealing resin that covers the first switching section.

3. The intelligent power module according to claim 2, wherein the module section includes a first signal terminal connected to the first resistor and a second signal terminal connected to the second resistor,
the sealing resin covers the pair of first rectifying elements and the pair of second rectifying elements, and
the first signal terminal and the second signal terminal protrude from the sealing resin.

4. The intelligent power module according to claim 3, comprising a drive circuit section that includes the drive element, the first resistor, and the second resistor.

5. The intelligent power module according to claim 4, further comprising a wiring board on which the drive circuit section is mounted,
wherein the wiring board includes a first circuit board on which the first resistor and the second resistor are mounted.

6. The intelligent power module according to claim 5, wherein
the sealing resin includes a top surface and a bottom surface facing away from each other in a first direction, and
the first signal terminal and the second signal terminal protrude from the top surface.

7. The intelligent power module according to claim 6, wherein the first circuit board includes a through-hole extending in the first direction and faces the top surface in the first direction, and
the first signal terminal and the second signal terminal extend through the through-hole.

8. The intelligent power module according to claim 7, wherein the wiring board includes a second circuit board spaced apart from the first circuit board, and an interconnect wiring electrically connecting the first circuit board and the second circuit board, and
the drive element is mounted on the second circuit board.

9. The intelligent power module according to claim 8, wherein the second circuit board is disposed on a side opposite the module section with respect to the first circuit board in the first direction.

10. The intelligent power module according to claim 6, wherein
the drive signal includes a first drive signal and a second drive signal,
the first switching section includes, in a circuit configuration, a first connection end electrically connected to the first electrode and the fourth electrode, and a second connection end electrically connected to the second electrode and the fifth electrode, and electrical conduction between the first connection end and the second connection end is switched between a conductive state and a non-conductive state in response to the first drive signal,
the module section includes a second switching section, and
the second switching section includes, in a circuit configuration, a third connection end and a fourth connection end, and electrical conduction between the third connection end and the fourth connection end is switched between a conductive state and a non-conductive state in response to the second drive signal.

11. The intelligent power module according to claim 10, further comprising:
a first power terminal electrically connected to the first connection end;
a second power terminal electrically connected to the fourth connection end; and
a third power terminal electrically connected to the second connection end and the third connection end.

12. The intelligent power module according to claim 11, wherein the sealing resin includes a first resin side surface and a second resin side surface facing away from each other in a second direction perpendicular to the first direction,
the first power terminal and the second power terminal protrude from the first resin side surface, and
the third power terminal protrudes from the second resin side surface.

13. The intelligent power module according to claim 1, wherein the first semiconductor element comprises an IGBT, and
the second semiconductor element comprises a MOSFET.

14. The intelligent power module according to claim 13, wherein the first semiconductor element includes a first semiconductor substrate, and the first semiconductor substrate contains Si, and
the second semiconductor element includes a second semiconductor substrate, and the second semiconductor substrate contains SiC.

15. The intelligent power module according to claim 1, wherein each of the first rectifying elements comprises a diode, and
each of the second rectifying elements comprises a diode.

16. A semiconductor module comprising:
a first semiconductor element including a first electrode, a second electrode, and a third electrode, wherein electrical conduction between the first electrode and the second electrode is established in response to a drive signal inputted to the third electrode;
a second semiconductor element including a fourth electrode, a fifth electrode, and a sixth electrode, wherein electrical conduction between the fourth electrode and the fifth electrode is established in response to a drive signal inputted to the sixth electrode;
a pair of first rectifying elements connected in series between the third electrode and the sixth electrode via a first connection point; and
a pair of second rectifying elements connected in series between the third electrode and the sixth electrode via a second connection point,
wherein a common drive signal is inputted to the third electrode and the sixth electrode,
the first electrode and the fourth electrode are electrically connected,
the second electrode and the fifth electrode are electrically connected,
each of the pair of first rectifying elements is connected to conduct forward current from the first connection point to a corresponding one of the third electrode and the sixth electrode, and
each of the pair of second rectifying elements is connected to conduct forward current from a corresponding one of the third electrode and the sixth electrode to the second connection point.
